(19) United States
(12) Patent Application Publication
(10) Pub. No.: US 2009/0045725 A1
(43) Pub. Date: Feb. 19, 2009

(54) POLYARYLENE

(75) Inventors: Daisuke Fukushima, Tsukuba (JP); Akihiko Okada, Tsukuba (JP); Takeshi Yamada, Tsukuba (JP); Kazuei Ohuchi, Tsukuba (JP); Hideyuki Higashimura, Tsukuba (JP); Nozomi Kogure, Tsukuba (JP)

Correspondence Address: SUGHRUE MION, PLLC, 2100 PENNSYLVANIA AVENUE, N.W., SUITE 800, WASHINGTON, DC, 20037, US

(73) Assignee: SUMITOMO CHEMICAL COMPANY, LIMITED, Chuo-ku, Tokyo (JP)

(21) Appl. No.: 11/916,464

(22) PCT Filed: Jun. 9, 2006
(86) PCT No.: PCT/JP2006/311613

§ 371 Date: Dec. 4, 2007

(30) Foreign Application Priority Data
Jun. 10, 2005 (JP) 2005-171066

(51) Int. Cl. H01J 1/63; C08G 61/04; C09K 11/00; H01L 51/05

(52) U.S. Cl. 313/504; 528/397; 528/380; 528/86; 528/8; 528/7; 528/403; 528/9; 252/301.35; 257/40; 257/E51.005

(57) ABSTRACT

A high-molecular compound, characterized by containing a chain consisting of repeating units represented by the general formula (1) and having an average number of repeating units constituting the chain of 3 or above and a ratio of bonds formed between the head and the tail to all the bonds formed between repeating units of 85% or above: (1) wherein Ar¹ is a divalent aromatic group whose aromatic ring is an aromatic hydrocarbon ring; R¹ is a substituent on Ar¹; n is an integer of 0 to 30; when n is 2 or above, plural R¹'s may be the same or different from each other, when the carbon atoms of a repeating unit of the general formula (1) are numbered as a divalent group according to Nomenclature of Organic Chemistry by IUPAC, between the two carbon atoms having free valencies, the carbon atom with a smaller number is defined as the head and the carbon atom with a larger number is defined as the tail; and no repeating unit of the general formula (1) has a two-fold axis of symmetry intersecting the straight line joining the head and the tail at right angles at the middle point.

### TECHNICAL FIELD

The present invention relates to polyarylene.

### BACKGROUND ART

In regioregular polyarylenes, there is a repeating unit of a non-symmetric divalent aromatic group, and with this divalent aromatic group, when assigning numbers to the carbon atoms by the IUPAC organic chemistry nomenclature rules, of the 2 carbon atoms with free atomic valence, the smaller numbered carbon atom is the head and the larger numbered carbon atom is the tail, and in regioregular polyarylenes, there is a high ratio of head-tail bonds, which is formed between the head and the tail. Because of the high regularity of these regioregular polyarylenes, capabilities are expressed, such as improved crystallinity, improved orientation, and improved conductivity (refer to Non-patent document 1 and 2).

For the regioregular polyarylene having a high ratio of head-tail bonds, ones with a repeating unit of a hetero-ring such as thiophene, pyridine, quinoline, furan are known (refer to Non-patent document 1).

In addition, for a polyarylene having a repeating unit of a divalent aromatic group in which the aromatic ring is an aromatic hydrocarbon ring, polyphenylenes described in Non-patent document 3 are known, but these do not have any descriptions relating to the regioregularity with the head-tail bonds. Furthermore, in the polyphenylene described in Non-patent document 3, an alkoxymethyl group or acyloxymethyl group is present as a substituent, but these substituents are easily cleaved in both oxidative and reductive environments and are not suitable for use as light-emitting material, charge transport material, organic semiconductor material, polymer electrolyte membrane, and the like.

Non patent document 1: Adv. Mater. 1998, 10, 93
Non-patent document 2: Appl. Phys. Lett. 1996, 69, 4108
Non-patent document 3: Polymeric Materials Science and Engineering 1999, 80, 229

### DISCLOSURE OF THE INVENTION

### Problem to be Solved by the Invention

A polyarylene is desired in which there is excellent stability as a polymer material for light-emitting material, charge transport material, organic semiconductor material, polymer electrolyte membrane, and the like, and there is a repeating unit of a divalent aromatic group in which the aromatic ring is an aromatic hydrocarbon ring, and there is contained a regioregular chain having a high ratio of head-tail bonds.

### Means for Solving the Problem

Upon intensive study in order to solve the above problem, the present inventors have discovered a polyarylene containing a regioregular chain having a high ratio of head-tail bonds with a repeating unit of a divalent aromatic group in which there are substituents which do not breakdown easily in oxidative and reductive environments and in which sulfur atom, nitrogen atom, or oxygen atom are not present in the aromatic ring.

In other words, the present invention relates to a polymer compound (polyarylene) containing a chain (generally referred to as constitutional sequence) consisting of only the repeating unit (generally referred to as constitutional unit) represented by the following Formula (1), and the average number of repeating units forming this chain is 3 or greater, and the ratio of bonds formed between the head and tail to all bonds formed between these repeating units is 85% or greater,

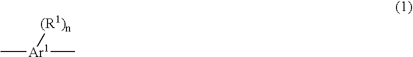

wherein Ar¹ is a divalent aromatic group and the aromatic ring is an aromatic hydrocarbon ring, in other words, the aromatic ring is constructed only of carbon atoms; R¹ represents a substituent on Ar¹, and they each represent independently a hydrocarbon group, hydrocarbon oxy group, hydrocarbon thio group, trialkylsilyl group, halogen atom, nitro group, cyano group, hydroxyl group, mercapto group, acyl group, formyl group, carboxyl group, hydrocarbon oxycarbonyl group, amino group, aminocarbonyl group, imidoyl group, azo group, acyloxy group, phosphonic acid group or sulfonic acid group; n represents an integer from 0 to 30 and when n is an integer of 2 or greater, a plurality of R¹ may be the same or different from each other; when the carbon atoms of the repeating unit represented by Formula (1) are assigned numbers as a divalent group according to the IUPAC organic chemistry nomenclature, of the two carbon atoms with the free atomic valences, the carbon atom with the smaller number is the head, and the carbon atom with the larger number is the tail; and no repeating unit represented by Formula (1) has a two-fold axis of symmetry that intersects the straight line connecting the head and tail at right angles at the midpoint of the line.

### ADVANTAGES OF THE INVENTION

The polymer compound of the present invention (polyarylene) has excellent stability such as thermal stability and chemical stability and the like and is useful as a light-emitting material and charge transport material, and can be used for laser dyes, organic solar cell material, organic semiconductor for organic transistors, electroconductive thin film material such as conductive thin film, organic semiconductor thin film and the like, and polymer electrolyte material such as polymer electrolyte membrane of metal ion and proton conductive membrane and the like.

### BRIEF DESCRIPTION OF THE DRAWINGS

FIG. 1 is the EL spectra of the EL device obtained in Comparative Example 2 before and after the drive;

FIG. 2 is the EL spectra of the EL device obtained in Example 2 before and after the drive;

FIG. 3 is the EL spectra of the EL device obtained in Comparative Example 3 before and after the drive;

FIG. 4 is the EL spectra of the EL device obtained in Example 3 before and after the drive;

FIG. 5 is the EL spectra of the EL device obtained in Example 8 before and after the drive;

FIG. 6 is the EL spectra of the EL device obtained in Example 9 before and after the drive;

FIG. 7 is the EL spectra of the EL device obtained in Comparative Example 8 before and after the drive; and

FIG. 8 is the EL spectra of the EL device obtained in Comparative Example 9 before and after the drive.

### BEST MODE FOR CARRYING OUT THE INVENTION

The polymer of the present invention (also referred to as the polyarylene of the present invention) contains a repeating unit represented by Formula (1). The Ar¹ in Formula (1) is a divalent aromatic group. The aromatic ring is an aromatic hydrocarbon ring.

A divalent aromatic group is the remaining atomic group when two hydrogen atoms bonded to carbon atoms in benzene are removed or the remaining atomic group when two hydrogen atoms bonded to carbon atoms of an aromatic ring are removed from a condensed ring containing one or more aromatic rings. Divalent aromatic groups normally have 6-100 carbons, preferably 6-60 carbons, more preferably 6-45 carbons, and even more preferably 6-30 carbons. The carbon number of the divalent aromatic group does not include the carbon number of substituents.

An atomic group shown in the following (1A-1) is an example of the remaining atomic group after removing two hydrogen atoms bonded to carbon atoms in benzene. The following Formulas (1B-1) to (1B-36) and (1C-1) to (1C-37) are examples of an atomic group of what remains after removing two hydrogen atoms bonded to carbon atoms of an aromatic ring from a condensed ring containing one or more aromatic rings.

The divalent aromatic group is preferably an atomic group of Formulas (1B-1) to (1B-36) and Formulas (1C-1) to (1C-37), more preferably atomic group of Formulas (1B-1) to (1B-13) and Formulas (1C-1) to (1C-37), even more preferably atomic group of Formulas (1B-8) to (1B-13) and Formulas (1C-1) to (1C-37), even more preferably atomic group of Formulas (1C-1) to (1C-37), and even more preferably Formulas (1C-4) to (1C-12).

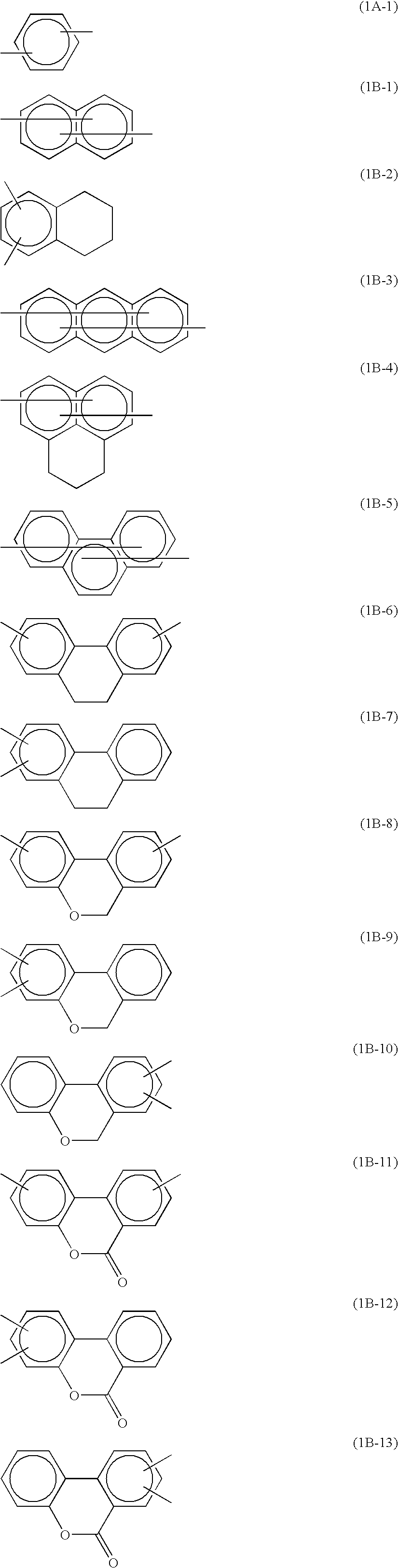

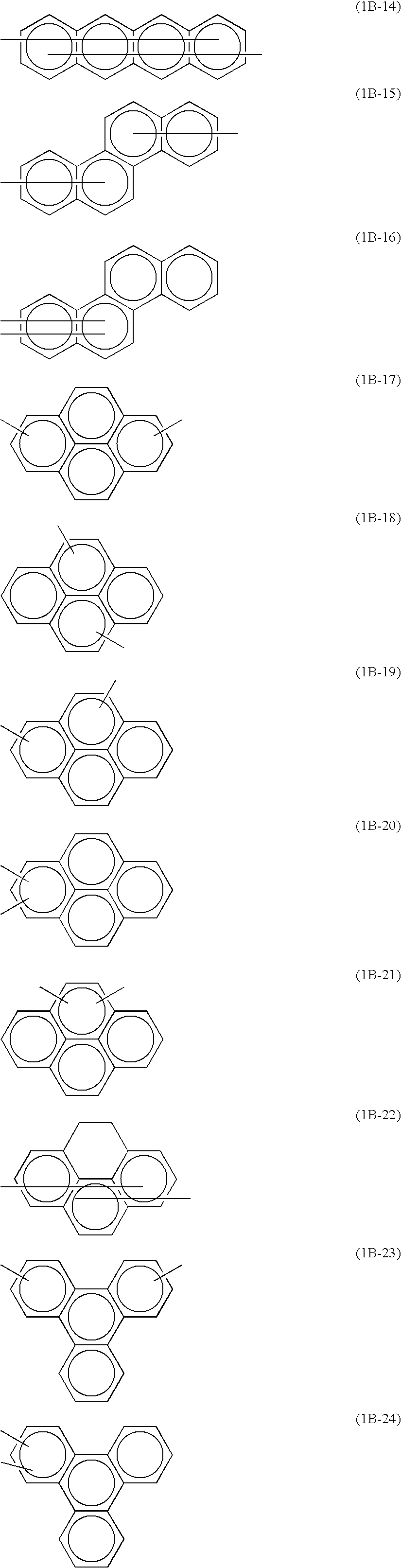

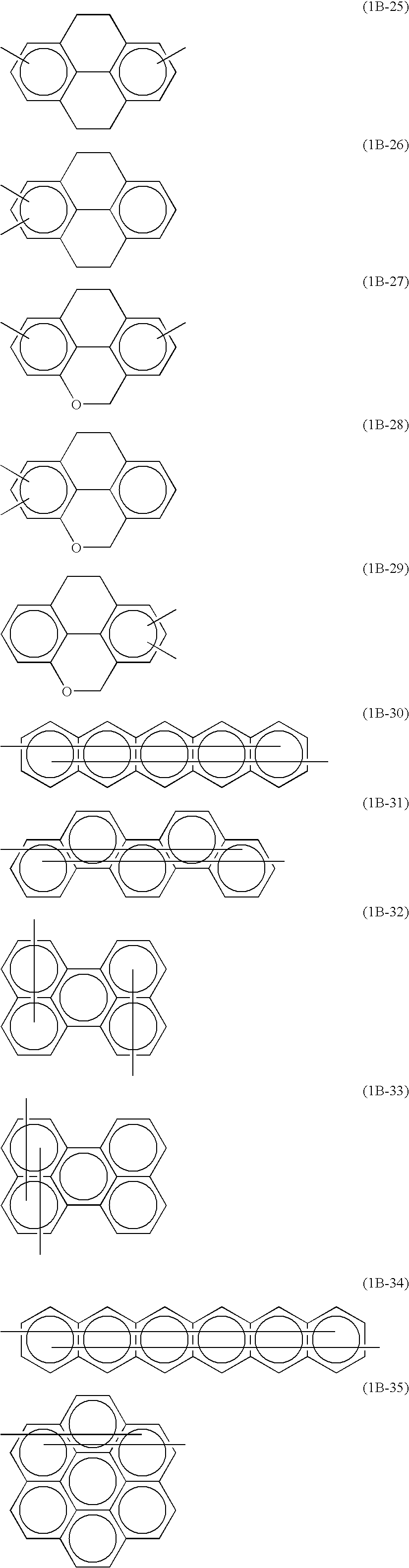

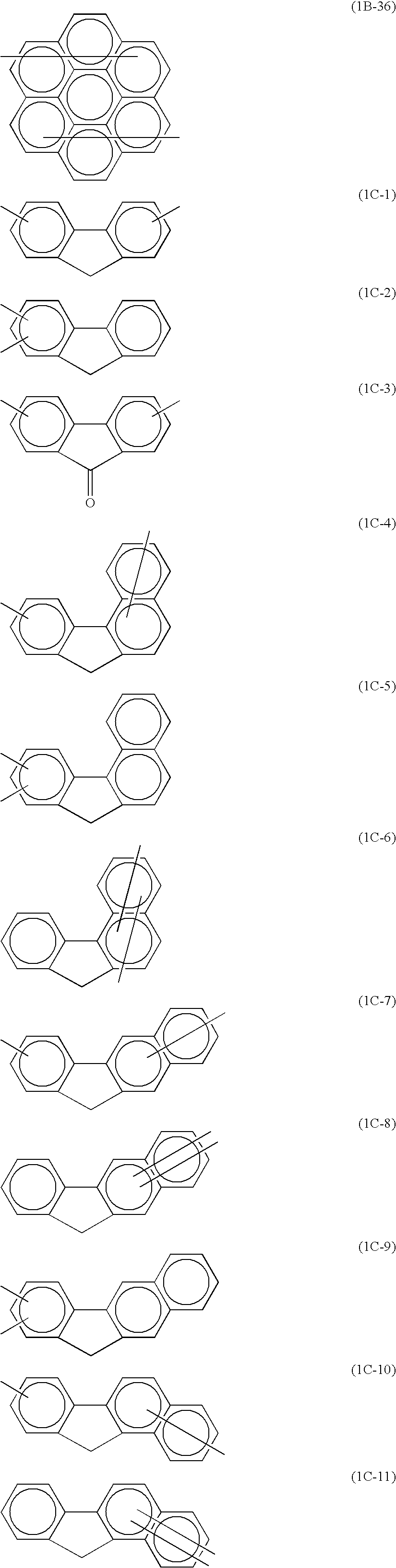

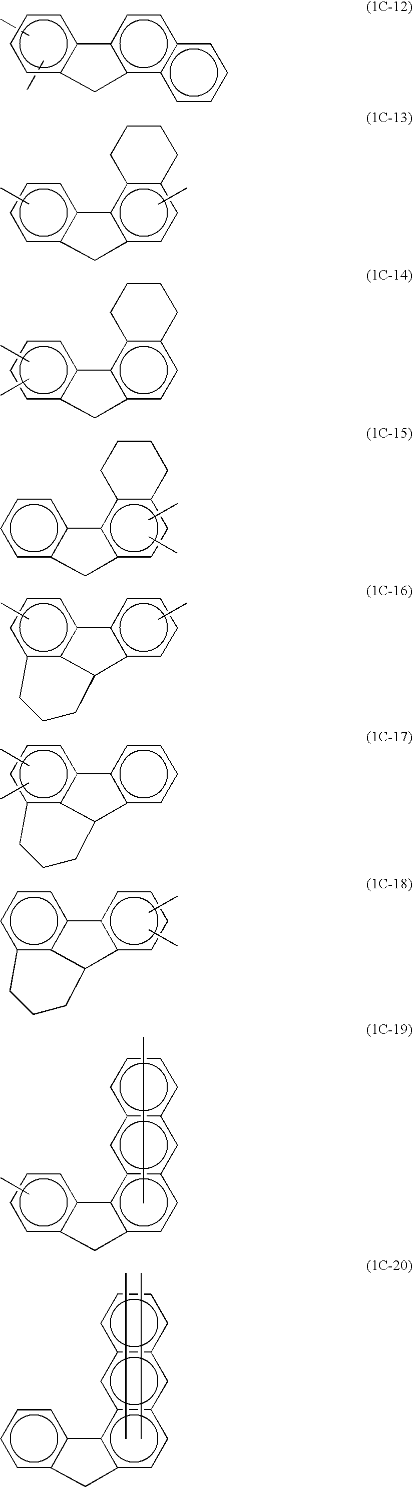

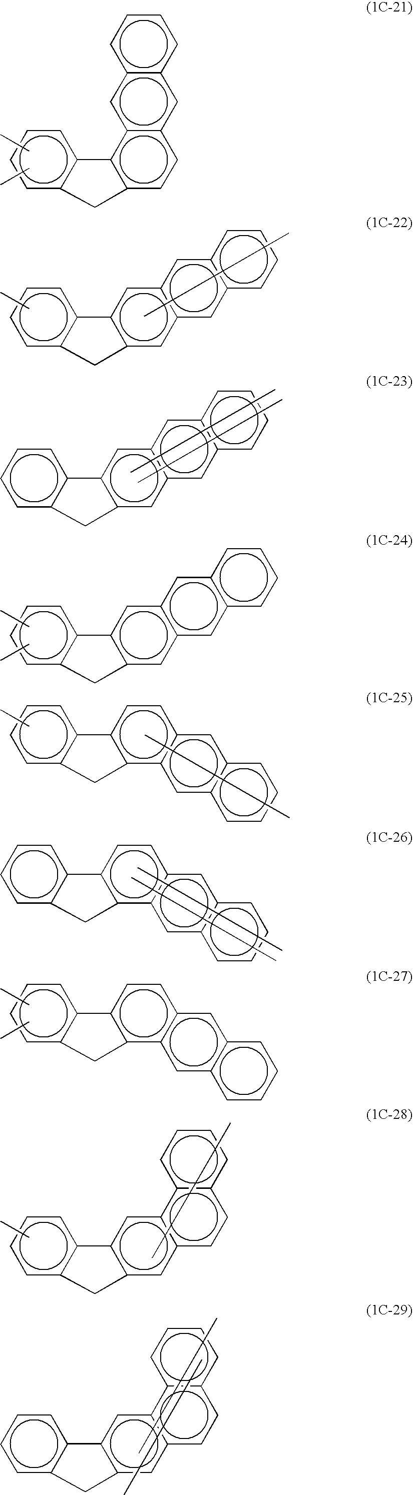

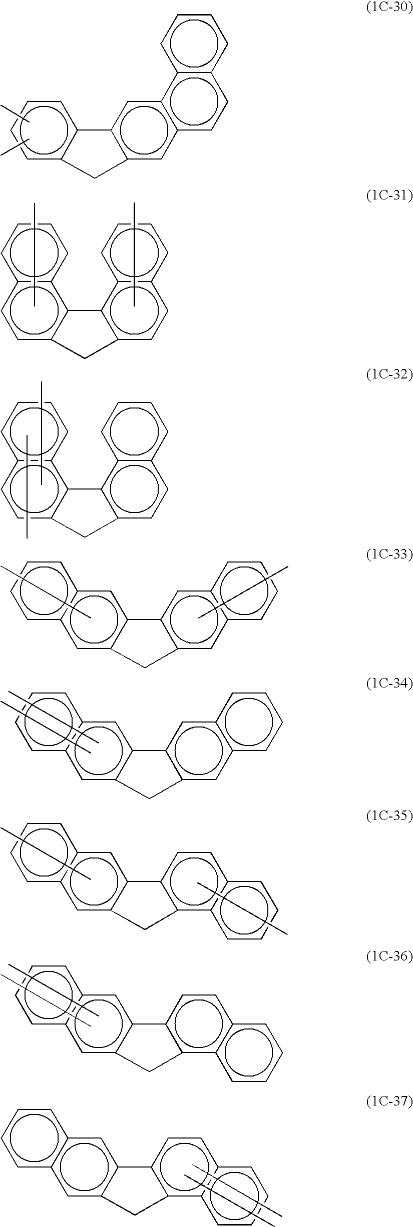

In Formula (1), R¹ represents a substituent on Ar¹, and each represents independently a hydrocarbon group, hydrocarbon oxy group, hydrocarbon thio group, trialkylsilyl group, halogen atom, nitro group, cyano group, hydroxyl group, mercapto group, acyl group, formyl group, carboxyl group, hydrocarbon oxycarbonyl group, amino group, aminocarbonyl group, imidoyl group, azo group, acyloxy group, phosphonic acid group or sulfonic acid group.

In Formula (1), the hydrocarbon group in R¹ is, for example, a straight chain, branched, or ring-shaped alkyl group having approximately 1-50 carbons in total, such as methyl group, ethyl group, propyl group, isopropyl group, butyl group, isobutyl group, t-butyl group, pentyl group, cyclopentyl group, hexyl group, cyclohexyl group, norbonyl group, nonyl group, decyl group, 3,7-dimethyl octyl group, and the like; an aryl group having approximately 6-60 carbons in total such as phenyl group, 4-methyl phenyl group, 4-isopropyl phenyl group, 4-butyl phenyl group, 4-t-butyl phenyl group, 4-hexyl phenyl group, 4-cyclohexyl phenyl group, 4-adamantyl phenyl group, 4-phenyl phenyl group, 1-naphthyl group, 2-naphthyl group, and the like; an aralkyl group having approximately 7-50 carbons in total such as phenyl methyl group, 1-phenyl ethyl group, 2-phenyl ethyl group, 1-phenyl-1-propyl group, 1-phenyl 2-propyl group, 2-phenyl-2-propyl group, 1-phenyl-3-propyl group, 1-phenyl-4-butyl group, 1-phenyl-5-pentyl group, 1-phenyl-6-hexyl group, and the like.

This hydrocarbon group is preferably a hydrocarbon group having 1-30 carbons, more preferably this is a hydrocarbon group having 1-22 carbons, and even more preferably a hydrocarbon group having 1-16 carbons.

This hydrocarbon group can be further substituted with a hydrocarbon thio group, trialkylsilyl group, halogen atom, nitro group, cyano group, hydroxyl group, mercapto group, acyl group, formyl group, carboxyl group, hydrocarbon oxycarbonyl group, amino group, aminocarbonyl group, imidoyl group, azo group, phosphonic acid group, and sulfonic acid group.

For the hydrocarbon thio group that can be substituted in the hydrocarbon group in R¹ of Formula (1), examples include hydrocarbon thio groups having approximately 1-50 carbons in total, such as methyl thio group, ethyl thio group, propyl thio group, isopropyl thio group, butyl thio group, isobutyl thio group, t-butyl thio group, pentyl thio group, hexyl thio group, cyclohexyl thio group, heptyl thio group, cyclohexyl methyl thio group, octyl thio group, 2-ethyl hexyl thio group, nonyl thio group, dodecyl thio group, pentadecyl thio group, octadecyl thio group, docosil thio group, phenyl thio group, 4-butyl phenyl thio group, and the like.

This hydrocarbon thio group preferably has 1-30 carbons, more preferably 1-22 carbons, and even more preferably 1-16 carbons.

For the alkyl group of the trialkylsilyl group that can be substituted in the hydrocarbon group in R¹ of Formula (1), examples include an alkyl group having approximately 1-50 carbons, such as methyl group, ethyl group, propyl group, isopropyl group, butyl group, isobutyl group, t-butyl group, pentyl group, hexyl group, nonyl group, dodecyl group, pentadecyl group, octadecyl group, docosil group, and the like. The three alkyl groups of the trialkylsilyl group can be the same or different from each other.

For the halogen atom that can be substituted in the hydrocarbon group in R¹ of Formula (1), examples include fluorine atom, chlorine atom, bromine ion, and iodine atom.

For the acyl group that can be substituted in the hydrocarbon group in R¹ of Formula (1), examples include acyl groups having approximately 2-30 carbons in total such as acetyl group, propanoyl group, hexanoyl group, octanoyl group, 2-ethyl hexanoyl group, benzoyl group, 4-butyl benzoyl group and the like.

For the hydrocarbon oxycarbonyl group that can be substituted in the hydrocarbon group in R¹ of Formula (1), examples include hydrocarbon oxycarbonyl group having approximately 1-30 carbons in total, such as methoxy carbonyl group, ethoxy carbonyl group, n-butoxy carbonyl group, t-butoxy carbonyl group, cyclohexyl methyl oxy carbonyl group, n-octyl oxy carbonyl group, phenyl oxy carbonyl group, 4-butyl phenyl oxy carbonyl group and the like.

For the amino group that can be substituted in the hydrocarbon group in R¹ of Formula (1), the two hydrogen atoms on the nitrogen atom can be substituted each independently with a hydrocarbon group, acyl group, or hydrocarbon oxycarbonyl group. Examples of the hydrocarbon group, acyl group, and hydrocarbon oxycarbonyl group are the same as those described above.

The amino carbonyl group that can be substituted in the hydrocarbon group in R¹ of Formula (1) has approximately 1-30 carbons in total and is a carbonyl group with a substitution of an amino group described previously.

For the imidoyl group that can be substituted in the hydrocarbon group in R¹ of Formula (1), examples include an imidoyl group having approximately 1-30 carbons in total, such as formimidoyl group, acetoimidoyl group, propion imidoyl group, benzimidoyl group, N-methyl acetoimidoyl group, N-phenyl acetoimidoyl group, and the like.

For the azo group that can be substituted in the hydrocarbon group in R¹ of Formula (1), examples include an azo group having approximately 1-30 carbons in total, such as diazenyl group, methyl azo group, propyl azo group, phenyl azo group, and the like.

For the hydrocarbon oxy group in R¹ of Formula (1), examples include a straight chain, branched, or ring-shaped alkyl oxy group having approximately 1-50 carbons in total, such as methyl oxy group, ethyl oxy group, propyl oxy group, isopropyl oxy group, butyl oxy group, isobutyl oxy group, t-butyl oxy group, pentyl oxy group, hexyl oxy group, cyclohexyl oxy group, and the like; an aryl oxy group having approximately 6-60 carbons in total such as phenoxy group, 4-methyl phenoxy group, 4-propyl phenoxy group, 4-isopropyl phenoxy group, 4-butyl phenoxy group, 4-t-butyl phenoxy group, 4-hexyl phenoxy group, 4-cyclohexyl phenoxy group, 4-phenoxy phenoxy group, 1-naphthyl oxy group, 2-naphthyl oxy group, and the like; an aralkyl oxy group having approximately 7-60 carbons in total such as phenyl methyl oxy group, 1-phenyl ethyl oxy group, 2-phenyl ethyl oxy group, 1-phenyl-1-propyl oxy group, 1-phenyl-2-propyl oxy group, 2-phenyl-2-propyl oxy group, 1-phenyl-3-propyl oxy group, 1-phenyl-4-butyl oxy group, 1-phenyl-5-pentyl oxy group, 1-phenyl-6-hexyl oxy group, and the like.

This hydrocarbon oxy group is preferably a hydrocarbon oxy group having 1-40 carbons, more preferably this is a hydrocarbon oxy group having 1-30 carbons, and even more preferably this is a hydrocarbon oxy group having 1-20 carbons.

This hydrocarbon oxy group can be further substituted with hydrocarbon oxy group, hydrocarbon thio group, trialkylsilyl group, halogen atom, nitro group, cyano group, hydroxyl group, mercapto group, acyl group, formyl group, carboxyl group, hydrocarbon oxycarbonyl group, amino group, amino carbonyl group, imidoyl group, azo group, phosphonic acid group, and sulfonic acid group.

Examples of the hydrocarbon oxy group, hydrocarbon thio group, trialkylsilyl group, halogen atom, acyl group, hydrocarbon oxycarbonyl group, amino group, amino carbonyl group, imidoyl group, and azo group are the same as those described above.

For the hydrocarbon thio group in R¹ of the Formula (1), examples include hydrocarbon thio group having approximately 1-50 carbons in total, such as methyl thio group, ethyl thio group, propyl thio group, isopropyl thio group, butyl thio group, isobutyl thio group, t-butyl thio group, pentyl thio group, hexyl thio group, cyclohexyl thio group, heptyl thio group, cyclohexyl methyl thio group, octyl thio group, 2-ethyl hexyl thio group, nonyl thio group, dodecyl thio group, pentadecyl thio group, octadecyl thio group, docosil thio group, phenyl thio group, 4-butyl phenyl thio group, and the like.

This hydrocarbon thio group preferably has 1-30 carbons, more preferably 1-22 carbons, and even more preferably 1-16 carbons.

This hydrocarbon thio group can be further substituted with hydrocarbon oxy group, hydrocarbon thio group, trialkylsilyl group, halogen atom, nitro group, cyano group, hydroxyl group, mercapto group, acyl group, formyl group, carboxyl group, hydrocarbon oxycarbonyl group, amino group, amino carbonyl group, imidoyl group, azo group, phosphonic acid group, or sulfonic acid group.

Examples of the hydrocarbon oxy group, hydrocarbon thio group, trialkylsilyl group, halogen atom, acyl group, hydrocarbon oxycarbonyl group, amino group, amino carbonyl group, imidoyl group, and azo group are the same as those described above.

For the alkyl group of the trialkylsilyl group of the R¹ of Formula (1), examples include an alkyl group having approximately 1-50 carbons, such as methyl group, ethyl group, propyl group, isopropyl group, butyl group, isobutyl group, t-butyl group, pentyl group, hexyl group, nonyl group, dodecyl group, pentadecyl group, octadecyl group, docosil group, and the like. The three alkyl groups of the trialkylsilyl group can be the same or different from each other.

For the halogen atom in the R¹ of Formula (1), examples include fluorine atom, chlorine atom, bromine atom, and iodine atom.

For the acyl group in the R¹ of Formula (1), examples include an acyl group having approximately 2-50 carbons in total such as acetyl group, propanoyl group, butanoyl group, cyclohexyl acetyl group, benzoyl group, 4-butyl benzoyl group and the like.

This acyl group preferably has 2-30 carbons, more preferably 2-22 carbons, and even more preferably 2-16 carbons.

This acyl group can be further substituted with a hydrocarbon oxy group, hydrocarbon thio group, trialkylsilyl group, halogen atom, nitro group, cyano group, hydroxyl group, mercapto group, acyl group, formyl group, carboxyl group, hydrocarbon oxycarbonyl group, amino group, amino carbonyl group, imidoyl group, azo group, phosphonic acid group, or sulfonic acid group.

Here, examples of the hydrocarbon oxy group, hydrocarbon thio group, trialkylsilyl group, halogen atom, acyl group, hydrocarbon oxycarbonyl group, amino group, amino carbonyl group, imidoyl group, and azo group are the same as those described above.

For the hydrocarbon oxycarbonyl group in the R¹ of Formula (1), examples include hydrocarbon oxycarbonyl group having approximately 2-50 carbons in total, such as methoxy carbonyl group, ethoxy carbonyl group, n-butoxy carbonyl group, t-butoxy carbonyl group, cyclohexyl methyl oxy carbonyl group, n-octyl oxy carbonyl group, phenyl oxy carbonyl group, 4-butyl phenyl oxy carbonyl group, 1-naphthyl oxy carbonyl group and the like.

This hydrocarbon oxycarbonyl group preferably has 2-30 carbons, more preferably 2-22 carbons, and even more preferably 2-16 carbons.

This hydrocarbon oxycarbonyl group can be further substituted with a hydrocarbon oxy group, hydrocarbon thio group, trialkylsilyl group, halogen atom, nitro group, cyano group, hydroxyl group, mercapto group, acyl group, formyl group, carboxyl group, hydrocarbon oxycarbonyl group, amino group, amino carbonyl group, imidoyl group, azo group, phosphonic acid group, or sulfonic acid group.

Here, examples of the hydrocarbon oxy group, hydrocarbon thio group, trialkylsilyl group, halogen atom, acyl group, hydrocarbon oxycarbonyl group, amino group, amino carbonyl group, imidoyl group, and azo group are the same as those described above.

For the amino group in R¹ of Formula (1), the two hydrogen atoms on the nitrogen atom can be substituted each independently with a hydrocarbon group, acyl group, or hydrocarbon oxycarbonyl group, and have approximately 0-50 carbons in total. Examples of the hydrocarbon group and acyl group are the same as those described above.

This amino group preferably has 0-30 carbons, more preferably 0-22 carbons, and even more preferably 0-16 carbons.

The amino carbonyl group in R¹ of Formula (1) is a carbonyl group with a substitution of an amino group as described previously and has a approximately 1-50 carbons in total.

This amino carbonyl group preferably has 1-30 carbons, more preferably 1-22 carbons, and even more preferably 1-16 carbons.

For the imidoyl group in R¹ of Formula (1), examples include an imidoyl group having approximately 1-50 carbons in total, such as formimidoyl group, aceto imidoyl group, propion imidoyl group, benzimidoyl group, N-methyl aceto imidoyl group, N-phenyl aceto imidoyl group, and the like.

This imidoyl group preferably has 1-30 carbons, more preferably 1-22 carbons, and even more preferably 1-16 carbons.

This imidoyl group can be further substituted with a hydrocarbon oxy group, hydrocarbon thio group, trialkylsilyl group, halogen atom, nitro group, cyano group, hydroxyl group, mercapto group, acyl group, formyl group, carboxyl group, hydrocarbon oxycarbonyl group, amino group, amino carbonyl group, imidoyl group, azo group, phosphonic acid group, or sulfonic acid group.

Here, examples of the hydrocarbon oxy group, hydrocarbon thio group, trialkylsilyl group, halogen atom, acyl group, hydrocarbon oxycarbonyl group, amino group, amino carbonyl group, imidoyl group, and azo group are the same as those described above.

For the azo group in R¹ of Formula (1), examples include an azo group having approximately 1-50 carbons in total, such as methyl azo group, propyl azo group, phenyl azo group, and the like.

This azo group preferably has 1-30 carbons, more preferably 1-22 carbons, and even more preferably 1-16 carbons.

This azo group can be further substituted with a hydrocarbon oxy group, hydrocarbon thio group, trialkylsilyl group, halogen atom, nitro group, cyano group, hydroxyl group, mercapto group, acyl group, formyl group, carboxyl group, hydrocarbon oxycarbonyl group, amino group, amino carbonyl group, imidoyl group, azo group, phosphonic acid group, or sulfonic acid group.

Here, examples of the hydrocarbon oxy group, hydrocarbon thio group, trialkylsilyl group, halogen atom, acyl group, hydrocarbon oxycarbonyl group, amino group, amino carbonyl group, imidoyl group, and azo group are the same as those described above.

For the acyloxy group in R¹ of Formula (1), examples include an acyloxy group having approximately 1-50 carbons in total, such as acetyl oxy group, butyl oxy group, octanoyl oxy group, 2-ethyl hexanoyl oxy group, benzoyl oxy group, 4-butyl benzoyl oxy group, and the like.

This acyloxy group preferably has 2-30 carbons, more preferably 2-22 carbons, and even more preferably 2-16 carbons.

This acyloxy group can be further substituted with a hydrocarbon oxy group, hydrocarbon thio group, trialkylsilyl group, halogen atom, nitro group, cyano group, hydroxyl group, mercapto group, acyl group, formyl group, carboxyl group, hydrocarbon oxycarbonyl group, amino group, amino carbonyl group, imidoyl group, azo group, phosphonic acid group, or sulfonic acid group.

Here, examples of the hydrocarbon oxy group, hydrocarbon thio group, trialkylsilyl group, halogen atom, acyl group, hydrocarbon oxycarbonyl group, amino group, amino carbonyl group, imidoyl group, and azo group are the same as those described above.

From the standpoint of stability, the R¹ in Formula (1) is preferably a hydrocarbon group, a hydrocarbon oxy group, hydrocarbon thio group, trialkylsilyl group, halogen atom, nitro group, cyano group, hydroxyl group, mercapto group, acyl group, carboxyl group, phosphonic acid group, sulfonic acid group. More preferably, it is a hydrocarbon group, hydrocarbon oxy group, hydrocarbon thio group, trialkylsilyl group, nitro group, cyano group, and acyl group, and even more preferably, it is a hydrocarbon group, hydrocarbon oxy group.

The n in Formula (1) represents an integer from 0 to 30. The number n is preferably an integer from 0 to 20, more preferably an integer from 0 to 10, and even more preferably an integer from 0 to 5. When n represents an integer of 2 or greater, the plurality of R¹ may be the same or different from each other.

When Ar¹ in Formula (1) is an atomic group in which two hydrogen atoms have been removed from a benzene ring, n represents an integer from 1 to 4. The number n at this time is preferably an integer from 1 to 3, more preferably, n is an integer from 1 to 2, even more preferably n is 1. When n is 1, the polyarylene of the present invention has a structure which more readily shows the effect of the regioregularity of the head-tail bond.

When Ar¹ in Formula (1) is the remaining atomic group when two hydrogen atoms bonded to carbon atoms of aromatic rings of a condensed ring which contains 1 or more aromatic rings are removed, and in addition when two R¹ are present on the sp³ carbon in Ar¹, the two R¹ can form a spiro ring with each other.

Following the IUPAC organic chemistry nomenclature method described in rule A-13 and rule A-24 in the organic chemistry/biochemistry nomenclature method (volume one) (revised second edition, Nankodo, 1988), when the carbon atoms of the repeating unit represented by Formula (1) are assigned numbers as a divalent group, of the two carbon atoms with the free atomic valences, the carbon atom with the smaller number is the head, and the carbon atom with the larger number is the tail. As described in the organic chemistry/biochemistry nomenclature method (volume one) (revised second edition, Nankodo, 1988), a free atomic valence is one that can form a bond with another free atom valence.

For example, for a divalent group represented by Formula (2), numbers are assigned to the carbon atoms according to the IUPAC organic chemistry nomenclature method, and when the carbon atom with the number m is represented as C^{m}, this is shown by Formula (2-a) (in Formula (2) and (2-a), R² represents a substituent and represents the same substituents represented by R¹ in Formula (1). In the Formula, m represents an integer of 1 or greater.) In Formula (2-a), the two carbons with free atomic valences are C¹ and C⁴, and of these carbon atoms, the carbon atom with the smaller number, C¹, is the head, and the carbon atom with the larger number, C⁴, is the tail.

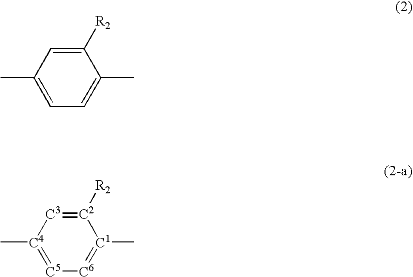

In the present invention, the repeating unit represented by Formula (1) does not have, under any circumstances, a two-fold axis of symmetry intersecting the straight line joining the head and the tail at right angles at the midpoint of this line.

Here, as described in page 633 of Atkins Physical Chemistry (Volume 1) (Fourth edition, Tokyo Kagaku Doujin, 1993), a two-fold axis of symmetry is an axis in which an object that is rotated 180 degrees around the axis appears the same as the original.

For example, with the divalent group represented by Formula (2-a), the midpoint of the line joining the head and tail is a point equidistant from carbon atom C¹ and C⁴ along a line which joins carbon atom C¹ and carbon atom C⁴ within the same divalent group. Here, at the midpoint of the line joining the head and tail, with any straight line which intersects this line at right angles as an axis, when the object is rotated 180 degrees, the object before rotation and the object after rotation do not overlap, and as a result, a two-fold axis of symmetry does not exist under any circumstances. Therefore, the divalent group represented by Formula (2-a) is included as a repeating unit represented by Formula (1).

In addition, for example, for a divalent group represented by Formula (3), numbers are assigned to the carbon atoms according to the IUPAC organic chemistry nomenclature method, and when the carbon atom with the number m is represented as C^{m}, this is shown by Formula (3-a) where m represents an integer of 1 or greater. In Formula (3-a), the two carbon with the free atomic valences are C¹ and C⁴. Of these, the carbon atom with the smaller number, C¹, is the head, and the carbon atom with the larger number, C⁴, is the tail. Here, the line that joins the head and tail is the straight line that joins carbon atom C¹ and carbon atom C⁴ within the same divalent group. With this, at the midpoint of the straight line joining the head and the tail, when the divalent group is rotated 180 degrees around an axis that is a line which intersects at right angles with this line joining the head and tail, the object before rotation and the object after rotation will overlap, and as a result, this axis can become a two-fold axis of symmetry. Therefore, the divalent group represented by Formula (3) is not included as a repeating unit represented by Formula (1).

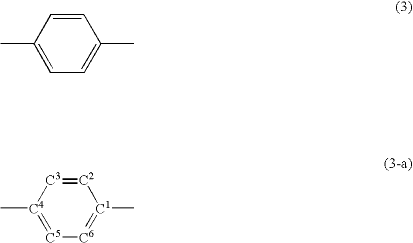

When confirming the presence or absence of a two-fold axis of symmetry described above, this is easier to confirm by thinking of switching the substituent represented by R¹ that is different from R² with the free atomic valence.

For the repeating unit represented by Formula (1) contained in the polyarylene of the present invention, concrete examples are shown with the following Formulas (4A-1) to (4A-9), (4B-1) to (4B-12), (4C-1) to (4C-24), (4D-1) to (4D-25), (4E-1) to (4E-5), (4F-1) to (4F-3), (4G-1) to (4G-10), (4H-1) to (4H-50). R³, R⁴, R⁵ each represent the same substituents as the substituents of R¹ of Formula 1. When a plurality of R³ is present within a single repeating unit, R³ can be each the same or different from each other. When R³ and R⁴ co-exist within the same repeating unit, R³ and R⁴ each represent a different substituent, and when R³, R⁴, and R⁵ co-exist in a single repeating unit, R³, R⁴, and R⁵ each represent a different substituent.

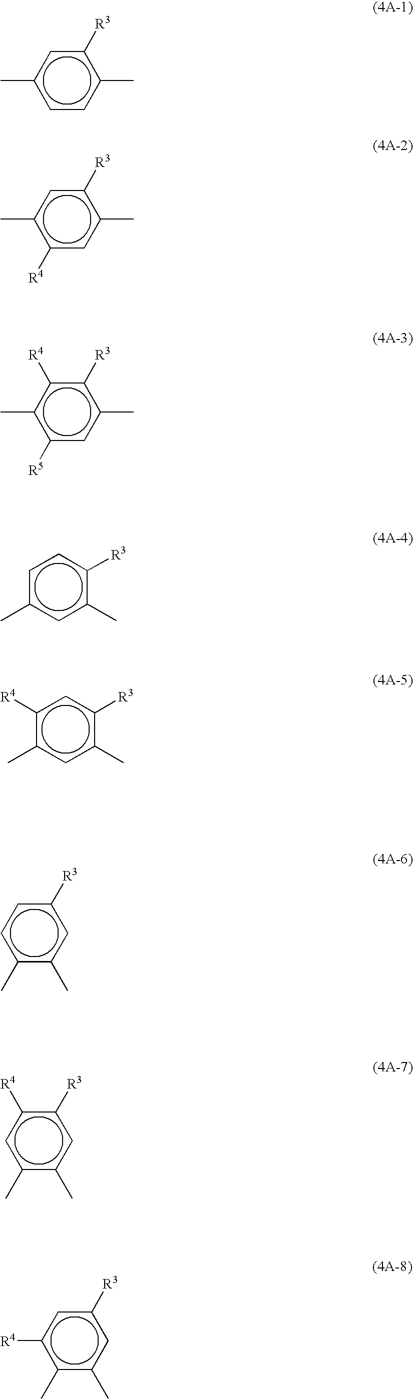

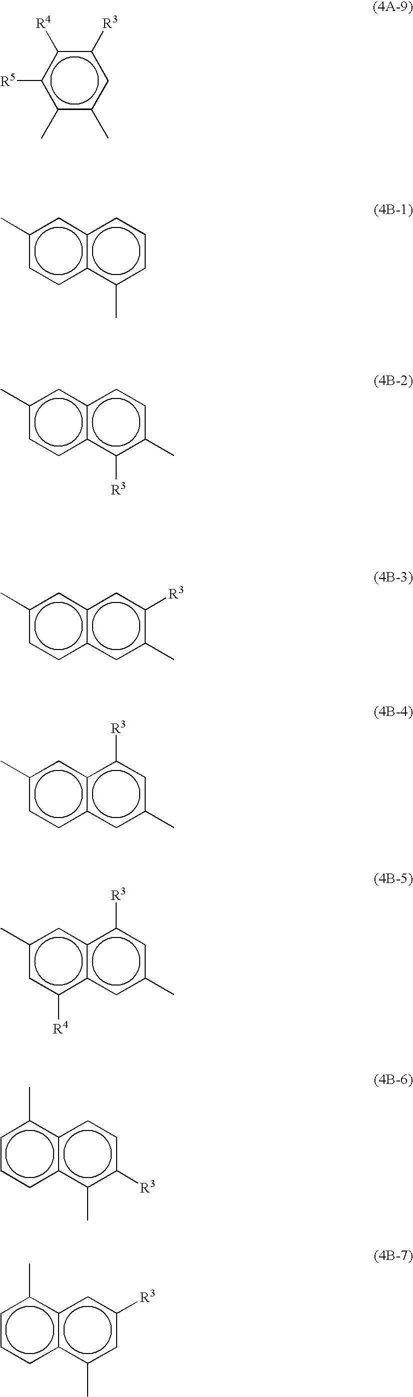

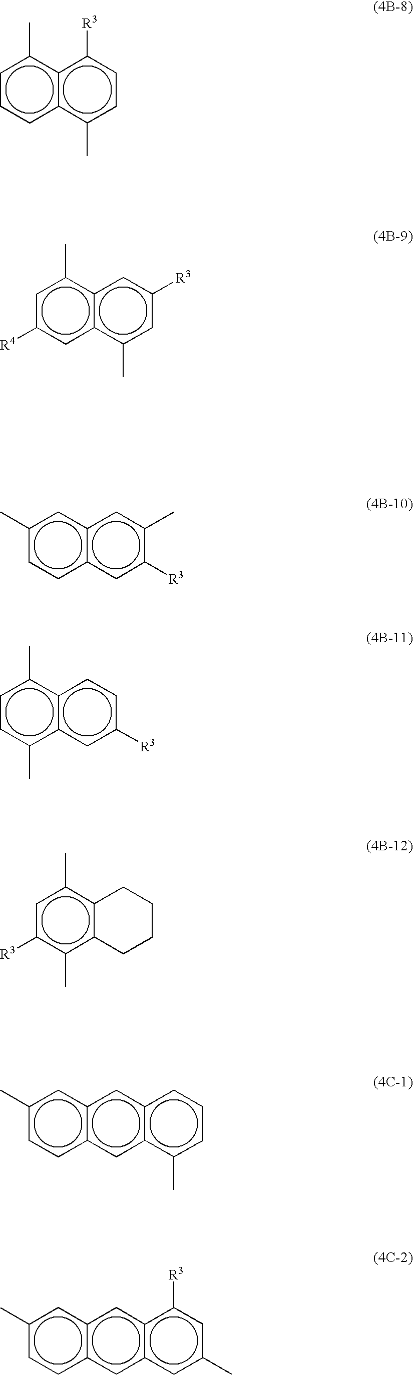

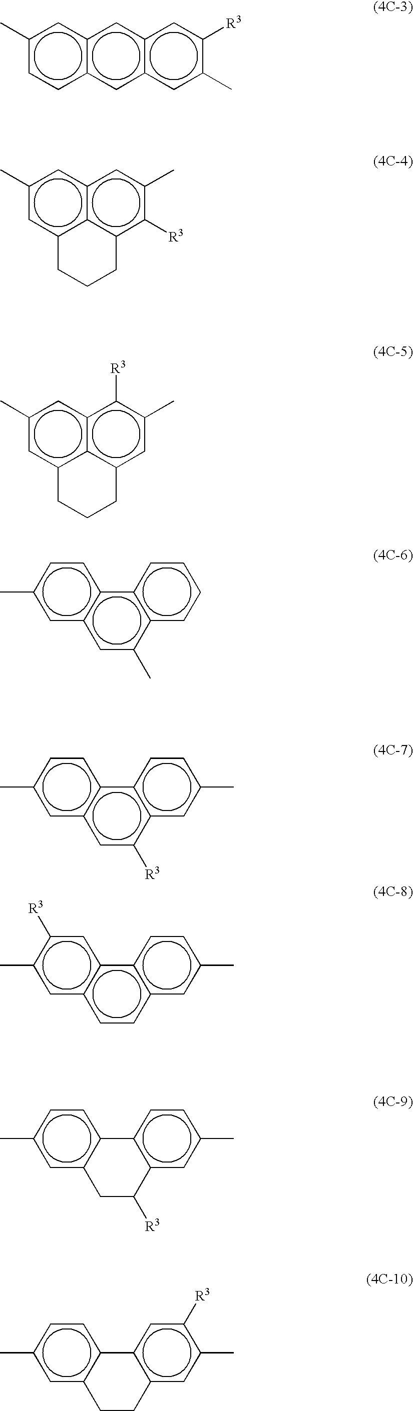

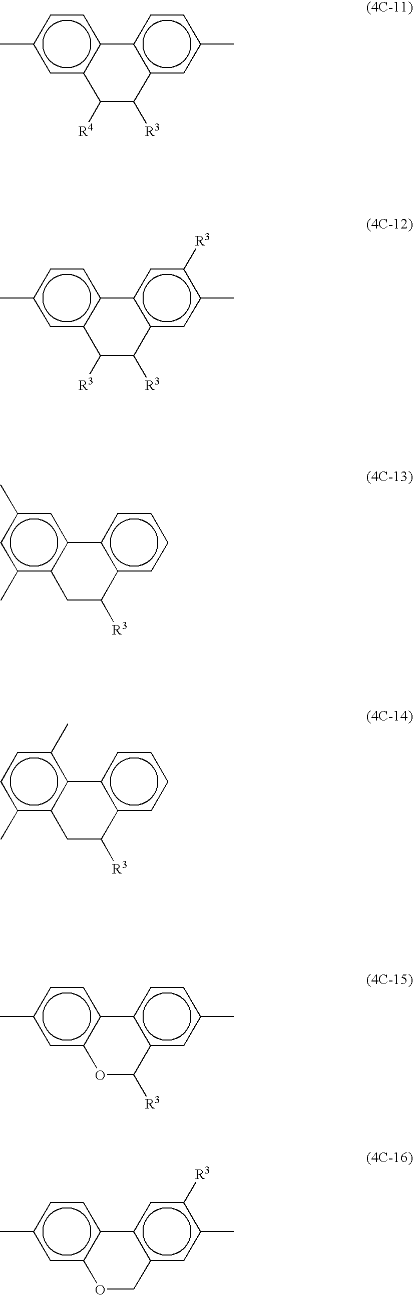

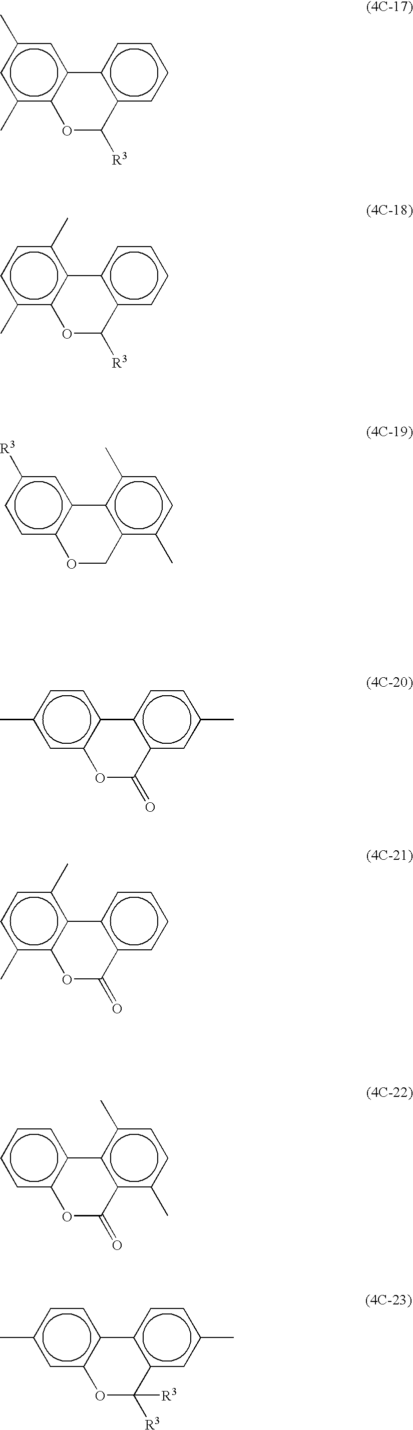

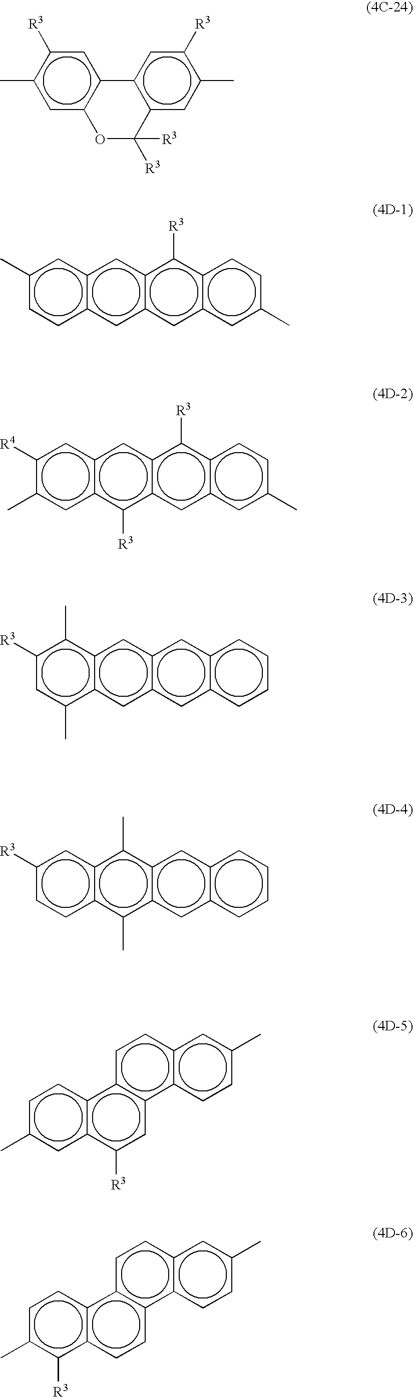

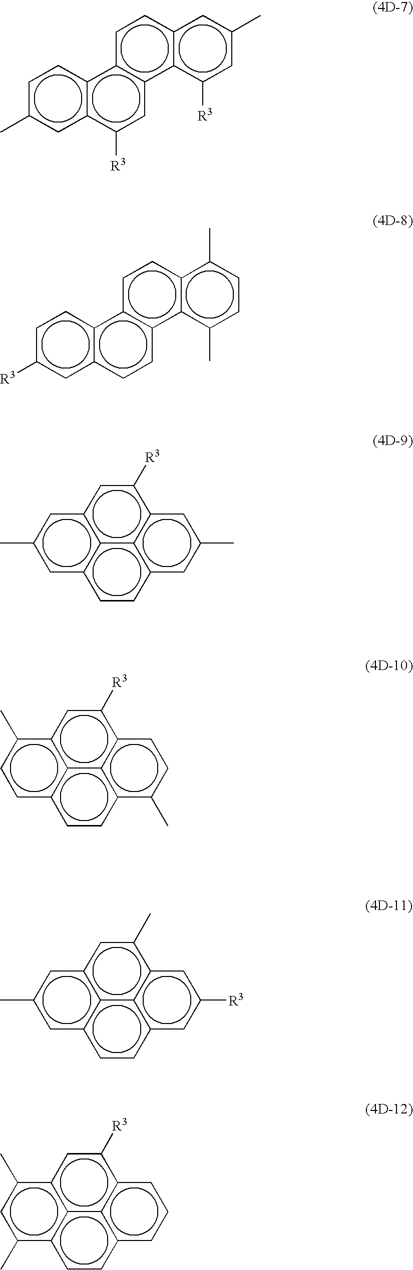

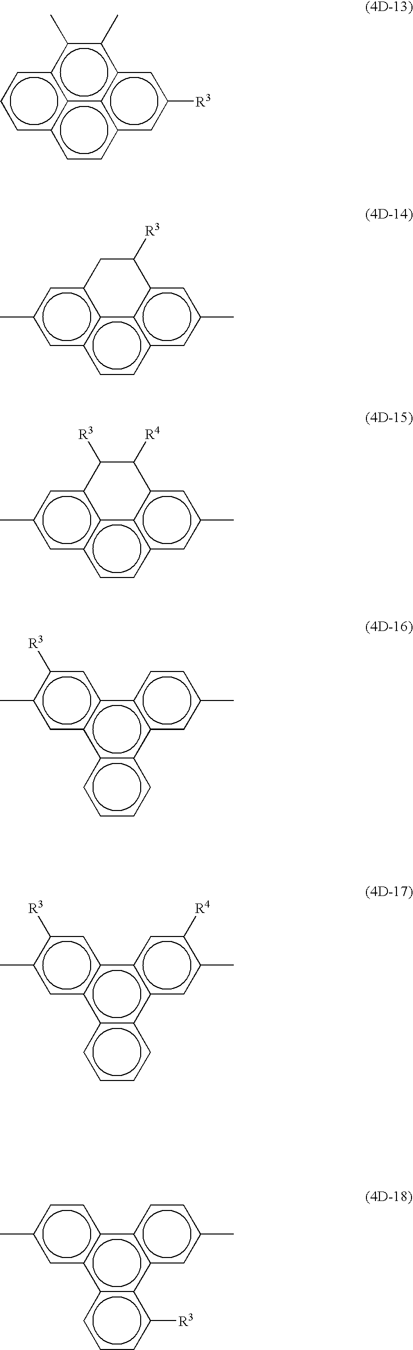

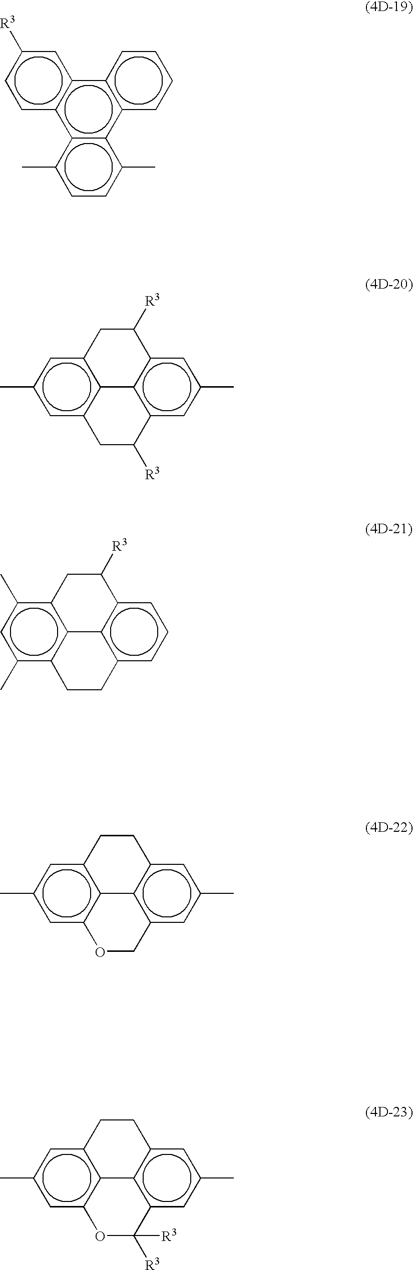

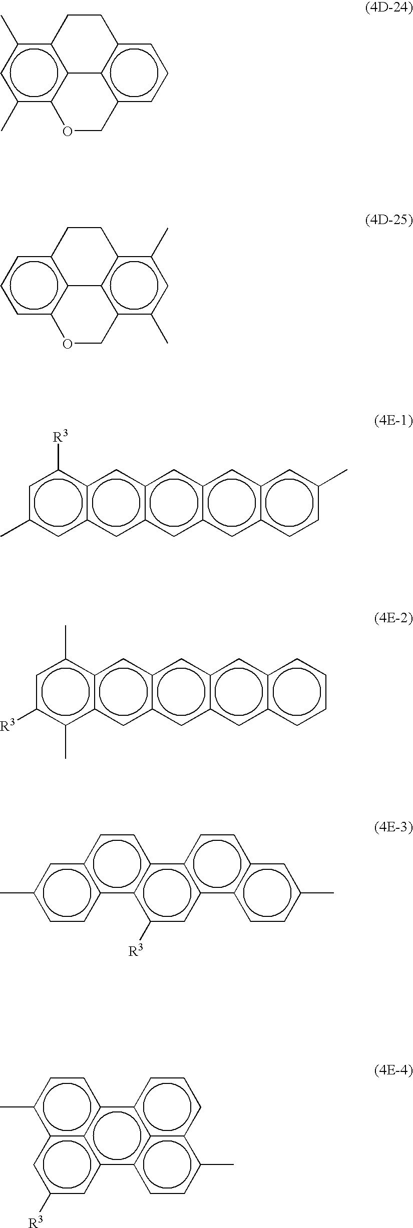

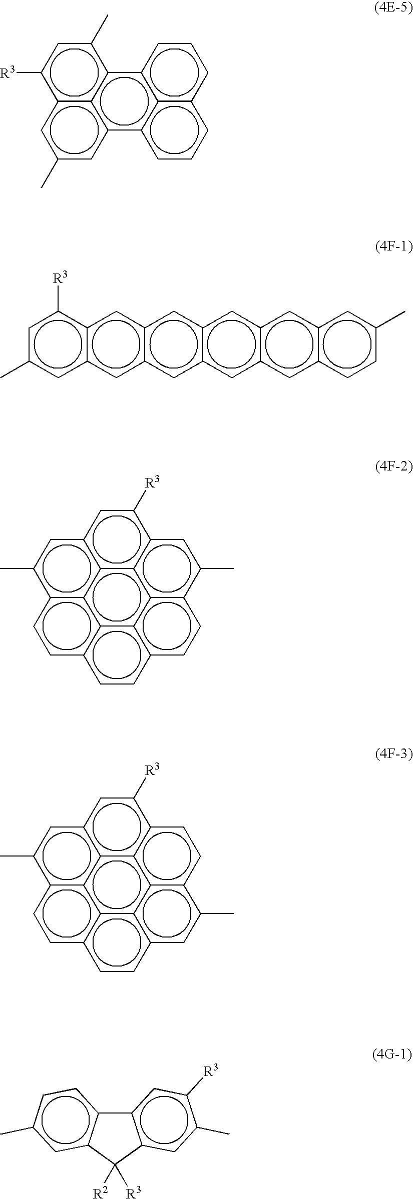

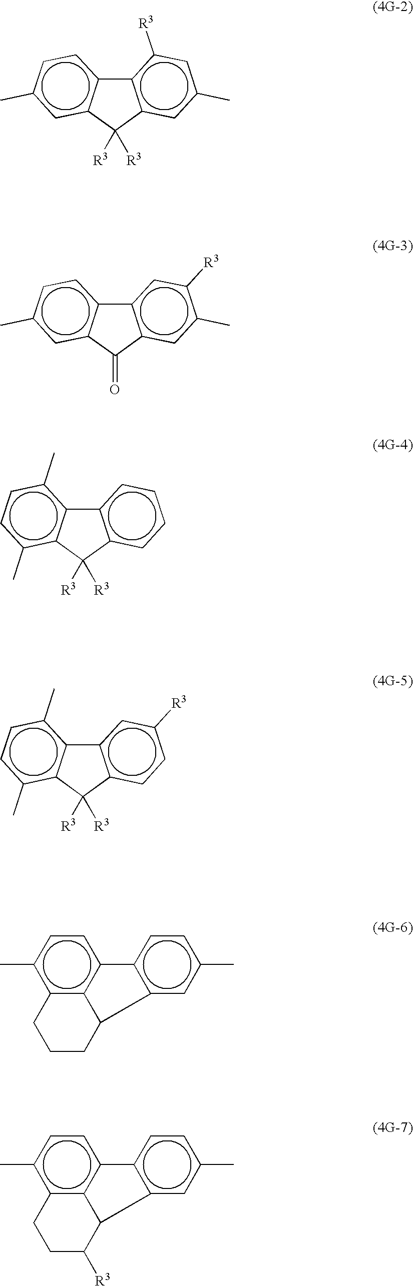

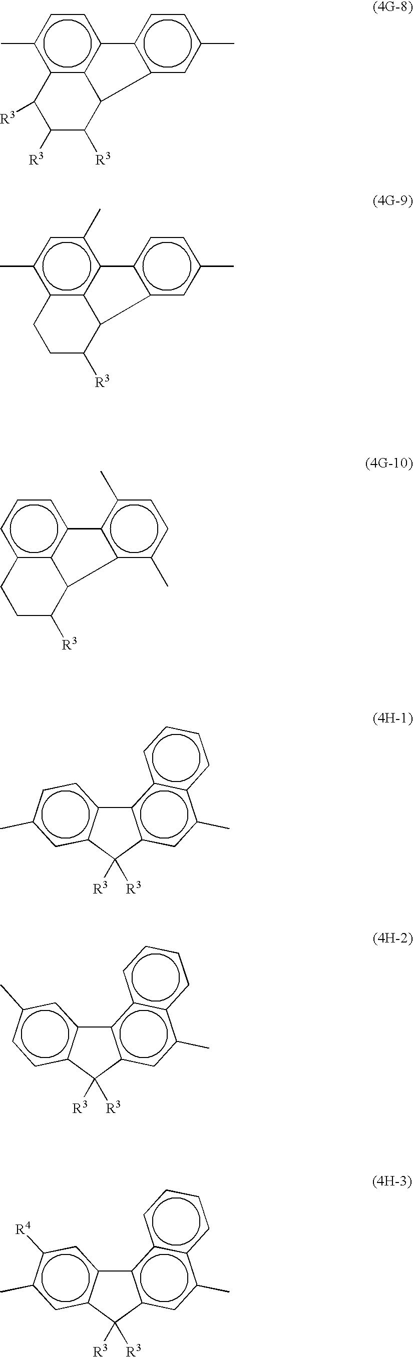

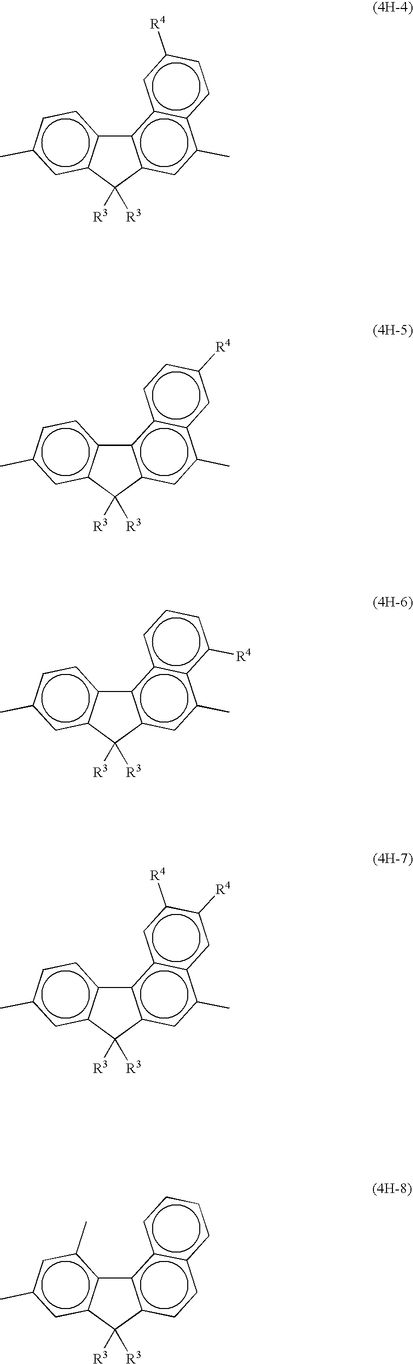

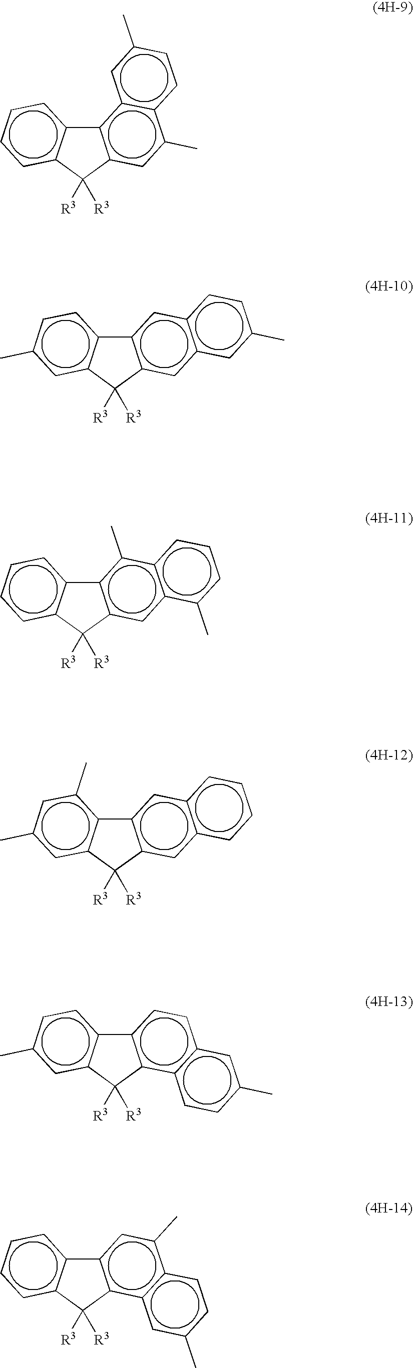

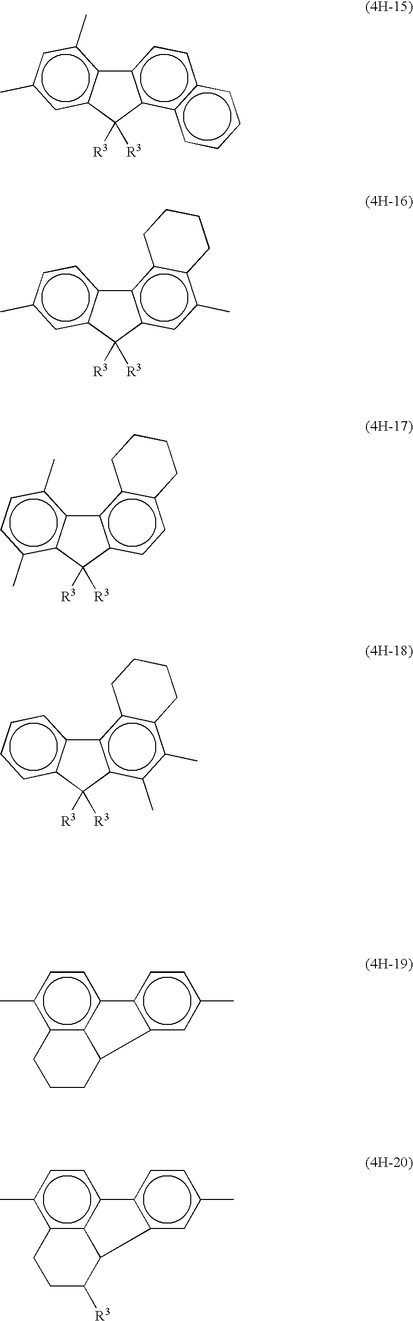

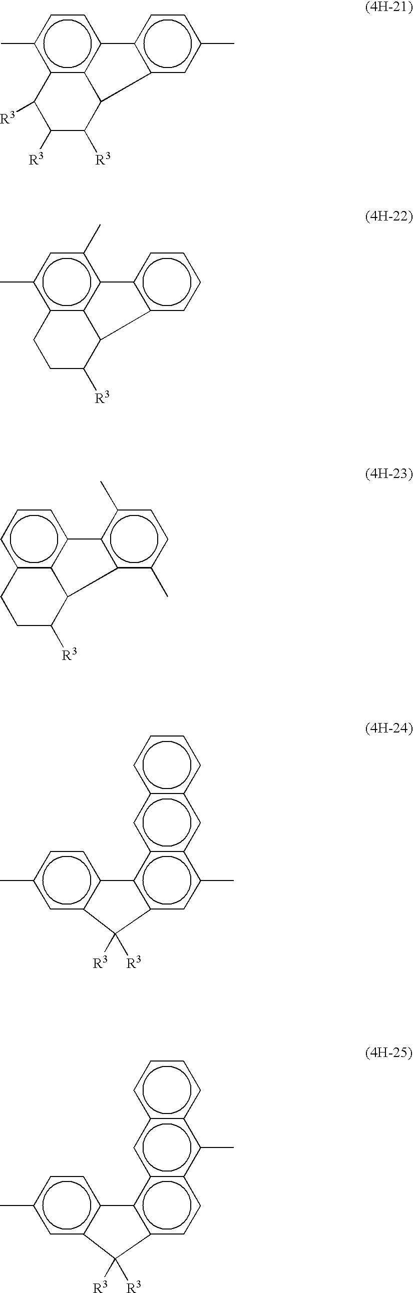

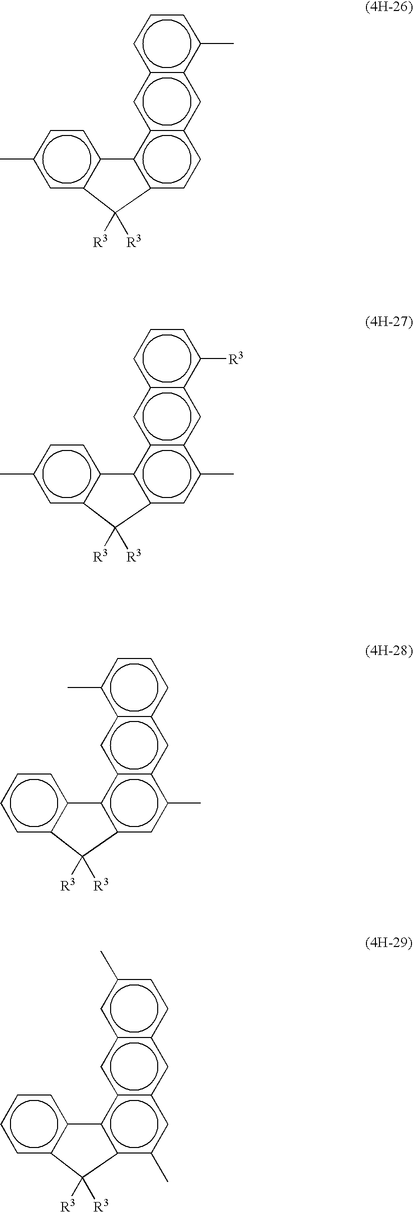

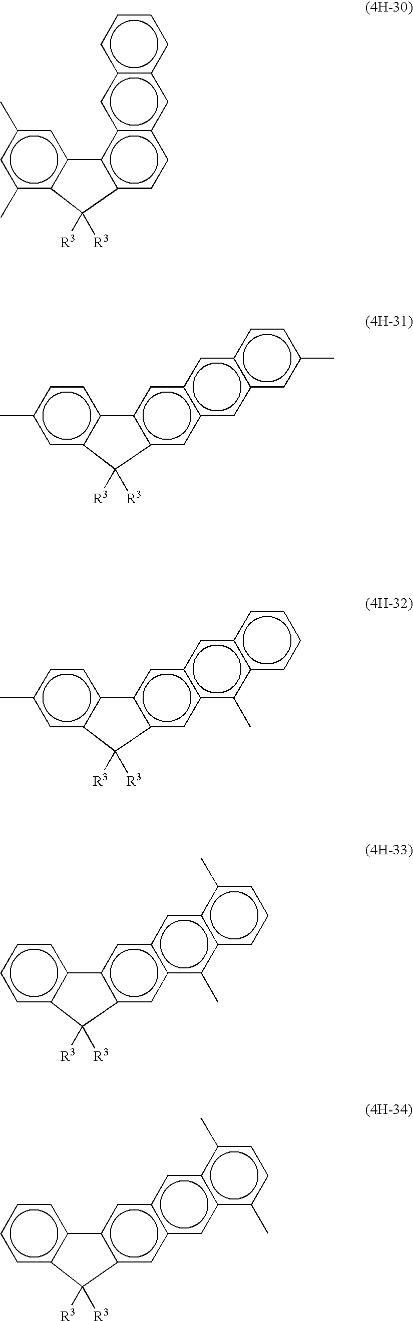

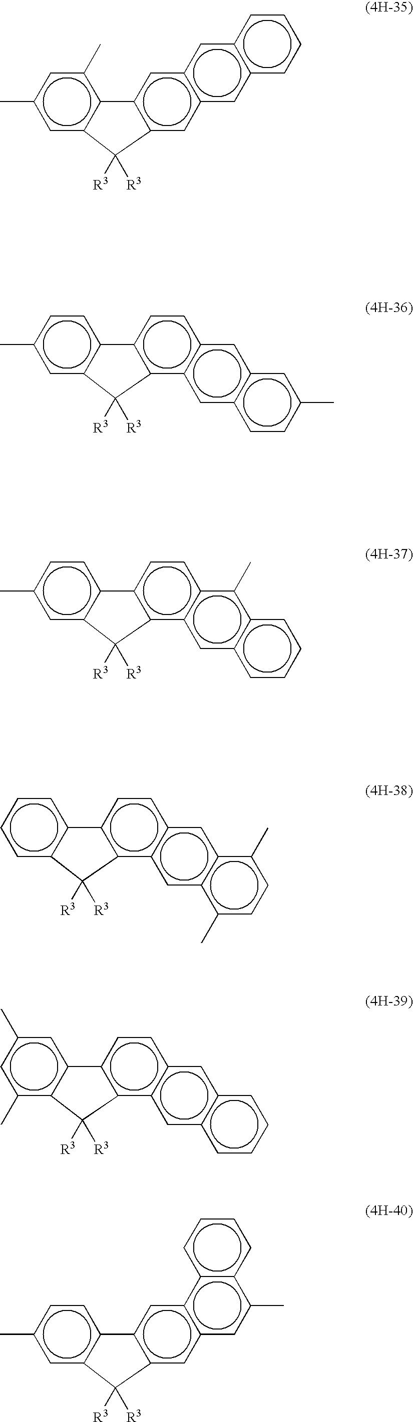

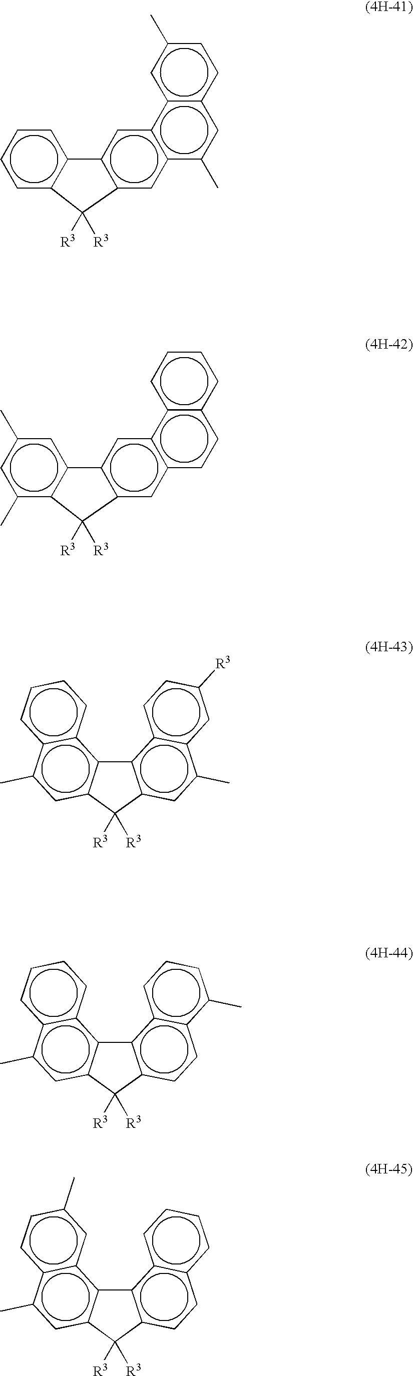

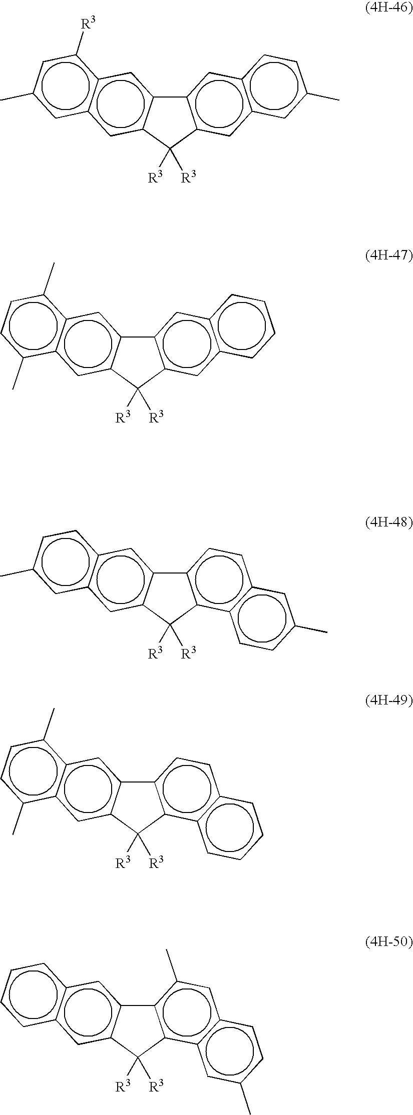

The repeating unit represented by Formula (1) contained in the polyarylene of the present invention is preferably a repeating unit represented by Formulas (4B-1) to (4B-12), (4C-1) to (4C-24), (4D-1) to (4D-25), (4E-1) to (4E-5), (4F-1) to (4F-3), (4G-1) to (4G-10), and (4H-1) to (4H-50), more preferably a repeating unit represented by Formulas (4B-1) to (4B-12), (4C-1) to (4C-24), (4G-1) to (4G-10), and (4H-1) to (4H-50), even more preferably a repeating unit represented by Formulas (4C-15) to (4C-24), (4G-1) to (4G-10), and (4H-1) to (4H-50), even more preferably a repeating unit represented by (4G-1) to (4G-10) and (4H-1) to (4H-50), and even more preferably a repeating unit represented by Formulas (4H-1) to (4H-50).

The polystyrene-reduced number average molecular weight (Mn) by size exclusion chromatography (SEC) of the polyarylene of the present invention is 5.0×10² to 1.0×10⁶. From the standpoint of stability and solubility and the like, it is preferably 1.0×10³ to 5.0×10⁵, and more preferably 2.0×10³ to 2.0×10⁵. In addition, the polystyrene-reduced weight average molecular weight (Mw) by SEC of the polyarylene of the present invention is 1.0×10³ to 2.0×10⁶. From the standpoint of stability, solubility, and membrane formation, and the like, it is preferably 2.0×10³ to 1.0×10⁶, and more preferably 5.0×10³ to 5.0×10⁵.

The polyarylene of the present invention contains a chain of only one type of repeating unit represented by Formula (1), and the average number of repeating units which form this chain (henceforth referred as the average chain number) is 3 or greater.

If the repeating unit contained in the polyarylene of the present invention is only one type of repeating unit represented by Formula (1), the average chain number is represented by the following equation (A1), for example.

Average chain number=Mn/FW₁ (A1)

In equation (A1), Mn is the polystyrene-reduced number average molecular weight measured by SEC of the polyarylene of the present invention. FW₁ is the Formula weight of one type of repeating unit represented by Formula (1).

In addition, in the polyarylene of the present invention, if there is the one type of repeating unit represented by Formula (1) (the repeating unit Q in the following equation (A2)) and another repeating unit other than this repeating unit, then the average chain number (N_{Q}) is represented by the following equation (A2).

Average chain number(N_{Q})=N1/N2 (A2)

In the equation, N1 is the number of repeating units Q contained per unit weight of the polyarylene of the present invention, and N2 is the number of blocks formed by repeating unit Q contained per unit weight of the polyarylene of the present invention. The block formed by the repeating unit Q is represented by the following Formula (BR).

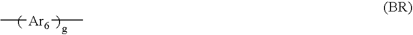

In the Formula, Ar₆ represents one type of repeating unit represented by the Formula (1), and g represents an integer of 1 or greater. A repeating unit or a terminal group other than this repeating unit represented by Ar₆ is adjacent to this block.

From the standpoint of crystallinity, orientation, conductivity, and the like, the lower limit for the average chain number of the polyarylene of the present invention is preferably 5, more preferably 6, even more preferably 7, even more preferably 8, even more preferably 10, even more preferably 12, even more preferably 15, even more preferably 20, even more preferably 30, even more preferably 50, and even more preferably 100.

The upper limit of the average chain number in the polyarylene of the present invention is preferably 5000, more preferably 1000, and even more preferably 500.

In the polyarylene of the present invention, the ratio of bonds formed between the head and the tail to all bonds formed between repeating units of one type represented by Formula (1) must be 85% or greater. From the standpoint of stability, the ratio of bonds formed between the head and the tail to all bonds formed between repeating units of one type represented by Formula (1) is preferably 90% or greater, more preferably 95% or greater, and even more preferably 98% or greater.

As the bond formed between adjacent repeating units, for example, with the repeating unit represented by the above Formula (2), three types of bonds represented by the following Formulas (2-b), (2-c), and (2-d) exist. Of these, the bond shown in Formula (2-b) is the bond formed between the head and tail.

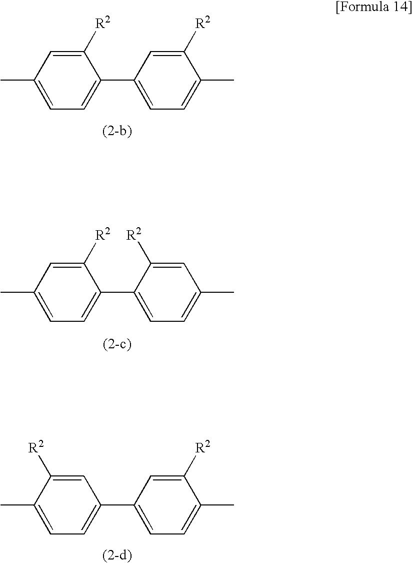

The polyarylene of the present invention contains a chain of only one type of repeating unit represented by Formula (1), and the number of repeating units that form this chain is an average of 3 or greater. Other than this repeating unit, the polyarylene of the present invention can also contain another repeating unit. The total for the one type of repeating unit indicated by Formula (1) is preferably 50 mol % or greater of all repeating units, more preferably 70 mol % or greater, even more preferably 80 mol % or greater, and even more preferably 90 mol % or greater.

Examples of repeating units contained in the polyarylene of the present invention other than the repeating unit represented by Formula (1) are shown in the following Formulas (5), (6), (7), and (8). The repeating units represented by the following Formulas (5), (6), (7), and (8) do not include the repeating unit represented by the previously described Formula (1).

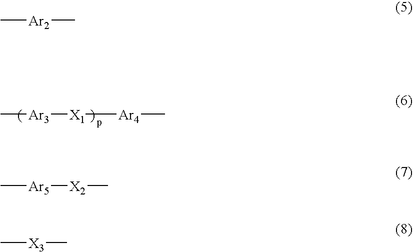

In the Formula, each of Ar₂, Ar₃, Ar₄, and Ar₅ is independently an arylene group, a divalent heterocyclic group, or a divalent group having a metal complex structure. When a plurality of Ar₃ is present, they can be the same or different from each other. Each of X₁, X₂, and X₃ independently represents —CRₐ═CR_{b}—, —C≡C—, —N(R_{c})—, —O—, —S—, —SO—, —SO₂—, or —(SiR_{d}Rₑ)_{q}—. Each of Rₐ and R_{b} is, independently, a hydrogen atom, a monovalent hydrocarbon group (alkyl group, aryl group, and the like), a monovalent heterocyclic group, carboxyl group, hydrocarbon oxycarbonyl group (substituted carboxyl group and the like), or a cyano group. Each of R_{c}, R_{d}, and Rₑ is, independently, a hydrogen atom, a monovalent hydrocarbon group (alkyl group, aryl group, aryl alkyl group, and the like), a monovalent heterocyclic group. p is 1 or 2, and q is an integer from 1 to 12. When there are a plurality of Rₐ, R_{b}, R_{c}, R_{d}, and Rₑ, they can be the same or different from each other. Concrete examples of the monovalent hydrocarbon group represented by Rₐ, R_{b}, R_{c}, R_{d}, and Rₑ are the examples of monovalent hydrocarbon groups represented by R¹ in Formula (1). Concrete examples of hydrocarbon oxycarbonyl groups represented by Rₐ and R_{b} are the examples of hydrocarbon oxycarbonyl groups represented by R¹ in Formula (1).

Here, the arylene group is an atomic group in which two hydrogen atoms are removed from an aromatic hydrocarbon and includes those with a condensed ring, or those in which two or more independent benzene rings or condensed rings are bonded directly or via a group such as vinylene or the like. The arylene group can have a substituent.

For the substituent, examples include substituents represented by R¹ in Formula (1) and monovalent heterocyclic groups. Preferably, the substituent is a hydrocarbon group, hydrocarbon oxy group, hydrocarbon thio group, trialkylsilyl group, halogen atom, nitro group, cyano group, hydroxyl group, mercapto group, acyl group, carboxyl group, phosphonic acid group, and sulfonic acid group; more preferably, it is a hydrocarbon group, hydrocarbon oxy group, hydrocarbon thio group, trialkylsilyl group, nitro group, cyano group, and acyl group; and even more preferably, it is a hydrocarbon group and hydrocarbon oxy group.

The carbon number of the arylene group not including the substituent is normally 6-60, and preferably is 6-20. In addition, the total carbon number of the arylene group including the substituent is normally 6-100.

Examples of the arylene group include phenylene group (for example, the following Formulas (9A-1) to (9A-3)), naphthalene diyl group (the following Formulas (9B-1)-(9B-6)), anthracene-diyl group (following Formulas (9C-1) to (9C-5)), biphenyl-diyl group (the following Formulas (9D-1) to (9D-6)), terphenyl-diyl group ((the following Formulas (9E-1) to (9E-3)), condensed ring compound group (the following Formulas (9F-1) to (9F-6)), fluorene-diyl group (the following Formulas (9F-7) to (9F-9)), stilbene-diyl (the following Formulas (9G-1) to (9G-4)), distilbene-diyl (the following Formulas (9G-5), (9G-6)), and the like. Among these, the phenylene group, biphenylene group, fluorene-diyl group, and stilbene-diyl group are preferred, more preferred are the phenylene group, biphenylene group, and fluorene-diyl group, and the fluorene-diyl group is particularly preferred.

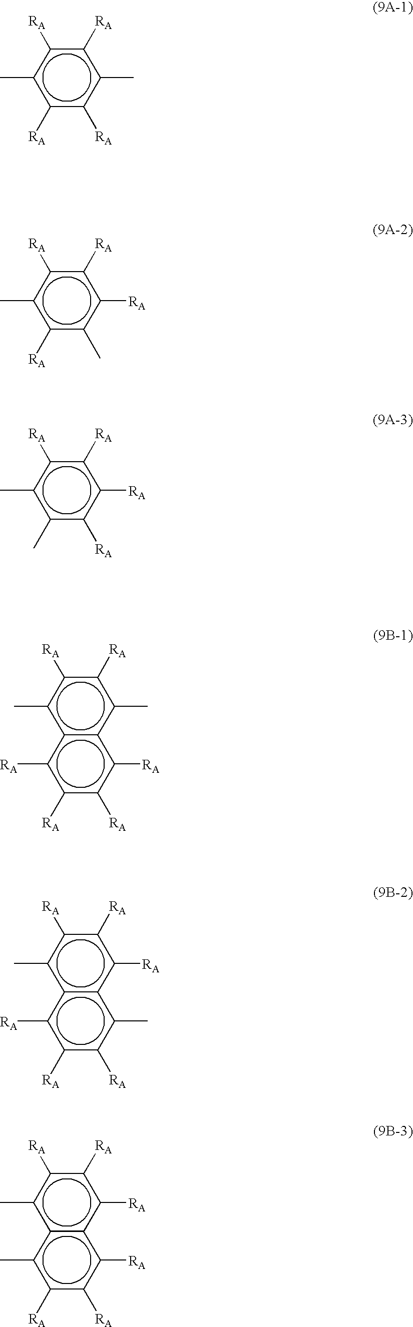

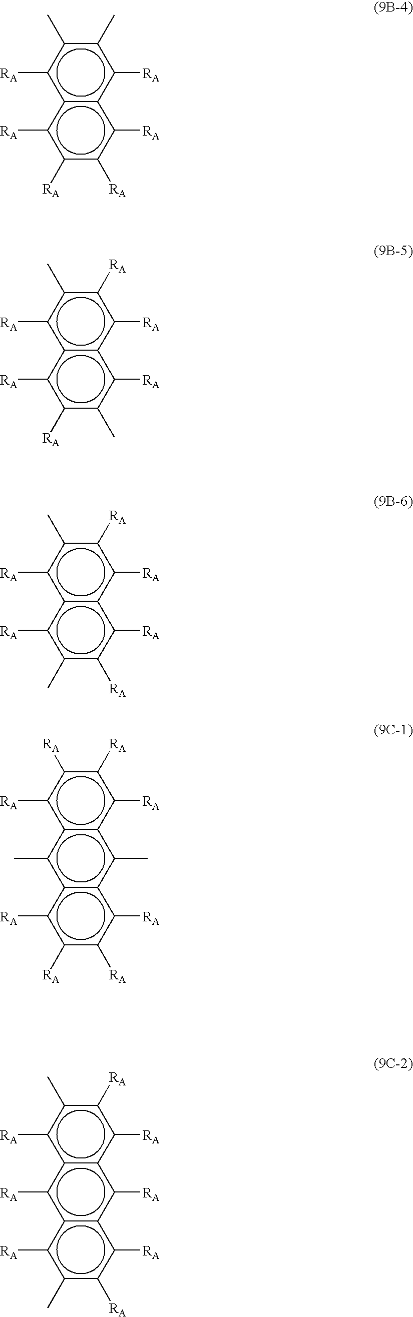

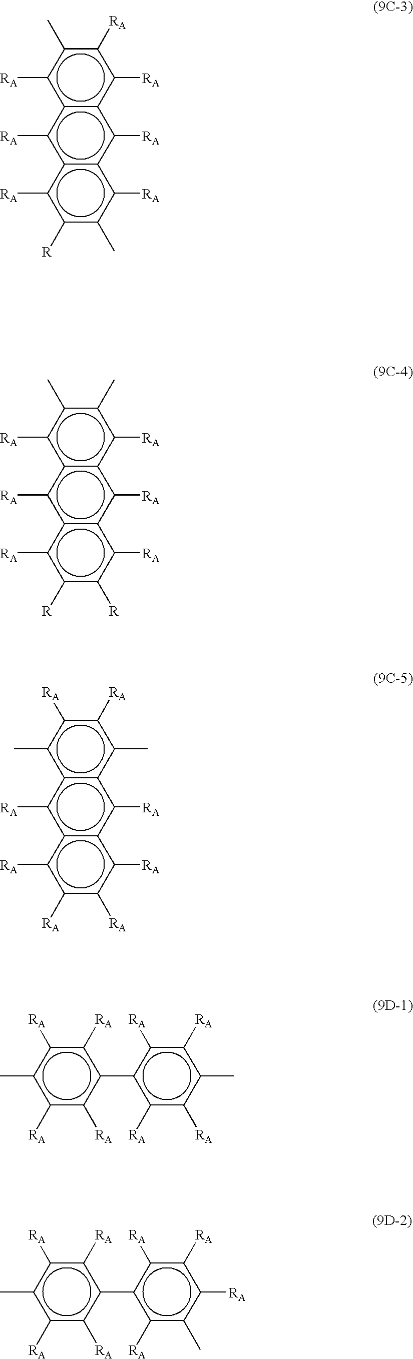

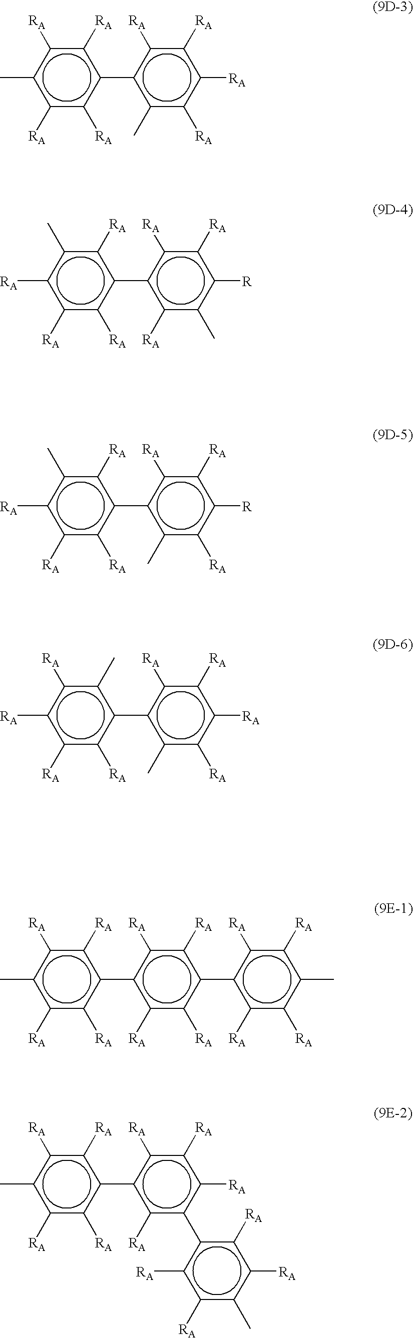

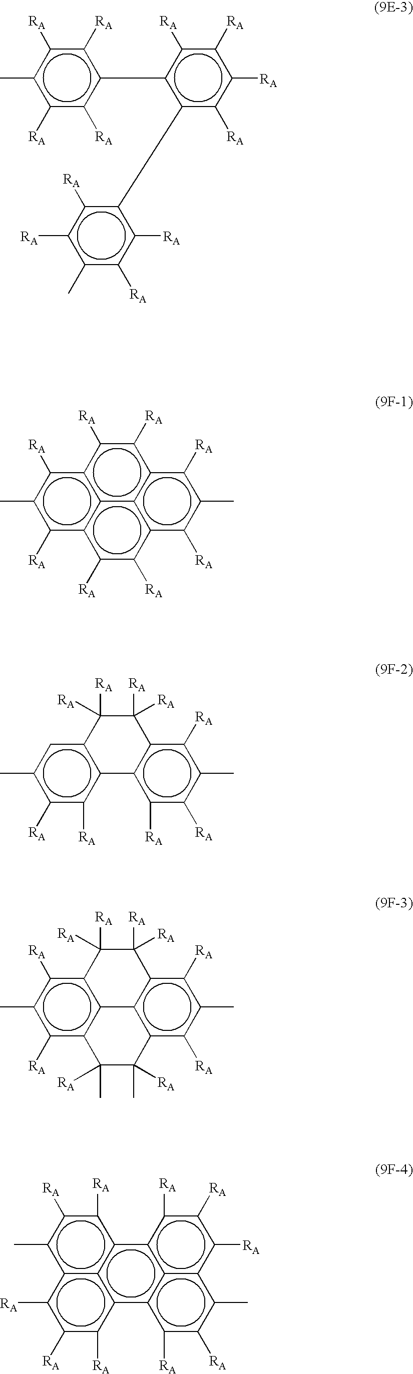

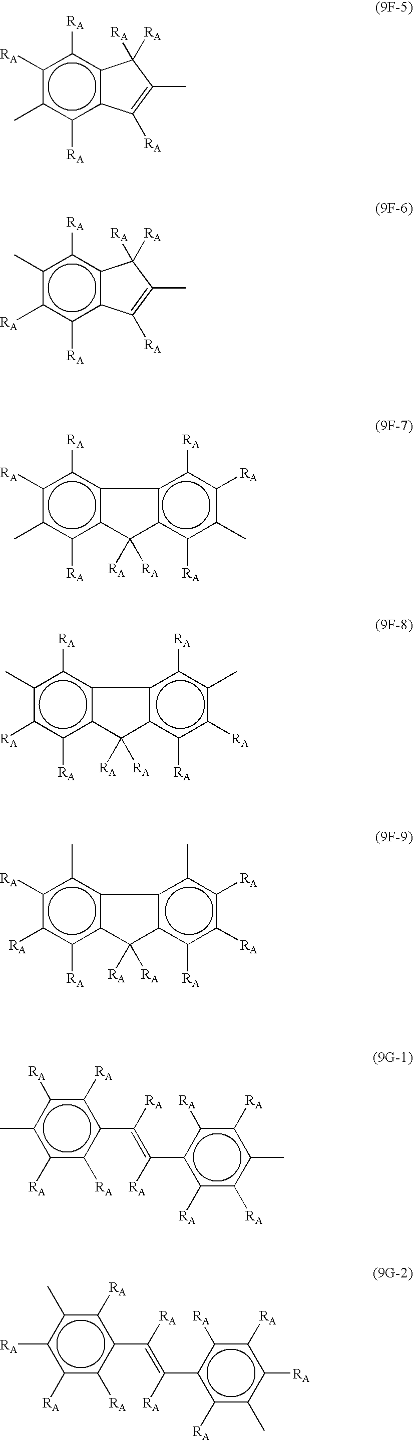

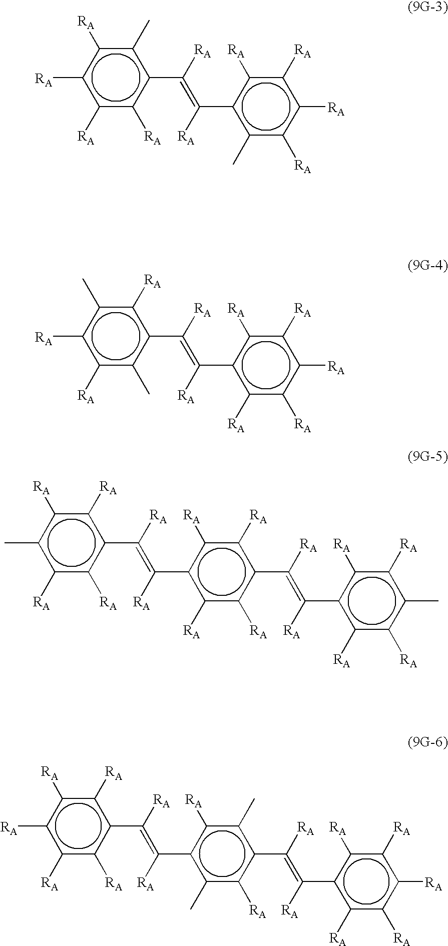

In addition, the divalent heterocyclic group of Ar₂, Ar₃, Ar₄, and Ar₅ is the remaining atomic group after two hydrogen atoms are removed from a heterocyclic compound. This group can have a substituent.

Here, with regard to the heterocyclic compound, these are compounds in which, among the organic compounds with a ring structure, the elements constructing the ring is not just carbon atoms, but contain within the ring a hetero atom such as oxygen, sulfur, nitrogen, phosphorus, boron, arsenic, and the like. Among the divalent heterocyclic ring groups, aromatic heterocyclic ring groups are preferred.

For the substituent, examples include the substituents represented by R¹ of Formula (1) and monovalent heterocyclic groups. The substituent is preferably hydrocarbon group, hydrocarbon oxy group, hydrocarbon thio group, trialkylsilyl group, halogen atom, nitro group, cyano group, hydroxyl group, mercapto group, acyl group, carboxyl group, phosphonic acid, sulfonic acid. More preferably, it is a hydrocarbon group, hydrocarbon oxy group, hydrocarbon thio group, trialkylsilyl group, nitro group, cyano group, acyl group, and even more preferably, it is a hydrocarbon group and hydrocarbon oxy group.

The carbon number of the divalent heterocyclic group not including the substituent is normally 3-60. The total carbon number of the divalent heterocyclic group including the substituent is normally 3-100.

For the divalent heterocyclic group, examples include the following:

A divalent heterocyclic ring containing nitrogen as the hetero atom; pyridine-diyl group (following Formulas (9H-1) to (9H-6)), diazaphenylene group (following Formulas (9H-7) to (9H-10)), quinoline diyl group (following Formulas (9I-1) to (9I-15)), quinoxaline diyl group (following Formulas (9I-16) to (9I-20)), acridine diyl group (following Formulas (9I-21 to 9I-24)), bipyridyl diyl group (following Formulas (9J-1) to (9J-3)), phenanthroline diyl group (following Formulas (9J-4) to (9J-6)), and the like.

A group having a fluorene structure containing oxygen, silicon, nitrogen, sulfur, selenium, and the like as the hetero atom (following Formulas (9J-7) to (9J-21)).

An example is a five member ring heterocyclic group containing oxygen, silicon, nitrogen, sulfur, selenium, and the like as the hetero atom (following Formulas (9K-1) to (9K-5)).

An example is a five member ring condensed heterocyclic group containing oxygen, silicon, nitrogen, sulfur, selenium, and the like as a hetero atom (following Formulas (9K-6) to (9K-16)).

An example is a group which is a dimer or oligomer of a five member ring heterocyclic group which contains oxygen, silicon, nitrogen, sulfur, selenium, and the like as the hetero atom and which is bonded at the alpha position of the hetero atom (following Formulas (9L-1) to (9L-2)).

An example is a group in which a phenyl group is bonded to the alpha position of the hetero atom of a 5 member heterocyclic group containing oxygen, silicon, nitrogen, sulfur, selenium, and the like as the hetero atom (following Formulas (9L-3) to (9L-9)).

An example is a group in which a phenyl group, furyl group, or thienyl group is substituted in a five member condensed heterocyclic group containing oxygen, nitrogen, sulfur, and the like as the hetero atom (the following Formulas (9M-1) to (9M-6)).

An example is a group in which a phenyl group is condensed with a 6 member ring heterocyclic group containing oxygen, nitrogen, sulfur, and the like as the hetero atom (following Formulas (9M-7) to (9M-15)).

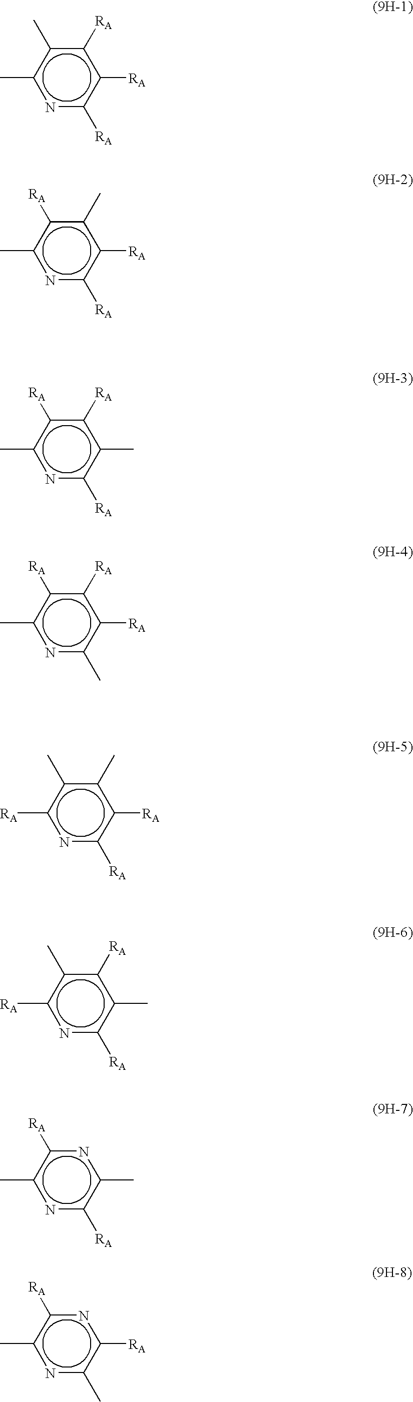

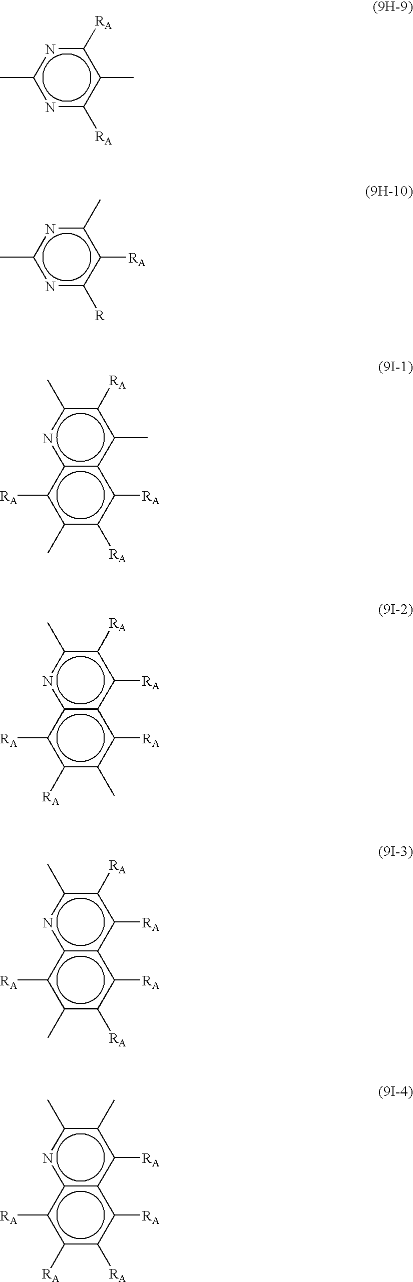

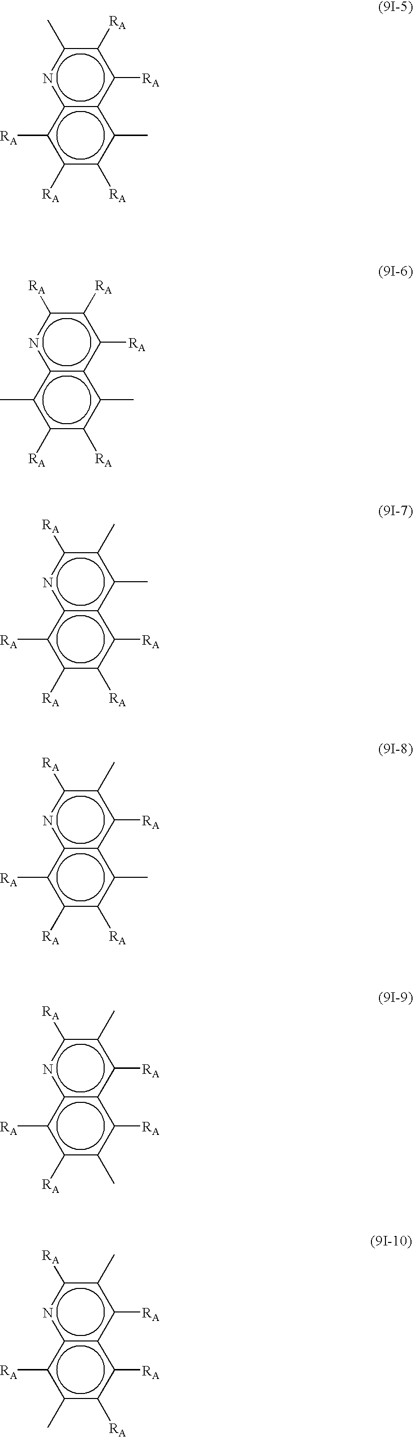

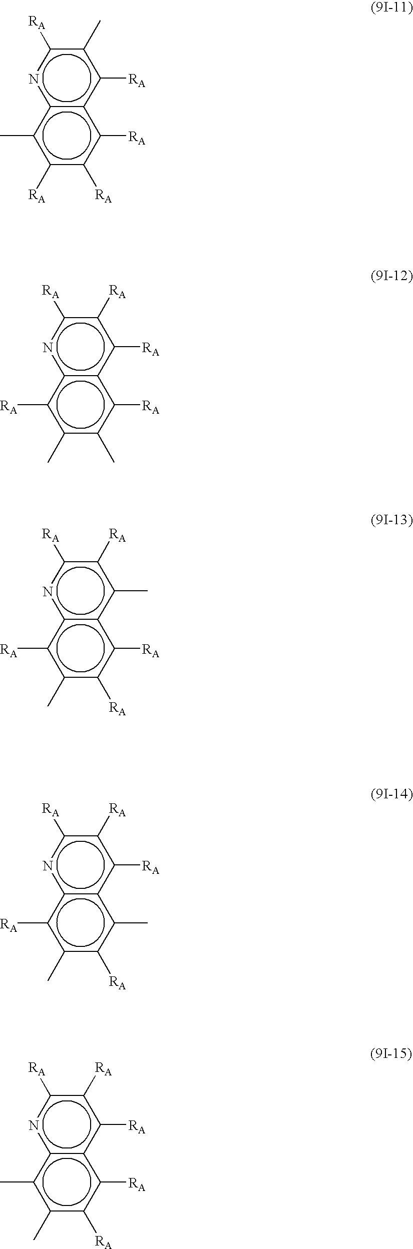

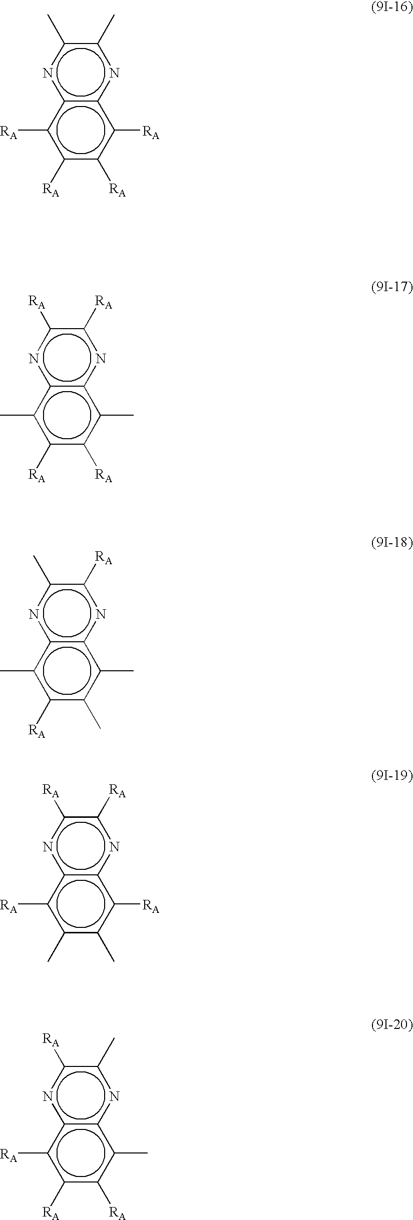

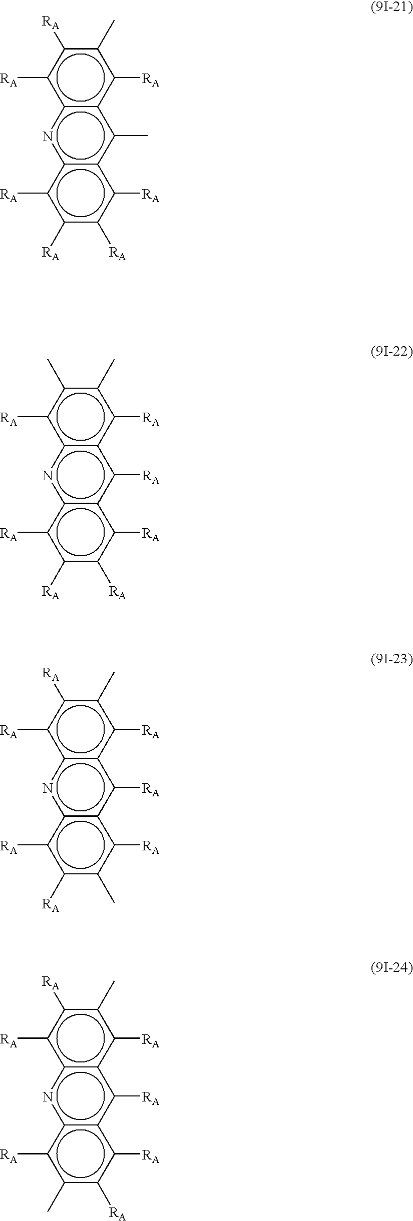

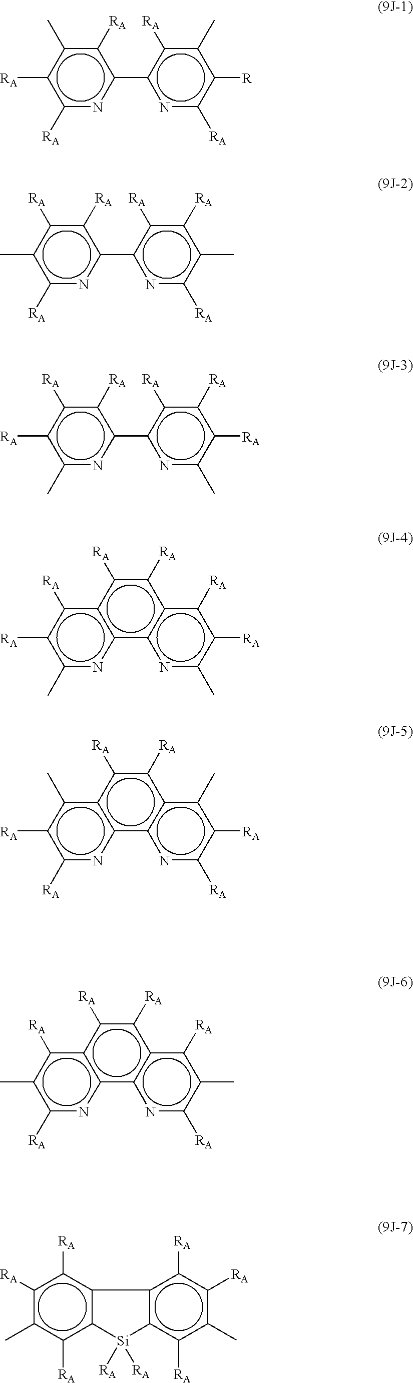

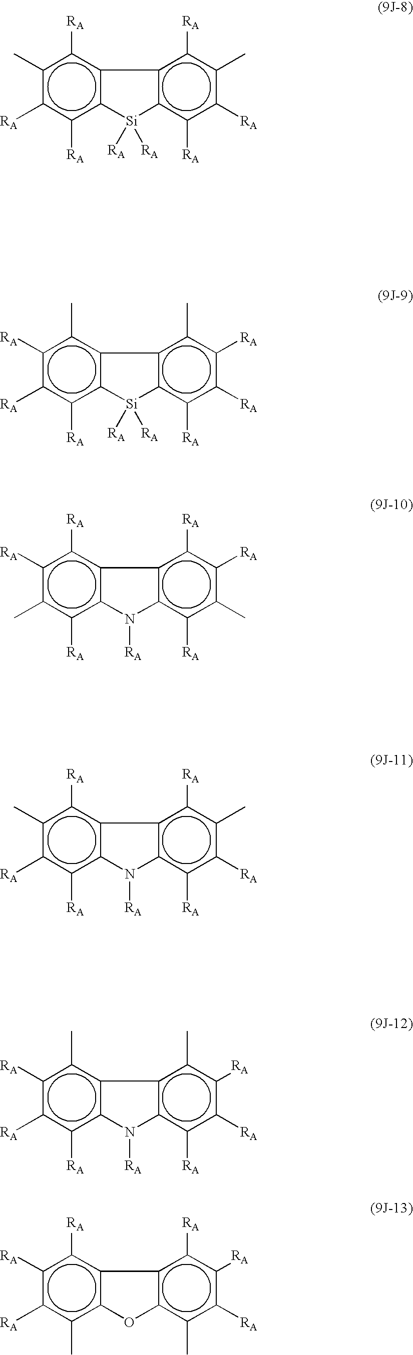

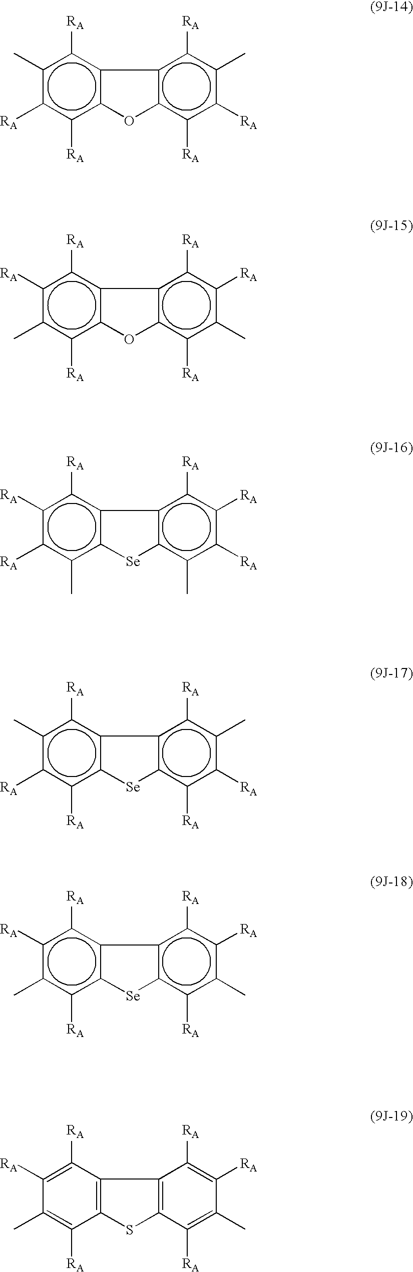

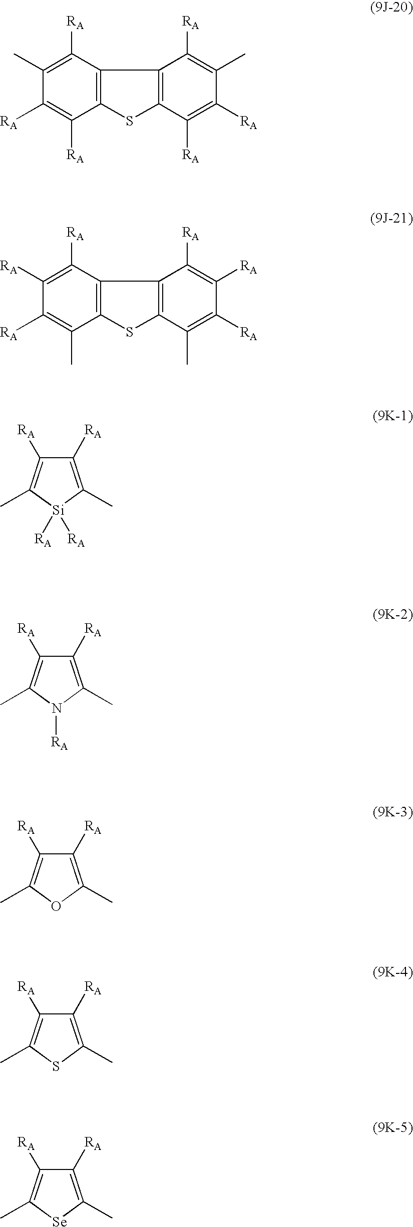

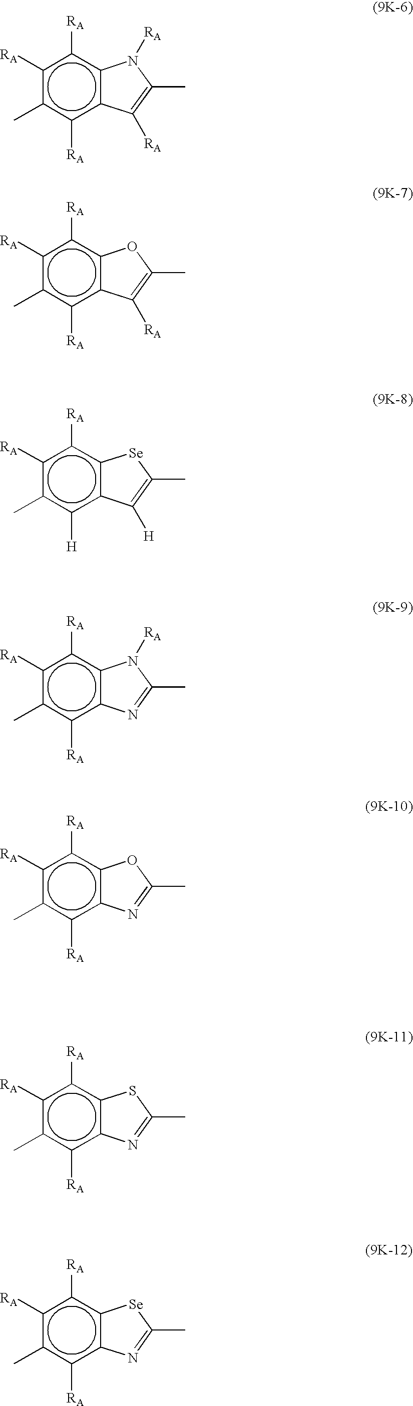

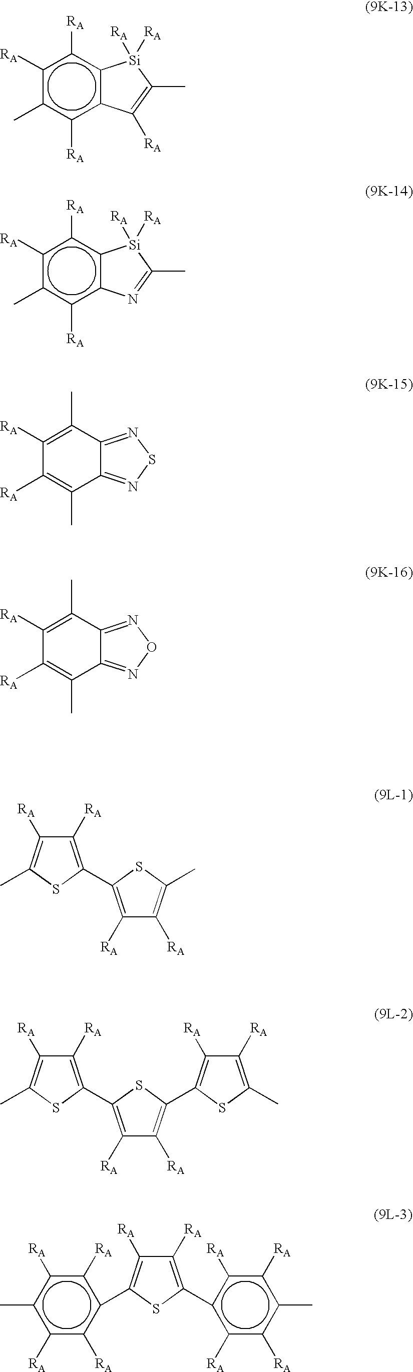

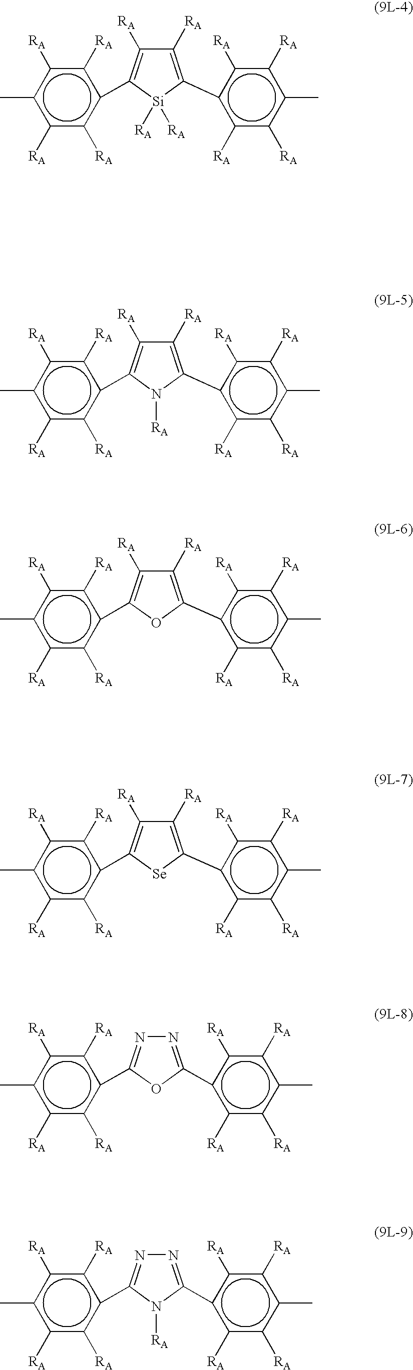

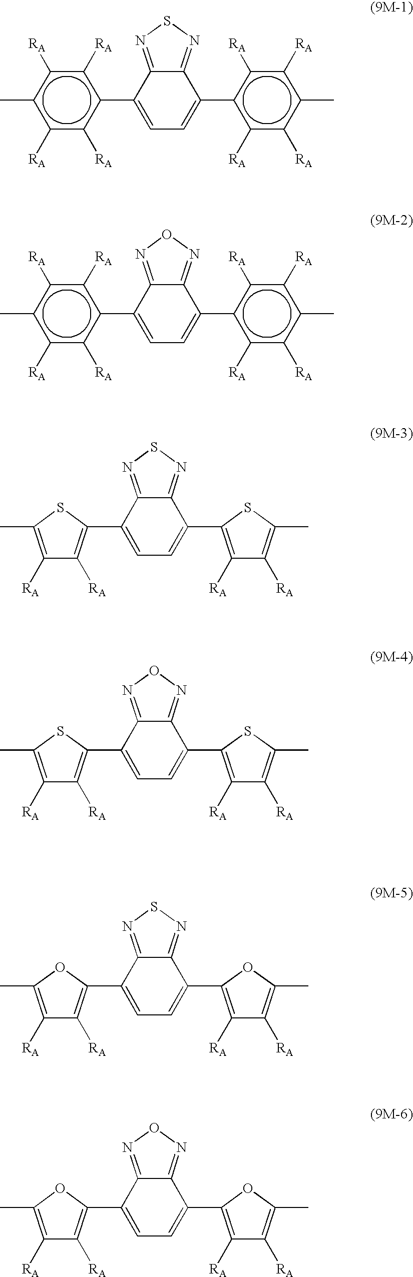

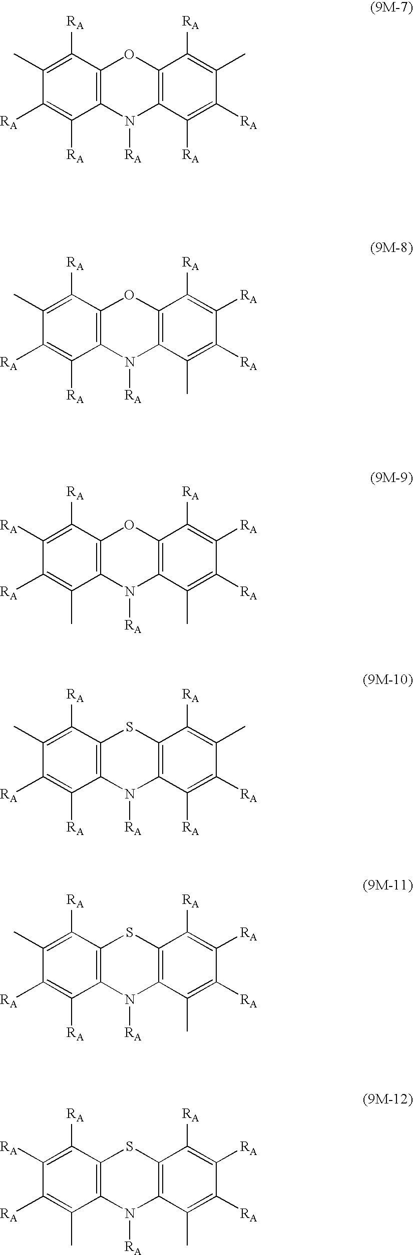

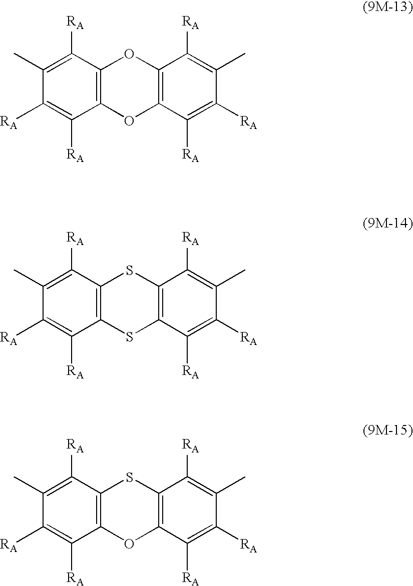

Furthermore, in Ar₂, Ar₃, Ar₄, and Ar₅, the divalent group having a metal complex structure is the divalent group that remains after two hydrogen atoms are removed from an organic ligand of a metal complex having an organic ligand.

The carbon number for this organic ligand is normally approximately 4-60. Examples include 8-quinolinole and its derivatives, benzoquinolinole and its derivatives, 2-phenyl-pyridine and its derivatives, 2-phenyl-benzothiazole and its derivatives, 2-phenyl-benzoxazole and its derivatives, porphyrin and its derivatives, and the like.

In addition, the central metal in this complex is, for example, aluminum, zinc, beryllium, iridium, platinum, gold, europium, terbium, and the like.

For the metal complex having an organic ligand, examples include metal complexes known as low molecular weight fluorescent material and phosphorescence material, and triplet luminescent complexes, and the like.

For the divalent group having a metal complex structure, concrete examples are shown in the following Formulas (9N-1) to (9N-7).

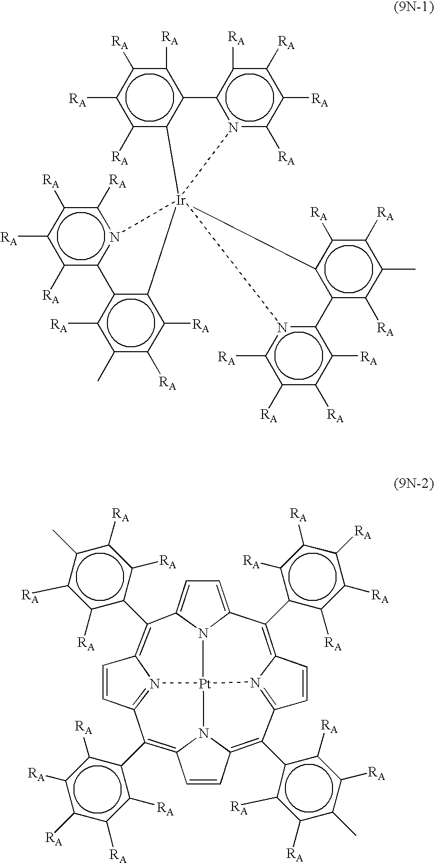

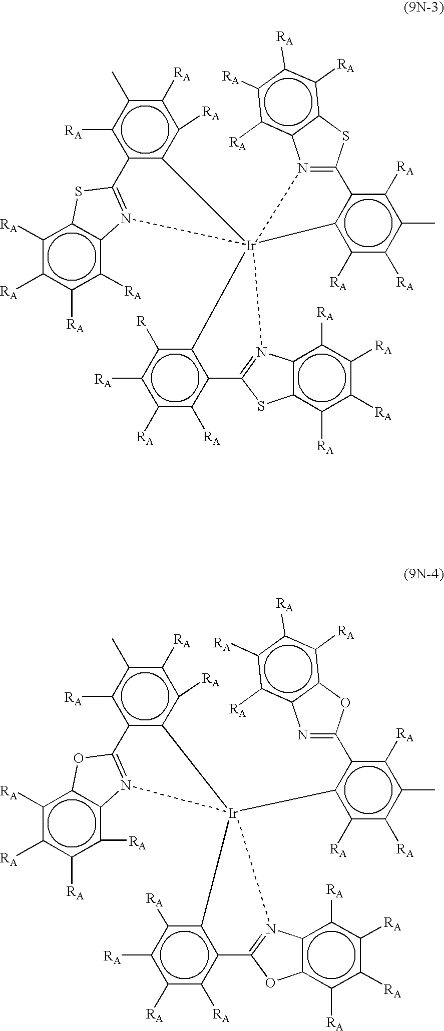

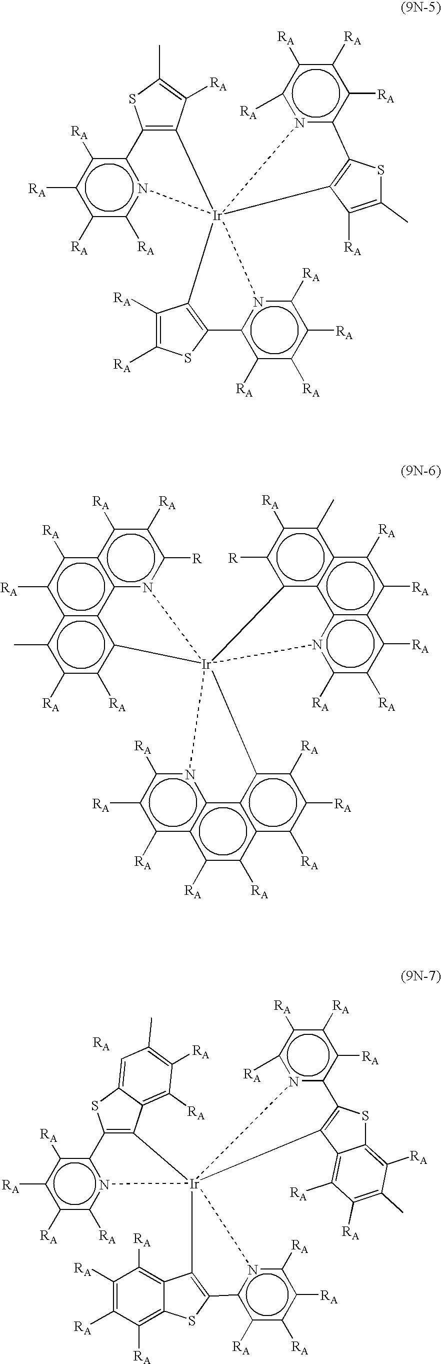

In the above Formulas (9A-1) to (9A-3), (9B-1) to (9B-6), (9C-1) to (9C-5), (9D-1) to (9D-6), (9E-1) to (9E-3), (9F-1) to (9F-9), (9G-1) to (9G-6), (9H-1) to (9H-10), (9I-1) to (9I-24), (9J-1) to (9J-21), (9K-1) to (9K-16), (9L-1) to (9L-9), (9M-1) to (9M-6), (9M-7) to (9M-15), and (9N-1) to (9N-7), each R_{A} is independently a hydrogen atom or a substituent represented by R¹ in Formula (1). Preferably, R_{A} is a hydrogen atom, hydrocarbon group, hydrocarbon oxy group, hydrocarbon thio group, trialkylsilyl group, halogen atom, nitro group, cyano group, hydroxyl group, mercapto group, acyl group, carboxyl group, phosphonic acid group, sulfonic acid group. More preferably, R_{A} is a hydrogen atom, hydrocarbon group, hydrocarbon oxy group, hydrocarbon thio group, trialkylsilyl group, nitro group, cyano group, acyl group. Even more preferably, R_{A} is a hydrogen atom, hydrocarbon group, hydrocarbon oxy group. Carbon atoms in the Formulas (9A-1) to (9A-3), (9B-1) to (9B-10), (9C-1) to (9C-6), (9D-1) to (9D-6), (9E-1) to (9E-3), (9F-1) to (9F-9), (9G-1) to (9G-6), (9H-1) to (9H-10), (9I-1) to (9I-24), (9J-1) to (9J-21), (9K-1) to (9K-16), (9L-1) to (9L-9), (9M-1) to (9M-6), (9M-7) to (9M-15), and (9N-1) to (9N-7) can be replaced with nitrogen atom, oxygen atom, or sulfur atom. A hydrogen atom can be replaced with a fluorine atom.

Concrete examples of the repeating unit represented by the Formula (5) are the same as the concrete examples of the arylene group, divalent heterocyclic group, or divalent group having a metal complex structure represented by Ar₂, Ar₃, Ar₄, and Ar₅. Preferably, it is a group represented by Formulas (9A-1) to (9A-3), (9B-1) to (9B-6), (9C-1) to (9C-5), (9D-1) to (9D-6), (9F-1) to (9F-9), (9G-1) to (9G-6), (9I-1) to (9I-24), (9J-7) to (9J-21), (9K-6) to (9K-16), (9L-3) to (9L-9), (9M-1) to (9M-6), and (9M-7) to (9M-15). More preferably, it is a group represented by Formulas (9A-1) to (9A-3), (9B-1) to (9B-6), (9C-1) to (9C-5), (9F-7) to (9F-9), (9G-1) to (9G-4), (9J-13) to (9J-15), (9J-19) to (9J-21), (9K-15) to (9K-16), (9L-3) to (9L-9), (9M-1) to (9M-6), and (9M-7) to (9M-12). More preferably, it is a group represented by Formulas (9A-1) to (9A-3), (9F-7) to (9F-9), (9J-13) to (9J-15), (9J-19) to (9J-21), (9K-15) to (9K-16), (9M-1) to (9M-6), and (9M-7) to (9M-12). Among these, it is preferably a group represented by the Formulas (9F-7) to (9F-9), (9J-13) to (9J-15), (9J-19) to (9J-21), (9K-15) to (9K-16), (9M-1) to (9M-6), and (9M-7) to (9M-12). It is more preferably a group represented by (9F-7) to (9F-9) and (9M-7) to (9M-12). It is even more preferably a group represented by (9F-7) to (9F-9).

Concrete examples of the repeating unit represented by Formula (6) include a group represented by the following Formulas (10A-1) to (10A-7), a group represented by Formulas (10B-1) to (10B-7), a group represented by Formulas (10C-1) to (10C-8), a group represented by Formulas (10D-1) to (10D-5), a group represented by Formulas (10E-1) to (10E-4), a group represented by Formulas (10F-1) to (10F-6), a group represented by Formulas (10G-1) to (10G-6), a group represented by Formulas (10H-1) to (10H-6), a group represented by (10I-1) to (10I-6), and a group represented by Formulas (10J-1) to (10J-6).

The repeating unit represented by Formula (6) is preferably a group represented by Formulas (10A-1) to (10A-7), a group represented by Formulas (10B-1) to (10B-7), a group represented by Formulas (10C-1) to (10C-8), a group represented by Formulas (10D-1) to (10D-5), a group represented by Formulas (10E-1) to (10E-4), a group represented by Formulas (10F-1) to (10F-6), and a group represented by Formulas (10J-1) to (10J-6). More preferably, it is a group represented by Formulas (10A-1) to (10A-7), a group represented by Formulas (10B-1) to (10B-7), a group represented by Formulas (10C-1) to (10C-8), a group represented by Formulas (10D-1) to (10D-5), and a group represented by Formulas (10E-1) to (10E-4). More preferably, it is a group represented by Formulas (10D-1) to (10D-5). Stated more concretely, groups represented by the following Formulas (11A-1) to (11A-5) are preferred,

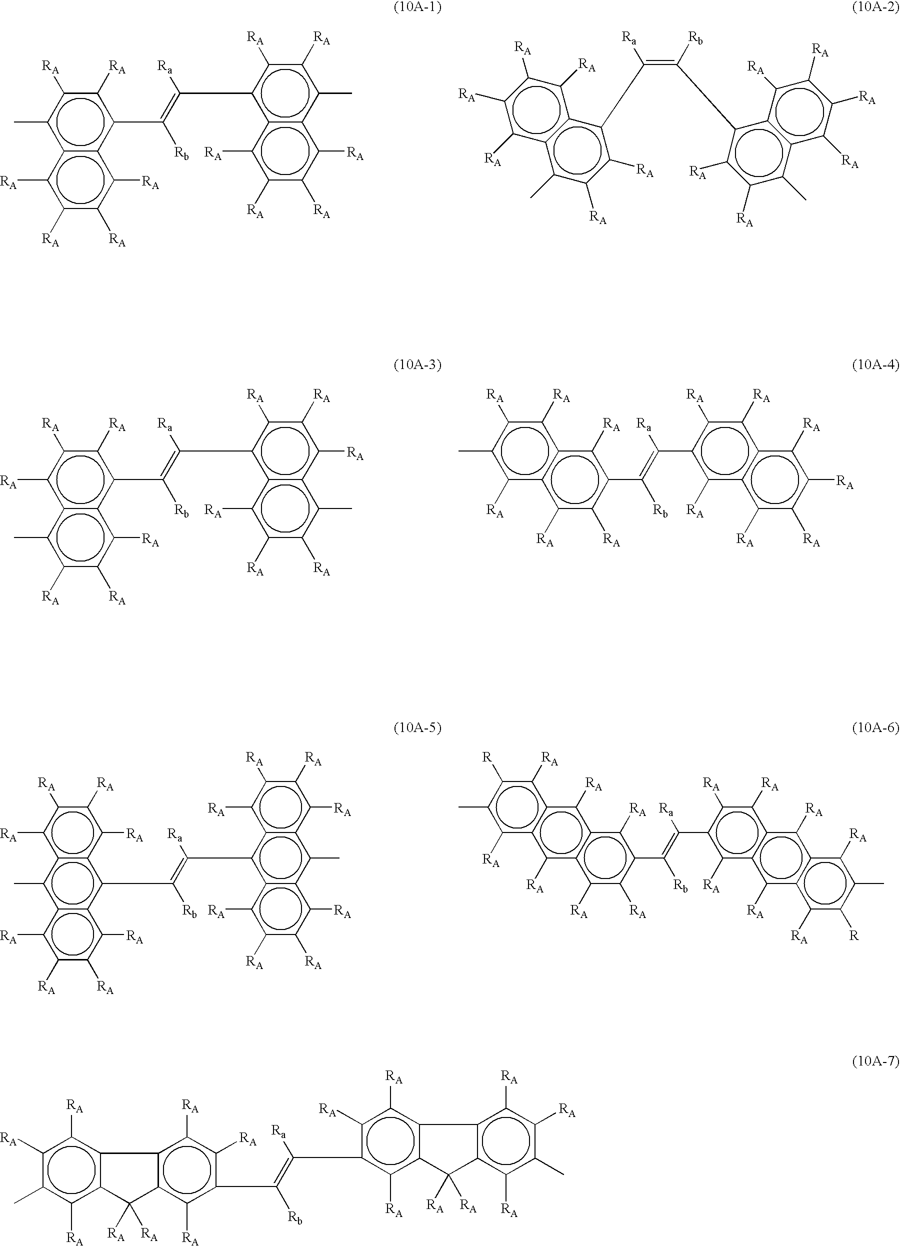

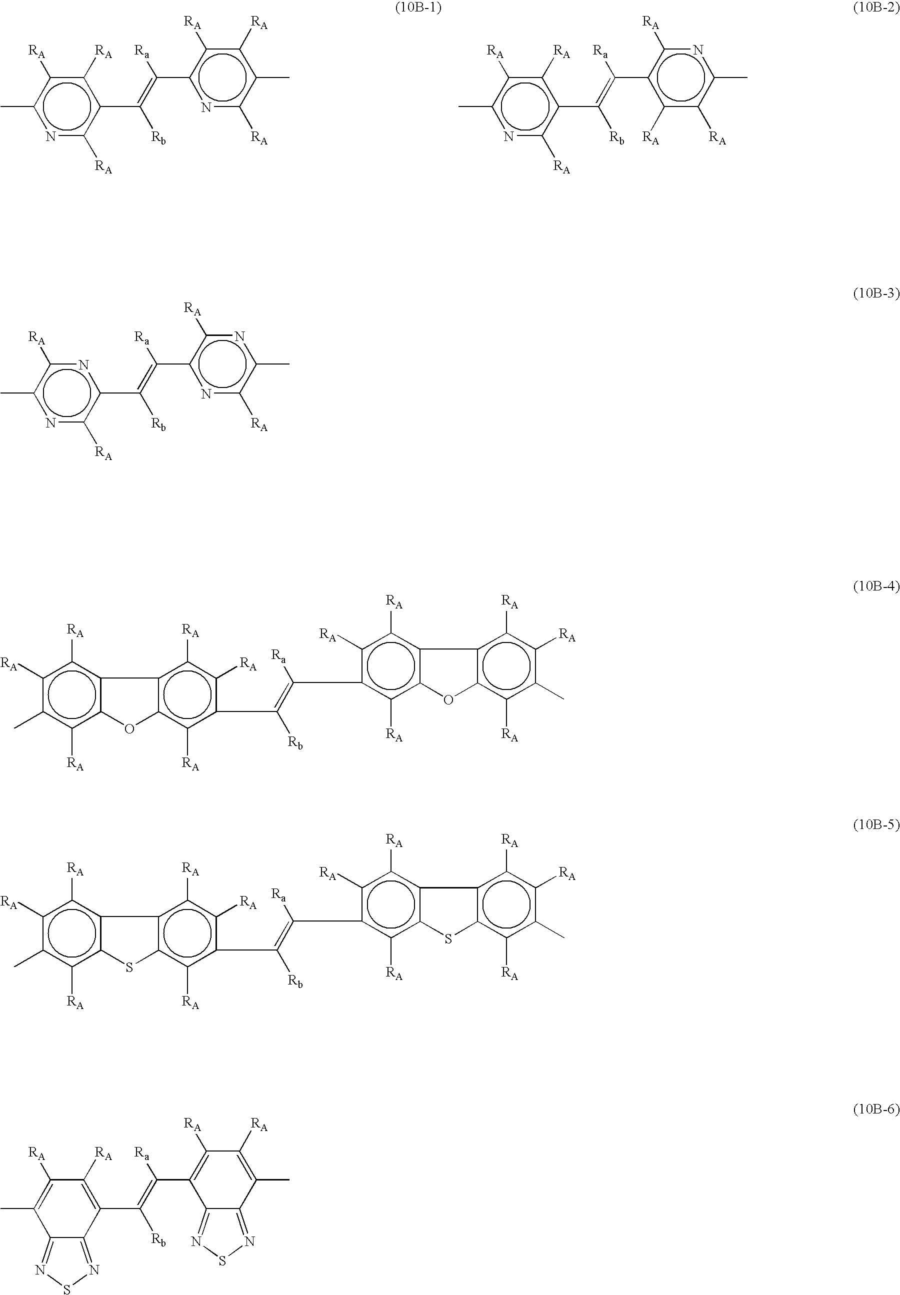

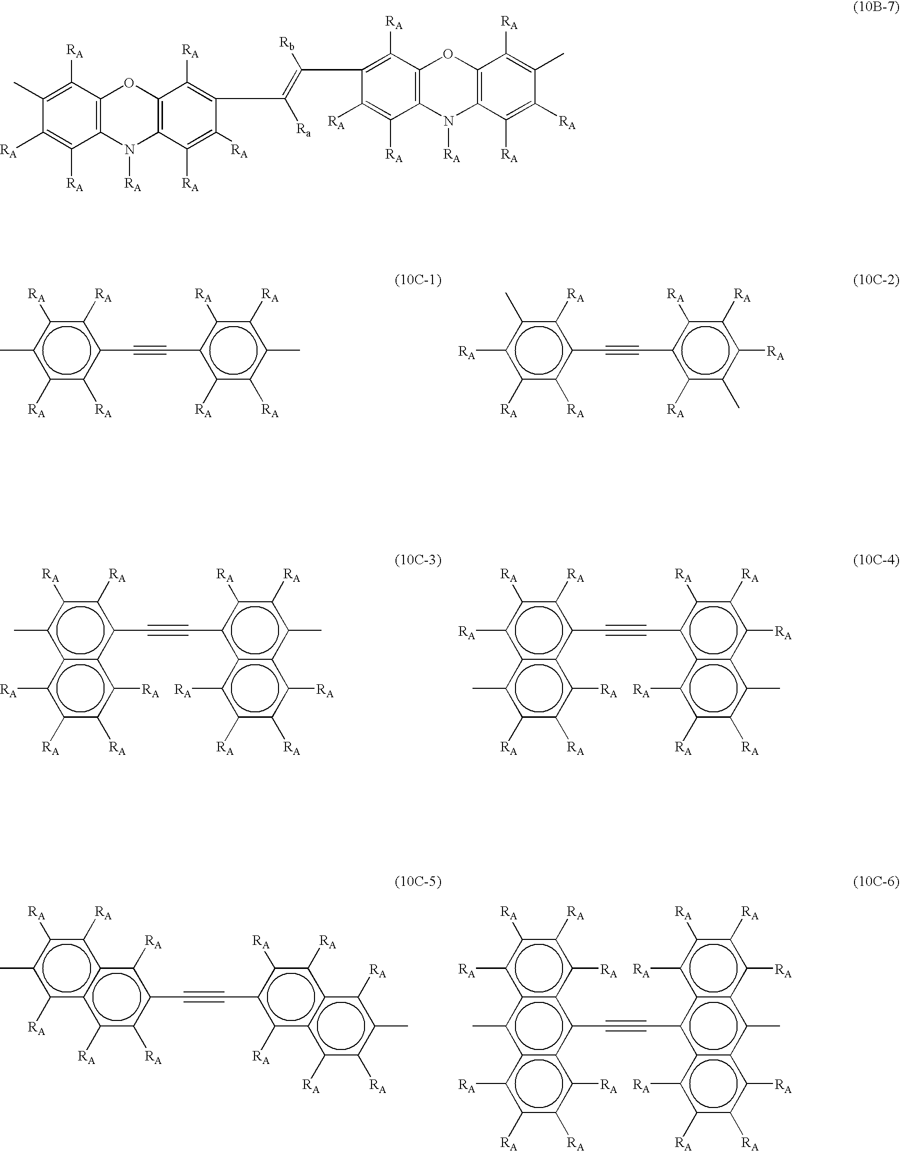

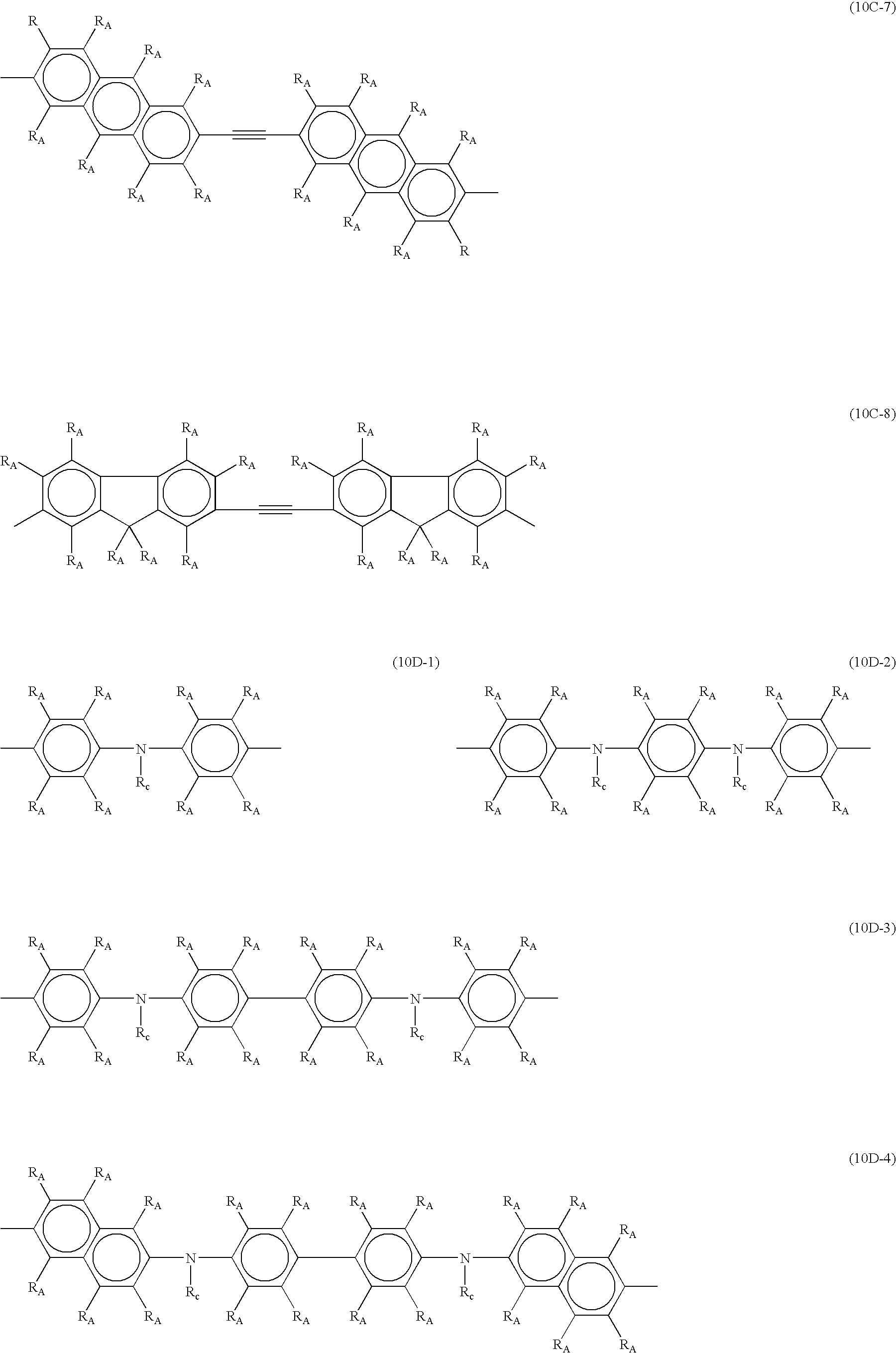

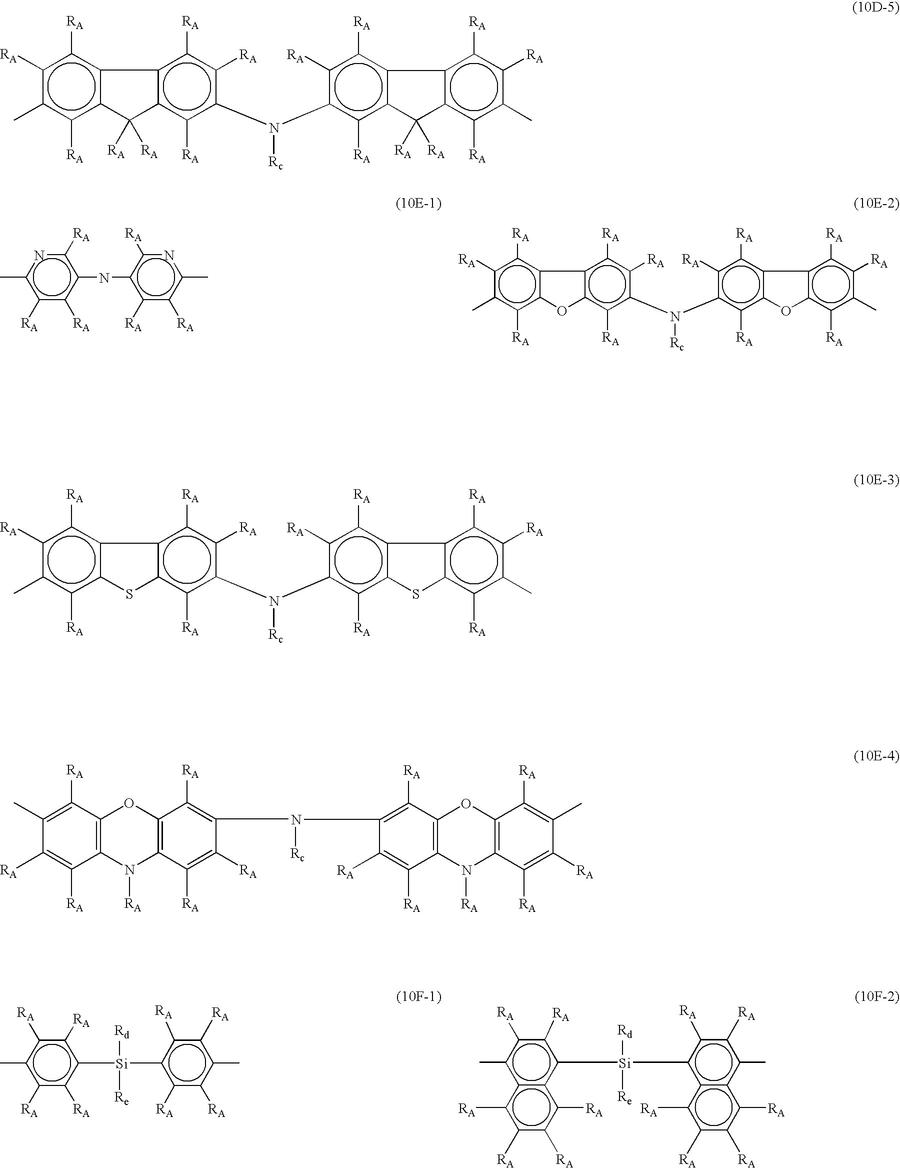

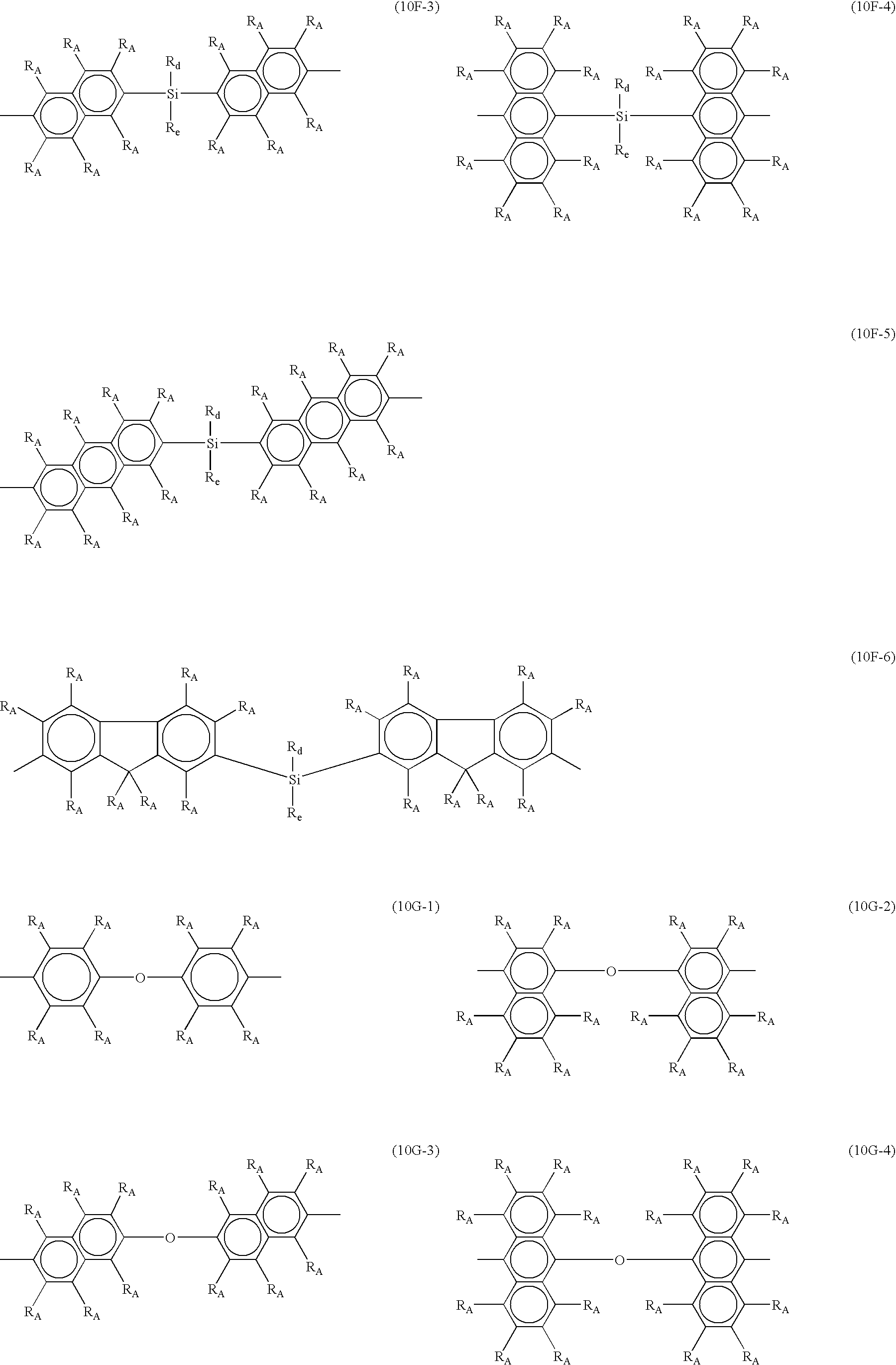

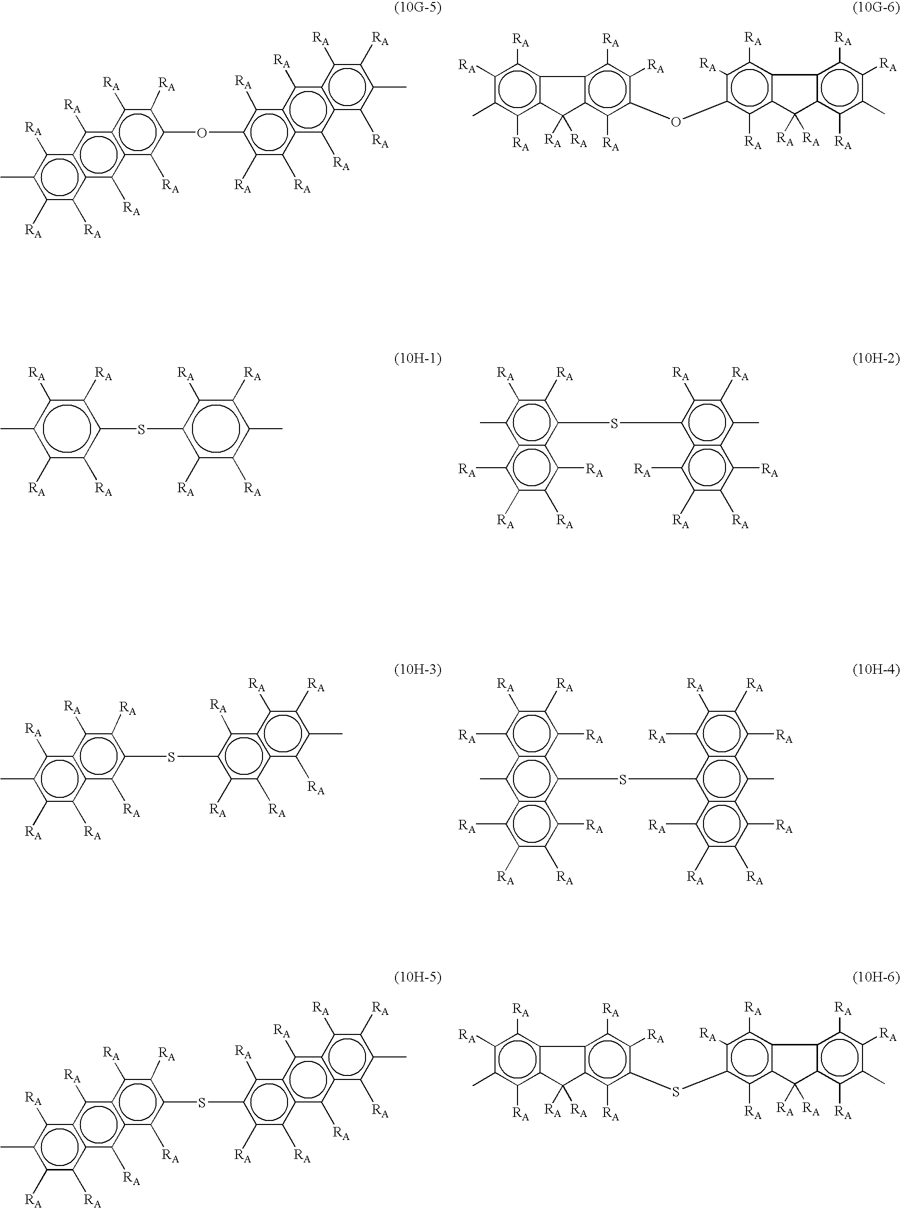

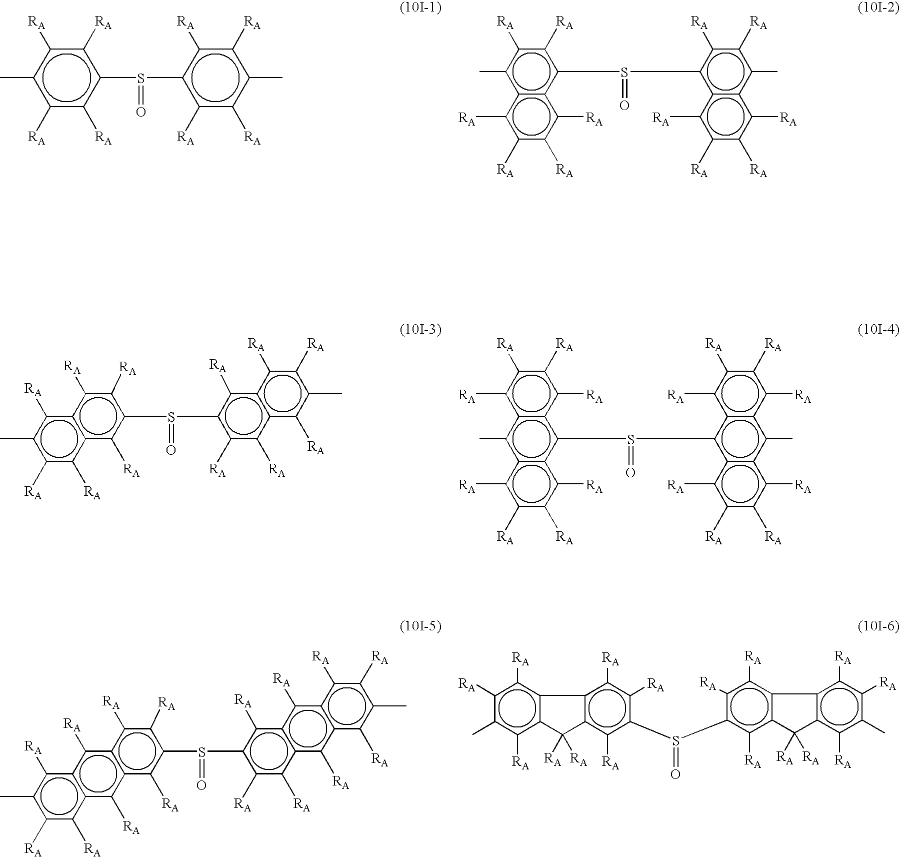

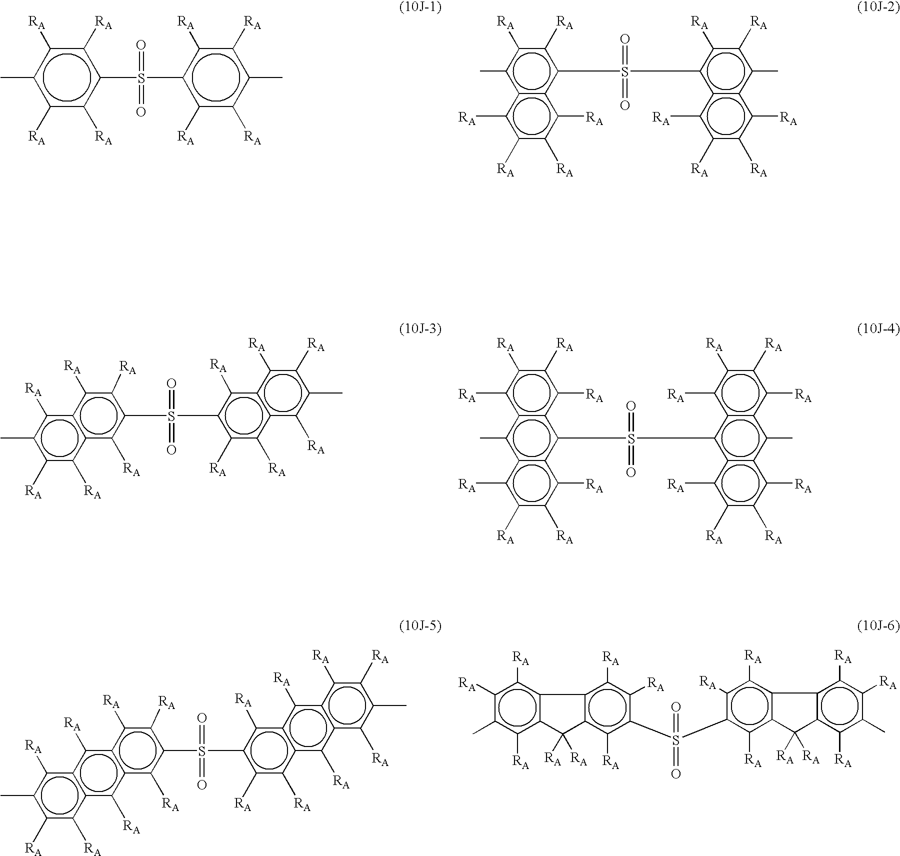

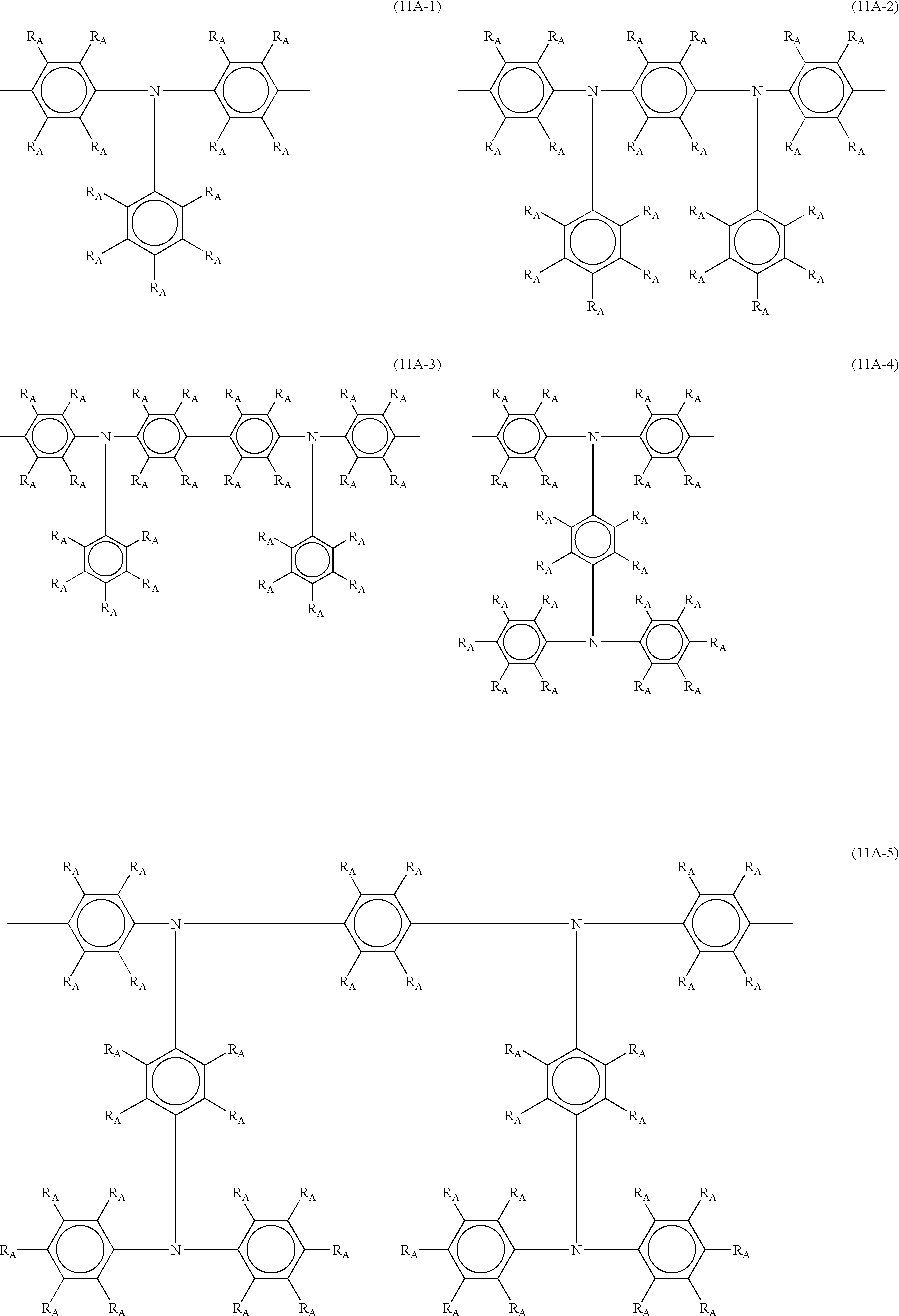

wherein R_{A}, Rₐ, R_{b}, R_{c}, R_{d}, and Rₑ are the same as described previously.

Concrete examples of the repeating unit represented by Formula (7) include groups represented by the following Formulas (12A-1) to (12A-7), groups represented by Formulas (12B-1) to (12B-7), groups represented by Formulas (12C-1) to (12C-8), groups represented by Formulas (12D-1) to (12D-4), groups represented by Formulas (12E-1) to (12E-4), groups represented by Formulas (12F-1) to (12F-6), groups represented by Formulas (12G-1) to (12G-6), groups represented by Formulas (12H-1) to (12H-6), groups represented by (12I-1) to (12I-6), and groups represented by Formulas (12J-1) to (12J-6).

Preferably, the repeating unit represented by Formula (7) is a group represented by the Formulas (12A-1) to (12A-7), a group represented by Formulas (12B-1) to (12B-7), a group represented by Formulas (12C-1) to (12C-8), a group represented by Formulas (12F-1) to (12F-6), and a group represented by Formulas (12J-1) to (12J-6). More preferably, it is a group represented by Formulas (12A-1) to (12A-7) and a group represented by Formulas (12B-1) to (12B-7). Even more preferably, it is a group represented by Formulas (12A-1) to (12A-7),

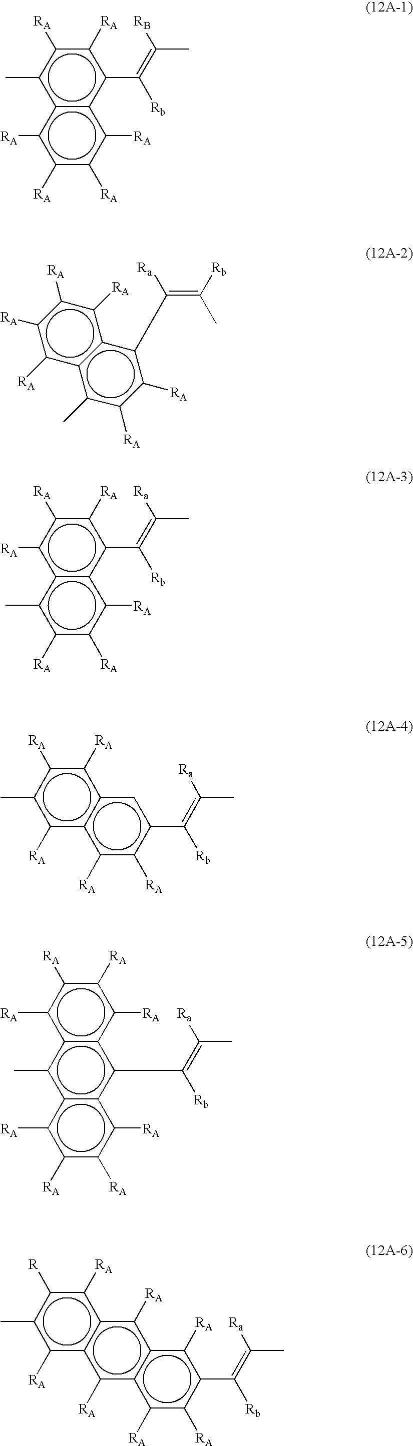

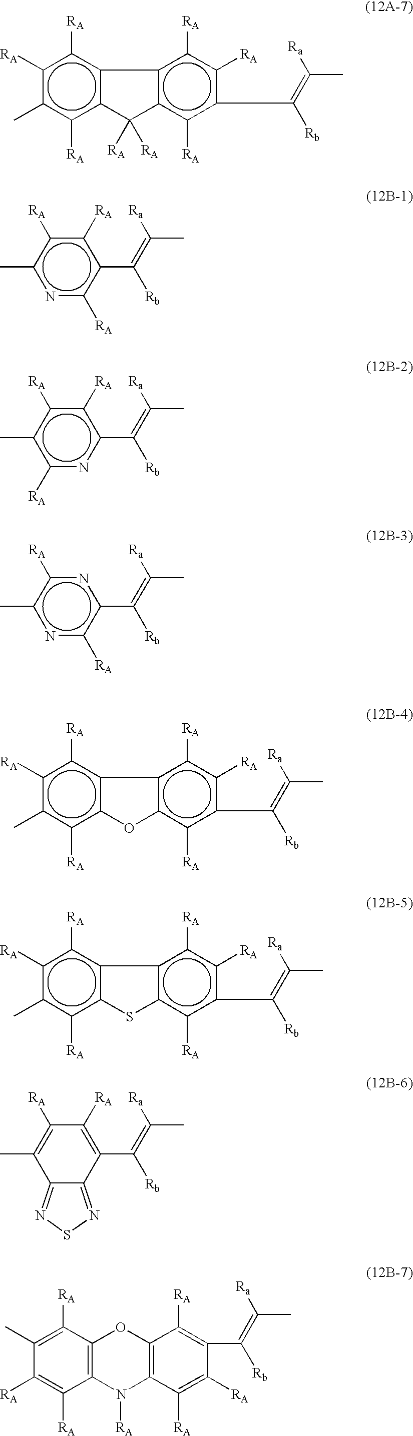

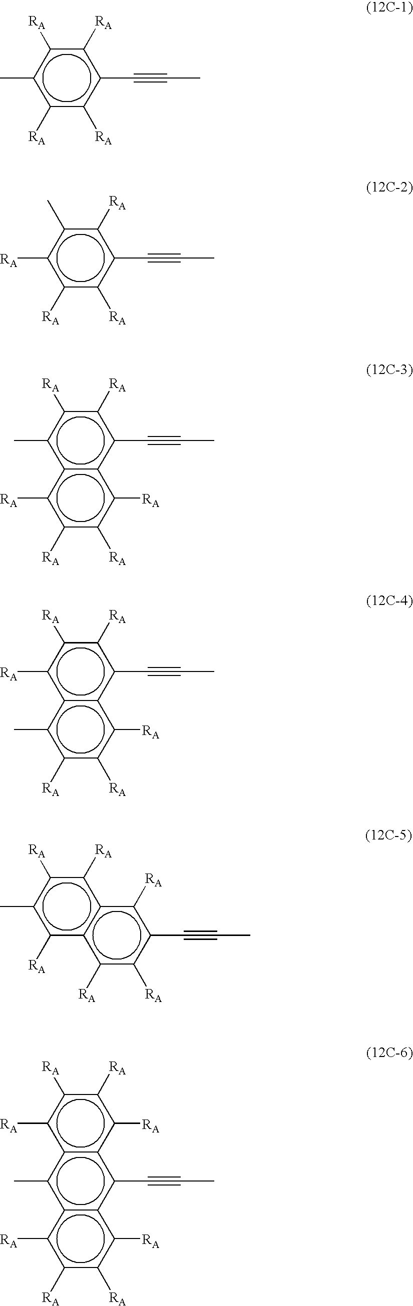

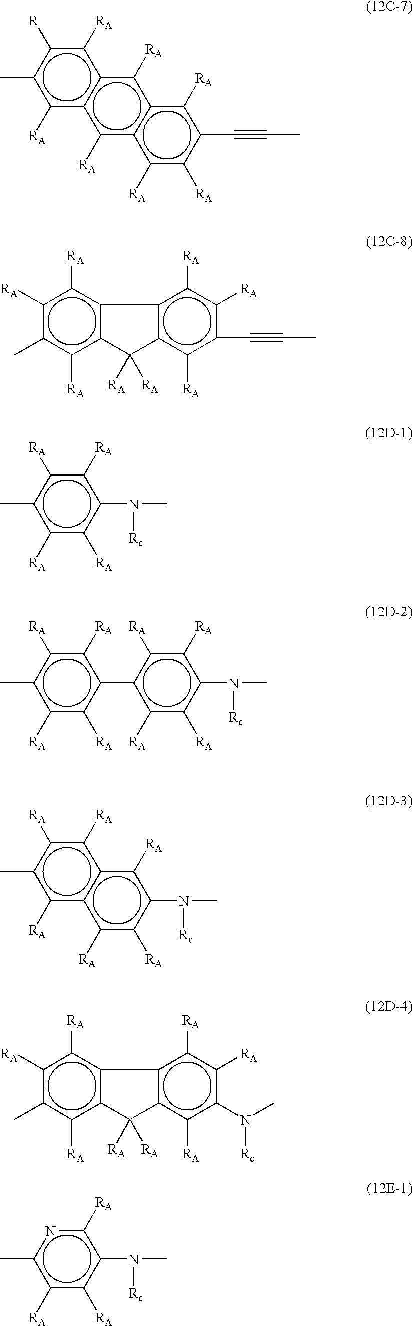

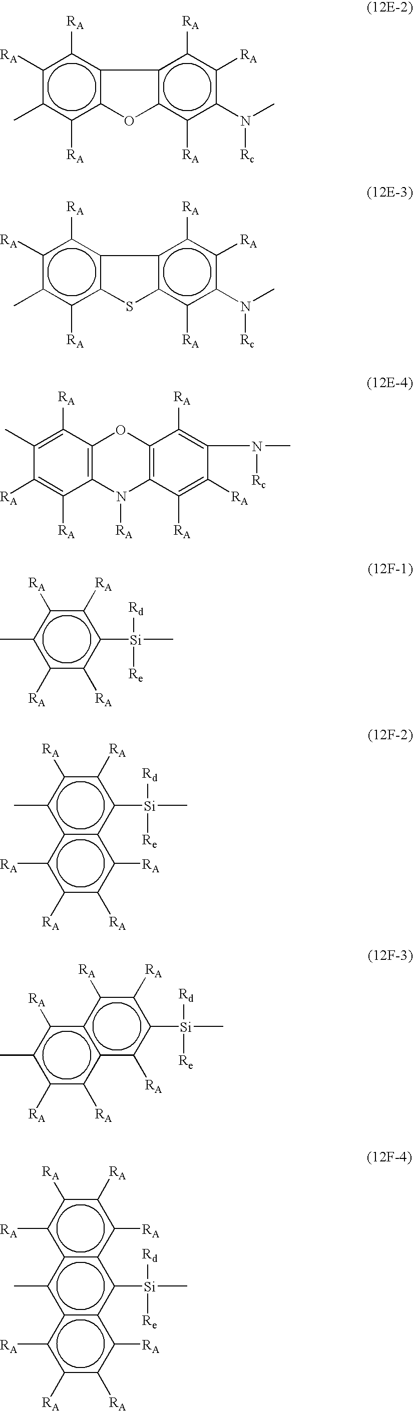

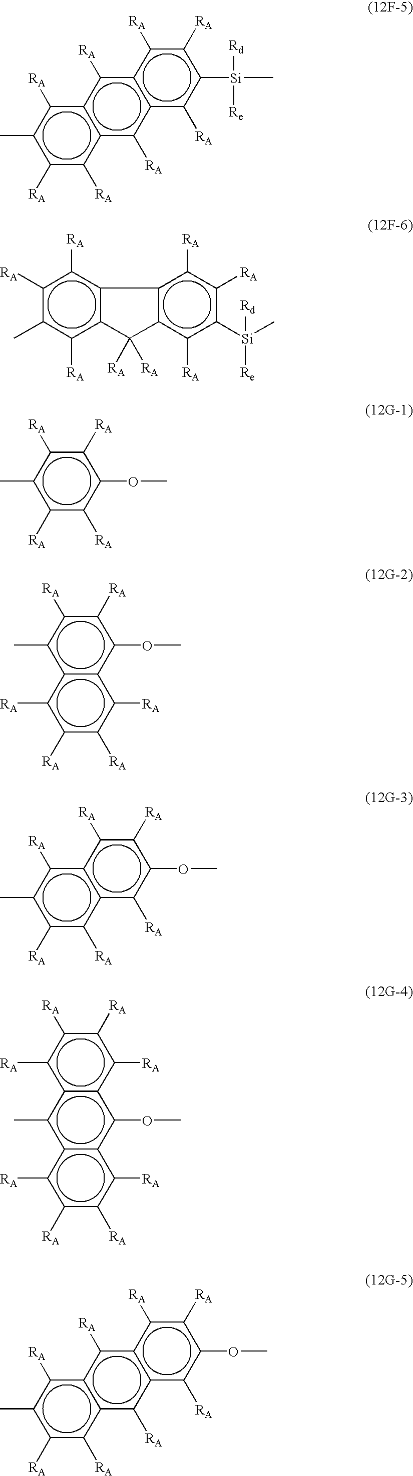

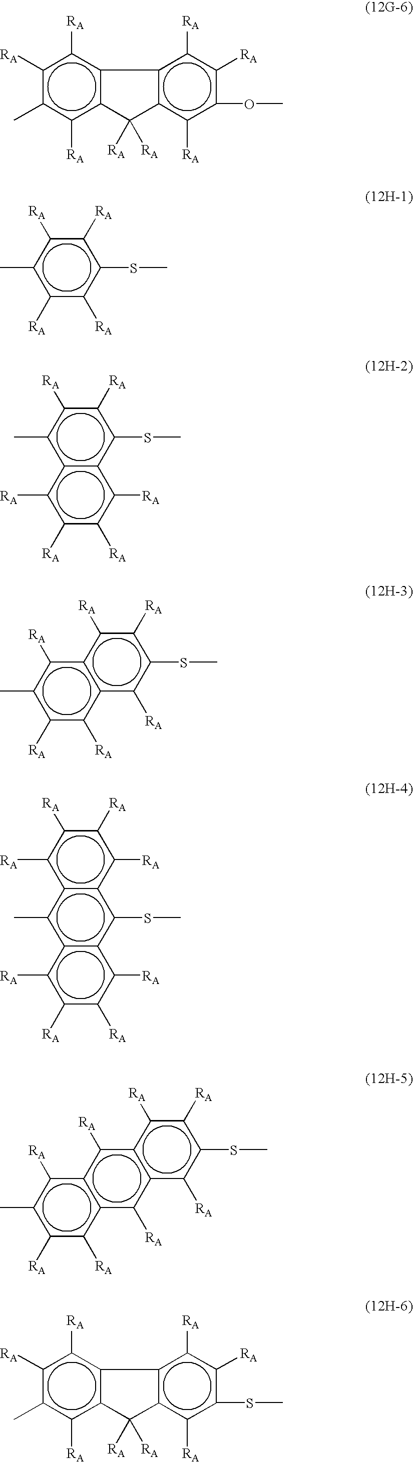

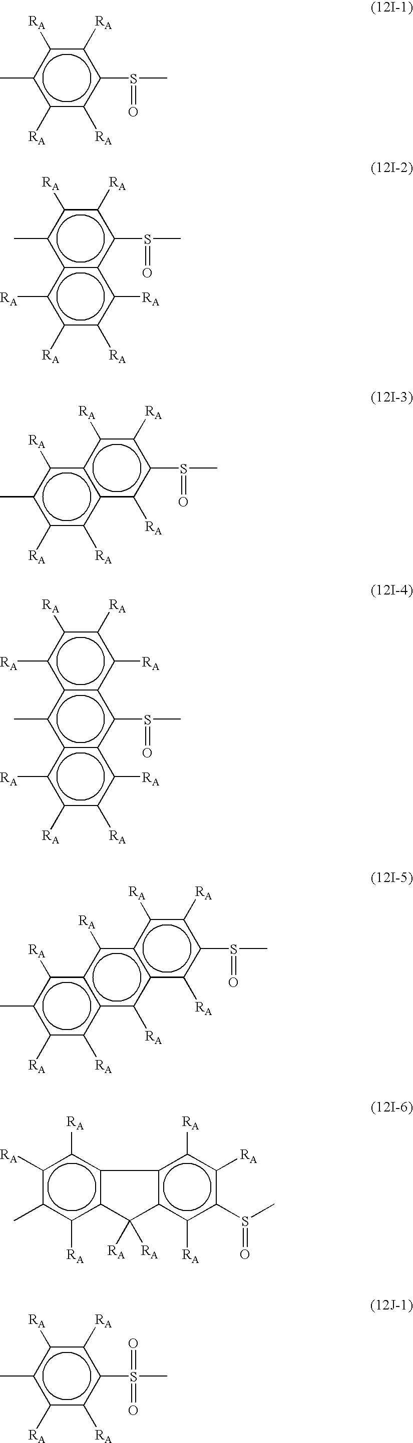

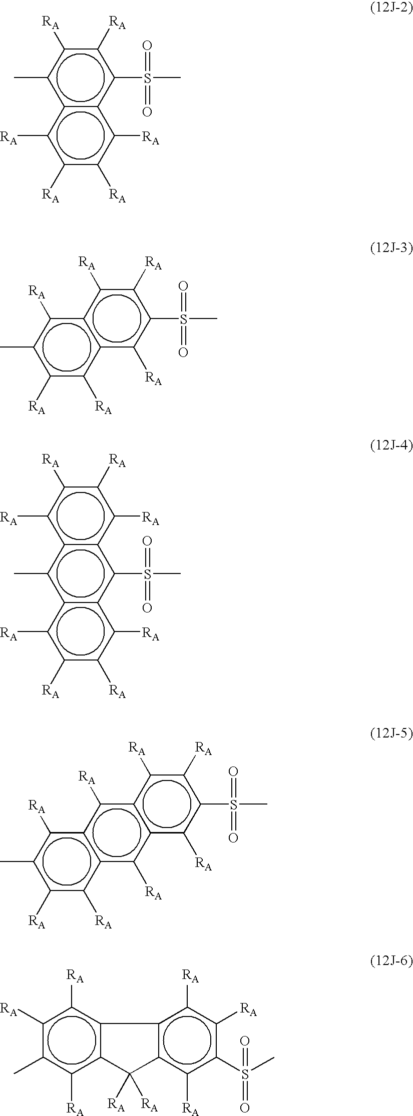

wherein, R_{A}, Rₐ, R_{b}, R_{c}, R_{d}, and Rₑ are the same as those described previously.

The repeating unit represented by Formula (8) is preferably —CRₐ═CR_{b}—, —C≡C—, —N(R_{c})—, —SO₂—, and —(SiR_{d}Rₑ)_{q}—. More preferably, it is —CRₐ═CR_{b}— and —N(R_{c})—. Even more preferably, it is —N(R_{c})—.

The polyarylene of the present invention is, for example,

polyarylene a: comprising only one type of repeating unit represented by Formula (1);

polyarylene b: comprising one type of repeating unit represented by Formula (1) and one or more types (particularly, one type or more and 10 types or less) of repeating units represented by Formulas (5), (6), (7), or (8);

polyarylene b-1: comprising one type of repeating unit represented by Formula (1), one or more types and ten types or less (particularly one type or more and 5 types or less, more particularly 1 type or more and 3 types or less, and more particularly 1 type or more and 2 types or less) of a repeating unit represented by Formulas (5) or (6);

polyarylene b-2: comprising one type of repeating unit represented by Formula (1) and one type of repeating unit represented by Formula (5);

polyarylene b-3: comprising one type of repeating unit represented by Formula (1) and one type of repeating unit represented by Formula (6);

polyarylene b-4: comprising one type of repeating unit represented by Formula (1) and one type of repeating unit represented by Formula (5) and one type of repeating unit represented by Formula (6); and the like.

Preferably, it is polyarylene a and polyarylene b, and more preferably it is polyarylene a. Polyarylene b is preferably polyarylene b-1, and more preferably it is polyarylene b-2, polyarylene b-3, polyarylene b-4. More preferably, it is polyarylene b-3 and polyarylene b-4.

In addition, in polyarylene b, a plurality of blocks represented by the aforementioned Formula (BR) is present, and preferably they are distributed in g of the plurality of Formula (BR).

Polyarylene b-2, b-3, and b-4 preferably have 3 or more blocks represented by the previous Formula (BR) per polymer chain. In other words, preferably the following Formula (BR-2) is satisfied,

(Xn×b1/N_{Q})≧3 Formula (BR-2)

wherein (BR-2), N_{Q} is the average chain number represented by Formula (A2), Xn is the number average polymerization degree of polyarylene b-2, b-3, or b-4 and is represented by the following Formula,

Xn=Mn′/{(b1×M1)+(b2×M2)+(b3×M3)}

wherein Mn′ represents the polystyrene-reduced number average molecular weight measured by SEC of polyarylene b-2, b-3, or b-4; b1, b2, and b3 are each the mol fraction of the repeating unit represented by Formula (1) in polyarylene b-2, b-3, or b-4, mol fraction of the repeating unit represented by Formula (5), and mol fraction of the repeating unit represented by Formula (6), respectively M1, M2, and M3 are each the Formula weight of the repeating unit represented by Formula (1) in polyarylene b-2, polyarylene b-3, or b-4, Formula weight of the repeating unit represented by Formula (5), Formula weight of repeating unit represented by Formula (6), respectively.

Although the terminal structure of the polyarylene of the present invention is not limited, preferably, it is a hydrogen atom and a substituent represented by Ar¹ of Formula (1), more preferably, it is a hydrogen atom, hydrocarbon group, hydrocarbon oxy group, halogen atom. Even more preferably, it is a hydrogen atom and hydrocarbon group.

The details of the preferred method for producing the polyarylene of the present invention is described below.

The polyarylene of the present invention is produced by polycondensation with the compound shown in the following Formula (A) as one of the raw materials,

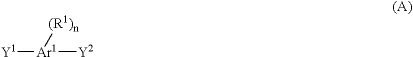

wherein Ar¹, R¹, and n are defined the same as in Ar¹, R¹, and n of Formula (1). In Formula (A), Y¹ each independently represents a halogen atom, a sulfonate group represented by Formula (B), or a methoxy group. In Formula (A), Y² is a borate ester group, boric acid group, group represented by Formula (C), group represented by Formula (D), or a group represented by Formula (E),

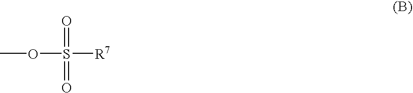

wherein R⁷ represents a hydrocarbon group that can be substituted, and examples for the hydrocarbon group are the same as those given for the hydrocarbon group represented by R¹ of Formula (1). This hydrocarbon group can be substituted with a halogen atom, nitro group, cyano group, acyl group, amino group, and hydrocarbon oxycarbonyl group, and the like. For the halogen atom, acyl group, amino group, and hydrocarbon oxycarbonyl group, examples are the same as those described previously,

—MgX_{A} (C)

wherein X_{A} represents a halogen atom. For the halogen atom, examples include chlorine atom, bromine atom, and iodine atom,

—ZnX_{A} (D)

wherein X_{A} represents a halogen atom. For the halogen atom, examples include chlorine atom, bromine atom, and iodine atom,

—Sn(R⁸)₃ (E)

wherein R⁸ represents a hydrocarbon group that can be substituted. For the hydrocarbon group, examples are the same as those given for the hydrocarbon group represented by R¹ of Formula (1). The plurality of R⁸ can be the same or different from each other. This hydrocarbon group can be substituted with a halogen atom, nitro group, cyano group, acyl group, amino group, hydrocarbon oxycarbonyl group, and the like. For the halogen atom, acyl group, amino group, and hydrocarbon oxycarbonyl group, examples are the same as those described previously.

The Y¹ in the Formula (A) each independently represents a halogen atom, a sulfonate group represented by Formula (B), or a methoxy group.

For the halogen atom in Y¹ of Formula (A), examples include chlorine atom, bromine atom, and iodine atom.

For the hydrocarbon group of R⁷ in Formula (B), examples are the same as those of the hydrocarbon group represented by R¹ in Formula (1). This hydrocarbon group can be substituted with a halogen atom, nitro group, cyano group, acyl group, amino group, hydrocarbon oxycarbonyl group, and the like. Examples of the halogen atom, acyl group, amino group, and hydrocarbon oxycarbonyl group are the same as given previously. Examples of sulfonate group represented by Formula (B) include methane sulfonate group, trifluoromethane sulfonate group, phenyl sulfonate group, 4-methyl phenyl sulfonate group, and the like.

In Formula (A), Y² represents a borate ester group, boric acid group, group represented by Formula (C), group represented by Formula (D), or group represented by Formula (E).

For the borate ester of Y² in Formula (A), examples include the groups indicated by the following Formula.

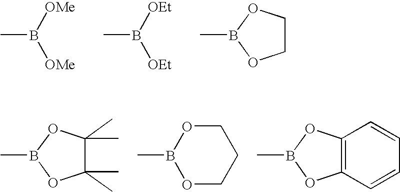

For the compound represented by Formula (A), ones that have already been synthesized and isolated can be used, or ones which have been prepared in the reaction system can be used.

From the standpoint of ease of synthesis, ease of handling, and toxicity and the like, the Y² in Formula (A) is preferably a borate ester group, boric acid group, a group represented by Formula (C). It is preferably a borate ester group or a boric acid group.

When synthesizing a polyarylene comprising only one type of repeating unit represented by Formula (1), for example, this is synthesized through polycondensation of only the monomer represented by Formula (A).

In addition, when synthesizing a polyarylene comprising a repeating unit represented by Formula (1) and a repeating unit represented by Formulas (5) or (6), for example, this can be synthesized by selecting only the necessary types of monomers represented by Formula (A) and monomers represented by the following Formula (F) or the following Formula (G) and conducting polycondensation,

Y³—Ar₂—Y⁴ (F)

wherein Ar₂ is defined as in the previously described Formula (5), Y³ and Y⁴ each independently indicate a group represented by Y¹ or Y² of Formula (A),

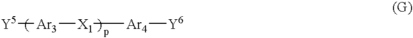

wherein Ar₃, Ar₄, X₁, and p are each defined as in the previously described Formula (6). Y⁵ and Y⁶ are each independently defined as in Formula (A).

An example for a method for polycondensation includes a method for reacting the monomer indicated by Formula (A) using a suitable catalyst and suitable base as necessary.

Examples for catalysts for polycondensation include, for example, transition metal complexes such as palladium complexes, such as palladium[tetrakis (triphenyl phosphine)], [tris(dibenzylidene acetone)]dipalladium, palladium acetate, [bis(triphenyl phosphine)]dichloropalladium, and the like; nickel complexes, such as nickel[tetrakis(triphenyl phosphine)], [1,3-bis(diphenyl phosphino) propane]dichloronickel, [bis(1,4-cyclooctadiene)]nickel, and the like; and if necessary, catalysts comprising ligands such as triphenyl phosphine, tris(o-tolyl)phosphine, tris(p-tolyl)phosphine, tris(o-methoxy phenyl)phosphine, tris(p-methoxy phenyl)phosphine, tri(t-butyl phosphine), tricyclohexyl phosphine, diphenyl phosphino propane, bipyridyl, and the like.

For this catalyst, ones that have already been synthesized can be used, or ones which have been prepared in the reaction system can be used. In the present invention, the catalyst can be used singly, or two or more types can be mixed and used.

This catalyst can be used in an amount that is appropriate, but in general, the amount of transition metal compound with respect to the compound indicated in Formula (A) is preferably 0.001-300 mol %, more preferably 0.005 to 50 mol %, and even more preferably 0.01 to 20 mol %.

In polycondensation, there are situations when a base can be used as necessary. For the base, examples include inorganic bases, such as sodium carbonate, potassium carbonate, cesium carbonate, potassium fluoride, cesium fluoride, tripotassium phosphate, organic bases such as tetra-butylammonium fluoride, tetrabutyl ammonium chloride, tetrabutyl ammonium bromide, tetrabutyl ammonium hydroxide, and the like.

This base can be used in an amount that is appropriate, but in general, it is 0.5-20 equivalents with respect to the compound shown in Formula (A), and more preferably 1-10 equivalents.

The polycondensation can be implemented without the presence of a solvent, but normally, it is conducted in the presence of an organic solvent.

Examples of the organic solvent to be used include tetrahydrofuran, benzene, toluene, xylene, mesitylene, 1,4-dioxane, dimethoxy ethane, N,N-dimethyl acetamide, N,N-dimethyl formamide, and the like. These organic solvents can be used singly or two or more types can be mixed and combined.

For the usage amount of the organic solvent, it is normally at a ratio such that the monomer concentration is 0.1-90 wt %. Preferably, the ratio is 1-50 wt %, and more preferably the ratio is 2-30 wt %.

Although it may differ depending on the reaction and the compounds to be used, in general, the organic solvent preferably has deoxygenation treatment in order to suppress side-reactions.

As long as the reaction temperature for implementing the polycondensation is within a range which maintains the reaction medium as a liquid, the reaction temperature is not particularly limited. Preferably, the temperature range is −100° C. to 200° C. More preferably, the temperature range is −80° C. to 150° C., and more preferably 0° C. to 120° C.

The reaction time will change depending on reaction conditions such as reaction temperature and the like, but normally, it is 1 hour or more and preferably it is 2 to 500 hours.

There may be situations when it is desirable to conduct the polycondensation under anhydrous conditions as needed. In particular, when Y² of the compound indicated by Formula (A) is a group represented by Formula (C), it is necessary to conduct under anhydrous conditions.

It is possible to conduct according to. For example, the target polymer compound can be obtained by adding the reaction solution to a lower alcohol such as methanol or the like and filtering and drying the deposited precipitate.

If the purity of the polymer compound obtained by the aftertreatment as described above is low, purification by the usual methods such as recrystallization, continuous extraction by a Soxhlet extraction apparatus, column chromatography and the like is possible.

Next, a polymer light-emitting device according to the present invention will be explained.

The polymer light-emitting device of the present invention is characterized by having an organic layer, which is positioned between the electrodes consisting of an anode and a cathode and contains a polymer compound according to the present invention.

The organic layer may be any one of a light-emitting layer, hole transport layer, hole injecting layer, electron transport layer, electron injection layer and interlayer; however, the organic layer is preferably a light-emitting layer.

The light-emitting layer herein refers to a layer having a function of emitting light. The hole transport layer refers to a layer having a function of transporting holes. The electron transport layer refers to a layer having a function of transporting electrons. Furthermore, the interlayer refers to a layer positioned between the light-emitting layer and the cathode and adjacent to the light-emitting layer and playing a role of isolating the light-emitting layer from the cathode or light-emitting layer from the hole injection layer or the hole transport layer. Not that the electron transport layer and hole transport layer are collectively referred to as a charge transport layer. Furthermore, the electron injection layer and hole injection layer are collectively referred to as a charge injection layer. The light-emitting layer, hole transport layer, hole injection layer, electron transport layer, and electron injection layer each independently consisting of two or more layers may be used.

When an organic layer serves as a light-emitting layer, the light-emitting layer consisting of the organic layer may further contain a hole transportable material, an electron transportable material or a light-emitting material. The light-emitting material herein refers to a material emitting fluorescence and/or phosphorescence.

When a polymer compound according to the present invention is mixed with a hole transportable material, the mixing ratio of the hole transportable material relative to the total mixture is 1 wt % to 80 wt %, and preferably 5 wt % to 60 wt %. When a polymer material according to the present invention is mixed with an electron transportable material, the mixing ratio of the electron transportable material relative to the total mixture is 1 wt % to 80 wt %, and preferably, 5 wt % to 60 wt %. When a polymer compound according to the present invention is mixed with a light-emitting material, the mixing ratio of the light-emitting material relative to the total mixture is 1 wt % to 80 wt %, and preferably, 5 wt % to 60 wt %. When a polymer compound according to the present invention is mixed with a light-emitting material, hole transportable material and/or electron transportable material, the mixing ratio of the light-emitting material relative to the total mixture is 1 wt % to 50 wt %, and preferably, 5 wt % to 40 wt %; and the ratio of the hole transportable material plus electron transportable material is 1 wt % to 50 wt %, and preferably, 5 wt % to 40 wt %. Therefore, the content of the polymer compound of the present invention is 98 wt % to 1 wt %, and preferably, 90 wt % to 20 wt %.

As the hole transportable material, electron transportable material and light-emitting material, a known low molecular weight compound, triplet light-emitting complex or polymer compound may be used; however, a polymer compound is preferably used.

As the polymer hole transportable material, electron transportable material and light-emitting material, mention may be made of a polyfluorene and a derivative and copolymer thereof; a polyarylene and a derivative and copolymer thereof; a polyarylenevinylene and a derivative and copolymer thereof; and a copolymer of an aromatic amine and a derivative thereof, which are disclosed, for example, in WO99/13692, WO99/48160, GB2340304A, WO00/53656, WO01/19834, WO00/55927, GB2348316, WO00/46321, WO00/06665, WO99/54943, WO99/54385, U.S. Pat. No. 5,777,070, WO98/06773, WO97/05184, WO00/35987, WO00/53655, WO01/34722, WO99/24526, WO00/22027, WO00/22026, WO98/27136, U.S. Pat. No. 573,636, WO98/21262, U.S. Pat. No. 5,741,921, WO97/09394, WO96/29356, WO96/10617, EP0707020, WO95/07955, JP-A-2001-181618, JP-A-2001-123156, JP-A-2001-3045, JP-A-2000-351967, JP-A-2000-303066, JP-A-2000-299189, JP-A-2000-252065, JP-A-2000-136379, JP-A-2000-104057, JP-A-2000-80167, JP-A-10-324870, JP-A-10-114891, JP-A-9-111233 and JP-A-9-45478.

As a fluorescent material of a low molecular weight compound, use may be made of a naphthalene derivative, anthracene or a derivative thereof; perylene or a derivative thereof; a dye such as polymethine base, xanthene base, coumarin base or cyanine base dye, a metallic complex of 8-hydroxyquinoline or a derivative thereof; aromatic amine; tetraphenylcyclopentadiene or a derivative thereof; or tetraphenylbutadiene or a derivative thereof.

More specifically, known compounds, for example, described in JP-A-57-51781 and 59-194393 may be used.

Examples of the triplet light-emitting complex include Ir(ppy)₃Btp₂Ir(acac) containing iridium as a core metal, PtOEP containing platinum as a core metal and Eu(TTA)₃phen containing europium as a core metal.

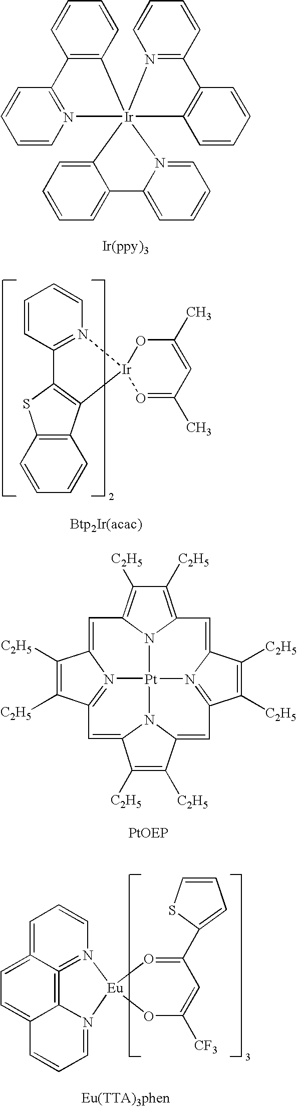

Specific examples of the triplet light-emitting complex are described, for example, in Nature, (1998), 395, 151; Appl. Phys. Lett. (1999), 75(1), 4; Proc. SPIE—lnt. Soc. Opt. Eng. (2001), 4105 (Organic Light-emitting Materials and Devices IV), 119; J. Am. Chem. Soc., (2001), 123, 4304; Appl Phys. Lett., (1997), 71 (18), 2596; Syn, Met., (1998), 94(1), 103; Syn. Met., (1999), 99 (2), 1361; Adv. Mater., (1999), 11(10), 852; and Jpn. J. Appl. Phys., 34, 1883 (1995).

A composition according to the present invention contains at least one type of material selected from a hole transportable material, electron transportable material and light-emitting material and a polymer compound according to the present invention and is used as a light-emitting material or a charge transport material.

The content ratio of at least one type of material selected from a hole transportable material, electron transportable material and light-emitting material as mentioned above relative to the polymer compound of the present invention may be determined depending upon the application; however, when the composition is as a light-emitting material, the content ratio is preferably the same as in the light-emitting layer.

The polystyrene-reduced number average molecular weight of the polymer composition of the present invention is normally about 10³-10⁸, and preferably 10⁴-10⁶. Also, the weight average molecular weight is normally about 10³-10⁸, and preferably 1×10⁴-5×10⁶ from the view points of film formation and efficiency of the device made thereof. An average molecular weight of a polymer composition is herein defined as a value obtained by analyzing using GPC a composition obtained by mixing 2 or more types of polymer compounds.

In a light-emitting layer that the polymer light-emitting device of the present invention has, the optimal value of film thickness differs depending upon the material to be used and may be selected so as to have appropriate driving voltage value and light emission efficiency value. The film thickness is, for example, 1 nm to 1 μm, preferably 2 nm to 500 nm, and further preferably, 5 nm to 200 nm.

Examples of a method for forming the light-emitting layer include a method of forming a film from a solution. Examples of the method of forming a film from a solution include coating methods such as spin-coating method, casting method, microgravure coating method, gravure-coating method, bar-coating method, roll-coating method, wire-bar coating method, dip-coating method, spray-coating method, screen printing method, flexographic printing method, offset printing method, and inkjet printing method. In view of ease of pattern formation and multicolor coating, printing methods such as a screen printing method, flexographic printing method, offset printing method, and inkjet printing method are preferable.

As the ink composition to be used in printing methods, any composition may be used as long as at least one type of polymer compound according to the present invention is contained. The composition may contain a hole transportable material, electron transportable material, light-emitting material, solvent and additives such as a stabilizer may be contained other than a polymer compound according to the present invention.

The ratio of the polymer compound according to the present invention in the ink composition is generally 20 wt % to 100 wt % based on the total weight of the composition excluding a solvent and preferably 40 wt % to 100 wt %.

Furthermore, when a solvent is contained in an ink composition, the ratio of the solvent is generally 1 wt % to 99.9 wt % based on the total weight of the composition, preferably 60 wt % to 99.5 wt % and more preferably, 80 wt % to 99.0 wt %.

The viscosity of the ink composition varies depending upon the printing method. When the ink composition passes through an ejection apparatus in the case of inkjet printing method, the viscosity preferably falls within the range of 1 to 20 mPa·s at 25° C. in order to prevent clogging and bending at the time of ejection.

The solution of the present invention may contain additives for controlling viscosity and/or surface tension other than a polymer compound according to the present invention. Examples of the additives include a polymer compound (thickener) of a high molecular weight and a poor solvent for increasing viscosity, a polymer compound of a low molecular weight for reducing viscosity, and a surfactant for reducing surface tension may be used in an appropriate combination.

As the polymer compound of a high molecular weight, any polymer may be used as long as it is soluble in the same solvent as that of a polymer compound according to the present invention and as long as it does not inhibit light emission and charge transport. For example, polystyrene and polymethyl methacrylate of a high molecular weight or a polymer compound having a larger molecular weight of the polymer compounds of the present invention can be used. The weight average molecular weight is preferably 0.5 million or more and more preferably 1 million or more.

A poor solvent can be used as a thickener. More specifically, viscosity can be increased by adding a small amount of poor solvent for the solid matter of the solution. When a poor solvent is added for this purpose, any type and addition amount of the solvent may be used as long as the solid matter of the solution does not precipitate. In consideration of the stability during storage, the amount of the poor solvent is preferably 50 wt % or less relative to the total amount of the solvent and further preferably 30 wt % or less.

A solution according to the present invention may contain an antioxidant other than a polymer compound according to the present invention to improve storage stability. As the antioxidant, any antioxidant may be used as long as it is soluble in the same solvent for a polymer compound according to the present invention and it does not inhibit light emission or charge transport. For example, mention may be made of a phenol based antioxidant and a phosphorus based antioxidant.

The solvent to be used as an ink composition may not be particularly limited; however, mention is preferably made of a solvent capable of dissolving or homogeneously dispersing components of the ink composition except for the solvent. Examples of the solvent include

chlorine base solvents such as chloroform, methane chloride, 1,2-dichloroethane, 1,1,2-trichloroethane, chlorobenzene and o-dichlorobenzene;

ether base solvents such as tetrahydrofuran, dioxane and anisole;

aromatic hydrocarbon base solvents such as toluene and xylene;

aliphatic hydrocarbon base solvents such as cyclohexane; methylcyclohexane, n-pentane, n-hexane, n-heptane, n-octane, n-nonane and n-decane;

ketone base solvents such as acetone, methylethyl ketone, cyclohexanone, benzophenone and acetophenone;

ester solvents such as ethyl acetate, butyl acetate, ethyl-cellosolve acetate, methyl benzoate and phenyl acetate;

polyhydric alcohols such as ethylene glycol, ethylene glycol monobutyl ether, ethylene glycol monoethyl ether, ethylene glycol monomethyl ether, dimethoxyethane, propylene glycol, diethoxymethane, triethylene glycol monoethyl ether, glycerin, and 1,2-hexane diol, and derivatives of these;

alcohol base solvents such as methanol, ethanol, propanol, isopropanol and cyclohexanol;

sulfoxide base solvents such as dimethylsulfoxide; and

amide base solvents such as N-methyl-2-pyrrolidone and N,N-dimethylformamide.

These solvent may be used singly or in a combination of theses.

Of them, in view of solubility, homogeneity during film formation time and viscosity property of a polymer compound and the like, use is preferably made of the aromatic hydrocarbon base solvent, ether base solvent, aliphatic hydrocarbon base solvent, ester base solvent and ketone base solvent; and more preferably, toluene, xylene, ethyl benzene, diethylbenzene, trimethylbenzene, n-propylbenzene, isopropylbenzene, n-butylbenzene, isobutylbenzene, s-butylbenzene, n-hexylbenzene, cychohexylbenzene, 1-methylnaphthalene, tetralin, anisole, ethoxy benzene, cyclohexane, bicyclohexyl, cyclohexenyl-cyclohexanone, n-heptyl-cyclohexane, n-hexyl-cyclohexane, decalin, methyl benzoate, cyclohexanone, 2-propyl-cyclohexanon, 2-heptanon, 3-heptanon, 4-heptanon, 2-octanone, 2-nonanone, 2-decanone, dicyclohexyl ketone, acetophenone and benzophenone.

As the number of types of solvents of the solution, in view of film formability, device characteristics etc., two or more types of solvents are preferable, 2 to 3 types of solvents are more preferable, and 2 types of solvents are further preferable.

When 2 types of solvents are contained in the solution, one of them may be present in a solid state at 25° C. In view of film formability, one of the solvent preferably has a boiling point of 180° C. or more and more preferably 200° C. or more. In view of viscosity, both types of solvents preferably dissolve 1 wt % or more of aromatic polymer at 60° C. and one of the two types of solvents may dissolve 1 wt % or more of aromatic polymer at 25° C.

When 2 types of solvents are contained in the solution, in view of viscosity and film formability, the solvent having the highest boiling point is contained in an amount of 40 to 90 wt % based on the total weight of the solvents in the solution, more preferably 50 to 90 wt %, and further preferably, 65 to 85 wt %.

The number of types of aromatic polymers according to the present invention contained in a solution can be one or two or more. A polymer compound other than a aromatic polymer according to the present invention may be contained as long as it cannot damage device property, etc.

The solution of the present invention may contain water and a metal and a salt thereof in the range of 1 to 1000 ppm. Examples of the metal include lithium, sodium, calcium, potassium, iron, copper, nickel, aluminum, zinc, chrome, manganese, cobalt, platinum and iridium. In addition, silicon, phosphorus, fluorine, chlorine, and/or bromine may be contained within the range of 1 to 1000 ppm.

A thin film can be produced by use of a solution according to the present invention in accordance with a spin-coating method, casting method, microgravure coating method, gravure-coating method, bar-coating method, roll-coating method, wire-bar coating method, dip-coating method, spray-coating method, screen printing method, flexographic printing method, offset printing method, inkjet printing method, or the like. Of them, the solution of the present invention is preferably used when a film is formed by a screen printing method, flexographic printing method, offset printing method, or inkjet printing method, and more preferably by an inkjet printing method.

When a thin film is prepared using the solution of the present invention, baking can be performed at a temperature of 100° C. or higher because the glass transition temperature of the polymer compound included in the solution is high, and the baking at 130° C. causes very little decrease of the device properties. Further, some types of the polymer compound can be baked at a temperature of 160° C. or higher.

Examples of the thin film to be prepared by use of a solution according to the present invention include a light-emitting thin film, electric conductive thin film and organic semiconductor thin film.

The electric conductive thin film of the present invention preferably has a surface resistance of 1 KΩ/∇ or less. The electric conductivity of the thin film can be improved by doping a Lewis acid, an ionic compound and the like. The surface resistance is more preferably 100 KΩ/∇ or less, and further preferably, 10 KΩ/∇ or less.

In the organic semiconductor thin film of the present invention, the value of larger one of an electron mobility and hole mobility is preferably not less than 10⁻⁵ cm²/V/second, more preferably, not less than 10⁻³ cm²/V/second, and further preferably, not less than 10⁻¹ cm²/V/second.

An organic transistor can be formed by forming the organic semiconductor thin film on a Si substrate having an insulating film formed of e.g., SiO₂ and a gate electrode formed therein and forming a source electrode and a drain electrode of Au or the like.

For the polymer light-emitting device of the present invention, when 3.5 V or higher voltage is applied between an anode and a cathode, from the viewpoint of the device luminance and the like the maximum external quantum yield is preferably 1% or greater and more preferably 1.5% or greater.

Examples of a polymer light-emitting device according to the present invention include

a polymer light-emitting device formed by providing an electron transport layer between an cathode and a light-emitting layer;

a polymer light-emitting device formed by providing a hole transport layer between an anode and a light-emitting layer; and

a polymer light-emitting device formed by providing an electron transport layer between an cathode and a light-emitting layer and a hole transport layer between the anode and the light-emitting layer.

For example, the following structures a) to d) are specifically mentioned.

a) anode/light-emitting layer/cathode

b) anode/hole transport layer/light-emitting layer/cathode

c) anode/light-emitting layer/electron transport layer/cathode

d) anode/hole transport layer/light-emitting layer/electron transport layer/cathode

(where the mark “/” means that individual layers are stacked in adjacent to each other.

Furthermore, in each of the structures, an interlayer may be provided between the light-emitting layer and the anode in adjacent to the light-emitting layer. That is, the structures of the following a′)-d′) can be shown as examples.

a′) anode/interlayer/light-emitting layer/cathode

b′) anode/hole transport layer/interlayer/light-emitting layer/cathode

c′) anode/interlayer/light-emitting layer/electron transport layer/cathode

d′) anode/hole transport layer/interlayer/light-emitting layer/electron transport layer/cathode

When a polymer light-emitting device according to the present invention has a hole transport layer, examples of the hole transportable material to be employed include polyvinylcarbazole or a derivative thereof; polysilane or a derivative thereof; polysiloxane derivative having an aromatic amine in a side chain or the main chain; pyrazoline derivative; arylamine derivative; stilbene derivative; triphenyl-diamine derivative; polyaniline or a derivative thereof; polythiophene or a derivative thereof; polypyrrole or a derivative thereof; poly(p-phenylenevinylene) or a derivative thereof; and poly(2,5-thienylenevinylene) or a derivative thereof.

Specific examples of the hole transportable material include those described in JP-A-63-70257, JP-A-63-175860, JP-A-2-135359, JP-A-2-135361, JP-A-2-209988, JP-A-3-37992, and JP-A-3-152184.

Of them, as a hole transportable material for use in hole transport layer, mention may be preferably made of polymer hole transportable materials such as polyvinylcarbazole or a derivative thereof, polysilane or a derivative thereof, a polysiloxane derivative having an aromatic amine compound group in a side chain or the main chain, polyaniline or a derivative thereof, polythiophene or a derivative thereof, poly(p-phenylenevinylene) or a derivative thereof, and poly(2,5-thienylenevinylene) or a derivative thereof; and more preferably, polyvinylcarbazole or a derivative thereof, polysilane or a derivative thereof, a polysiloxane derivative having an aromatic amine in a side chain or the main chain.

Examples of a hole transportable material of a low molecular compound include a pyrazoline derivative, arylamine derivative, stilbene derivative and triphenyl diamine derivative. The hole transportable material of a low molecular compound is preferably used by dispersing it in a polymer binder.

As the polymer binder to be mixed, it is preferred to use one which does not inhibit charge transfer extremely. Furthermore, it is suitable to use one having no intensive absorption to visible light. Example of the polymer binder include poly(N-vinylcarbazole), polyaniline or a derivative thereof, polythiophene or a derivative thereof, poly(p-phenylenevinylene) or a derivative thereof, poly(2,5-thienylenevinylene) or a derivative thereof, polycarbonate, polyacrylate, polymethylacrylate, polymethylmethacrylate, polystyrene, polyvinylchloride and polysiloxane.

Poly(N-vinylcarbazole) or a derivative thereof can be obtained from a vinyl monomer through cation polymerization or radical polymerization.

Examples of polysilane or a derivative thereof include compounds described in Chem. Rev. Vol. No. 89, p. 1359 (1989) and the published specification of British Patent GB2300196. As a synthetic method thereof, the method described in these documents can be used. In particular, the Kipping method can be suitably used.

In polysiloxane or a derivative thereof, since a polysiloxane skeleton structure has no hole transportability, one having the aforementioned structure of a low molecular weight hole transportable material in a side chain or the main chain is suitably used. In particular, one having a hole transportable aromatic amine in a side chain or the main chain may be mentioned.

A method of forming a hole transfer layer film is not particularly limited. In the case of low molecular weight hole transportable material, a method of forming a film from a mixed solution with a polymer binder may be mentioned. In the case of a high molecular weight hole transportable material, a method of forming a film from a solution may be mentioned.

As a solvent for use in film-formation from a solution, one that can dissolve or homogenously disperse a hole transportable material is preferable. Examples of the solvent include

chlorine base solvents such as chloroform, methane chloride, 1,2-dichloroethane, 1,1,2-trichloroethane, chlorobenzene and o-dichlorobenzene;

ether base solvents such as tetrahydrofuran and dioxane;

aromatic hydrocarbon base solvents such as toluene and xylene;

aliphatic hydrocarbon base solvents such as cyclohexane; methylcyclohexane, n-pentane, n-hexane, n-heptane, n-octane, n-nonane and n-decane;

ketone base solvents such as acetone, methylethyl ketone and cyclohexanone;

ester solvents such as ethyl acetate, butyl acetate and ethylcellosolve acetate;

polyhydric alcohols such as ethylene glycol, ethylene glycol monobutyl ether, ethylene glycol monoethyl ether, ethylene glycol monomethyl ether, dimethoxyethane, propylene glycol, diethoxymethane, triethylene glycol monoethyl ether, glycerin and 1,2-hexane diol, and derivatives of these;

alcohol base solvents such as methanol, ethanol, propanol, isopropanol and cyclohexanol;

sulfoxide base solvents such as dimethylsulfoxide; and

amide base solvents such as N-methyl-2-pyrrolidone and N,N-dimethylformamide.

These solvent may be used singly or in combination.

Examples of the film formation method from a solution include a spin-coating method, casting method, microgravure coating method, gravure-coating method, bar-coating method, roll-coating method, wire-bar coating method, dip-coating method, spray-coating method, screen printing method, flexographic printing method, offset printing method and inkjet printing method.

As the film thickness of a hole transport layer, its optimal value varies depending upon the material to be used. The film thickness may be selected such that driving voltage and light emission efficiency take appropriately values. However, it is at least required to have a sufficient film thickness not to produce pin holes. The extremely thick film is not preferable because the driving voltage of the device increases. Accordingly, the film thickness of the hole transport layer is, for example, from 1 nm to 1 μm, preferably 2 nm to 500 nm, and further preferably, 5 nm to 200 nm.

When a polymer light-emitting device according to the present invention has an electron transport layer, as the electron transportable material to be used, a known material may be used. Examples thereof include

a metal complex of oxadiazole derivative thereof;

anthraquinodimethane derivative thereof,

benzoquinone or a derivative thereof,

naphthoquinone or a derivative thereof,

anthraquinone or a derivative thereof,

tetracyanoanthraquino-dimethane or a derivative thereof,

fluorenone derivative,

diphenyl-dicyanoethylene or a derivative thereof;

diphenoquinone derivative, or

8-hydroxyquinoline or a derivative thereof;

polyquinoline or a derivative thereof;

polyquinoxaline or a derivative thereof; and

polyfluorene or a derivative thereof.

Specific examples include those described in JP-A-63-70257, JP-A-63-175860, JP-A-2-135359, JP-A-2-135361, JP-A-2-209988, JP-A-3-37992 and JP-A-3-152184.

Of them, mention is preferably made of a metal complex of oxadiazole derivative thereof,

benzoquinone or a derivative thereof,

anthraquinone or a derivative thereof, or

8-hydroxyquinoline or a derivative thereof;

polyquinoline or a derivative thereof;

polyquinoxaline or a derivative thereof; and

polyfluorene or a derivative thereof, and further preferably,

2-(4-viphenyl)-5-(4-t-butylphenyl)-1,3,4-oxadiazole, benzoquinone, anthraquinone, tris(8-quinolyl)aluminum and polyquinoline.

A film formation method for an electron transport layer is not particularly limited. Examples of a film formation method using a low molecular weight electron transportable material include a vacuum deposition method for forming a film from powder and a method for forming a film from a solution or molten state. Examples of a film formation method using a high molecular weight electron transportable material include a method of forming a film from a solution or molten state. In the method of forming a film from a solution or molten state, a polymer binder as mentioned above may be used together.

As a solvent to be used in forming a film from a solution, one capable of dissolving or homogeneously dispersing an electron transportable material and/or a polymer binder is preferable. Examples of the solvent include

chlorine base solvents such as chloroform, methane chloride, 1,2-dichloroethane, 1,1,2-trichloroethane, chlorobenzene and o-dichlorobenzene;

ether base solvents such as tetrahydrofuran and dioxane;

aromatic hydrocarbon base solvents such as toluene and xylene;

aliphatic hydrocarbon base solvents such as cyclohexane; methylcyclohexane, n-pentane, n-hexane, n-heptane, n-octane, n-nonane and n-decane;

ketone base solvents such as acetone, methylethyl ketone and cyclohexanone;

ester solvents such as ethyl acetate, butyl acetate and ethyl-cellosolve acetate;

polyhydric alcohols such as ethylene glycol, ethylene glycol monobutyl ether, ethylene glycol monoethyl ether, ethylene glycol monomethyl ether, dimethoxyethane, propylene glycol, diethoxymethane, triethylene glycol monoethyl ether, glycerin and 1,2-hexane diol, and derivatives of these;

alcohol base solvents such as methanol, ethanol, propanol, isopropanol and cyclohexanol;

sulfoxide base solvents such as dimethylsulfoxide; and

amide base solvents such as N-methyl-2-pyrrolidone and N,N-dimethylformamide.

These solvent may be used singly or in combination.

As a method of forming a film from a solution or a molten state, use may be made of coating methods such as a spin-coating method, casting method, microgravure coating method, gravure-coating method, bar-coating method, roll-coating method, wire-bar coating method, dip-coating method, spray-coating method, screen printing method, flexographic printing method, offset printing method and inkjet printing method.

As the film thickness of an electron transport layer, its optimal value varies depending upon the material to be used. The film thickness may be selected such that driving voltage and light emission efficiency take appropriately values. However, it is at least required to have a sufficient film thickness not to produce pin holes. The extremely thick film is not preferable because the driving voltage of the device increases. Accordingly, the film thickness of the electron transport layer is, for example, from 1 nm to 1 μm, preferably 2 nm to 500 nm, and further preferably, 5 nm to 200 nm.

Of the charge transport layers provided in adjacent to an electrode, one having a function of improving charge injection efficiency from the electrode and an effect of reducing the driving voltage of the device is generally called particularly as a charge injection layer (hole injection layer, electron injection layer) in some cases.

To improve adhesion properties to an electrode and improve charge injection from the electrode, the charge injection layer or an insulating layer of 2 nm or less in thickness may be provided in adjacent to the electrode. Alternatively, to improve adhesion properties to the interface or to prevent contamination, a thin buffer layer may be inserted into the interface between a charge transport layer and a light-emitting layer.

The order, number and thickness of layers to be stacked can be appropriately set in consideration of light emission efficiency and the lifespan of a device.

In the present invention, as a polymer light-emitting device having a charge injection layer (electron injection layer, hole injection layer) provided therein, mention may be made of a polymer light-emitting device having a charge injection layer in adjacent to a cathode and a polymer light-emitting device having an charge injection layer in adjacent to an anode.

For example, the following structures e) to p) may be specifically mentioned.

e) anode/charge injection layer/light-emitting layer/cathode

f) anode/light-emitting layer/charge injection layer/cathode

g) anode/charge injection layer/light-emitting layer/charge injection layer/cathode

h) anode/charge injection layer/hole transport layer/light-emitting layer/cathode

i) anode/hole transport layer/light-emitting layer/charge injection layer/cathode

j) anode/charge injection layer/hole transport layer/light-emitting layer/charge injection layer/cathode

k) anode/charge injection layer/light-emitting layer/electron transport layer/cathode

l) anode/light-emitting layer/electron transport layer/charge injection layer/cathode

m) anode/charge injection layer/light-emitting layer/electron transport layer/charge injection layer/cathode

n) anode/charge injection layer/hole transport layer/light-emitting layer/electron transport layer/cathode

o) anode/hole transport layer/light-emitting layer/electron transport layer/charge injection layer/cathode

p) anode/charge injection layer/hole transport layer/light-emitting layer/electron transport layer/charge injection layer/cathode.

Furthermore, in each of the structures, an interlayer may be provided between the light-emitting layer and the anode adjacent to the light-emitting layer. In this case, the interlayer may serve as a hole injection layer and/or hole transport layer.

Specific examples of the charge injection layer include

a layer containing an electric conductive polymer;

a layer formed between an anode and a hole transport layer and containing ionization potential value between that of an anode material and a hole transportable material contained in the hole transport layer; and

a layer provided between a cathode and an electron transport layer and having an electron affinity value between that of an anode material and an electron transportable material contained in the electron transport layer.

When the charge injection layer is a layer containing an electric conductive polymer, the electric conductivity of the electric conductive polymer is preferably 10⁻⁵ S/cm to 10³ (both inclusive), more preferably 10⁻⁵ S/cm to 10² (both inclusive), and further preferably 10⁻⁵ S/cm to 10¹ (both inclusive) to reduce a leakage current between light-emitting pixels.

When the charge injection layer is a layer containing an electric conductive polymer, the electric conductivity of the electric conductive polymer is preferably 10⁻⁵ S/cm to 10³ S/cm (both inclusive), more preferably 10⁻⁵ S/cm to 10² S/cm (both inclusive), and further preferably 10⁻⁵ S/cm to 10¹ S/cm (both inclusive) to reduce a leakage current between light-emitting pixels.

To set an electric conductivity of the electric conductive polymer at 10⁻⁵ S/cm to 10³ (both inclusive), generally an appropriate amount of ions are doped in the electric conductive polymer.

The type of ions, if they are doped into a hole injection layer, are anion and if they are doped into an electron injection layer, are cations. Examples of the anions include polystyrene sulfonic acid ion, alkylbenzene sulfonic acid ion and camphor sulfonic acid ion. Examples of the cations include lithium ion, sodium ion, potassium ion and tetrabutylammonium ion.

The film thickness of a charge injection layer is from 1 nm to 100 nm, and preferably, 2 nm to 50 nm.

The material to be used in a charge injection layer may be appropriately selected in connection with the material to be used in a layer adjacent to an electrode. Examples thereof include

polyaniline or a derivative thereof;

polythiophene or a derivative thereof;

polypyrrole or a derivative thereof;

polyphenylenevinylene or a derivative thereof;

polythienylenevinylene or a derivative thereof;

polyquinoline or a derivative thereof;

polyquinoxaline or a derivative thereof;

an electric conductive polymer such as a polymer containing an aromatic amine structure in the main chain or a side chain;

metal phthalocyanine (such as copper phthalocyanine); and

carbon.

The insulating layer having a film thickness of 2 nm or less has a function of facilitating charge injection. Examples of the material of the insulating layer include a metal fluoride, metal oxide and organic insulating material. Examples of a polymer light-emitting device having an insulating layer of a film thickness of 2 nm or less include

a polymer light-emitting device having an insulating layer having a film thickness of 2 nm or less in adjacent to a cathode, and

a polymer LED having an insulating layer having a film thickness of 2 nm or less in adjacent to an anode.

For example, the following structures q) to ab) may be specifically mentioned.

q) anode/insulating layer having a film thickness of 2 nm or less/light-emitting layer/cathode

r) anode/light-emitting layer/insulating layer having a film thickness of 2 nm or less/cathode

s) anode/insulating layer having a film thickness of 2 nm or less/light-emitting layer/insulating layer having a film thickness of 2 nm or less/cathode

t) anode/insulating layer having a film thickness of 2 nm or less/hole transport layer/light-emitting layer/cathode

u) anode/hole transport layer/light-emitting layer/insulating layer having a film thickness of 2 nm or less/cathode

v) anode/insulating layer having a film thickness of 2 nm or less/hole transport layer/light-emitting layer/insulating layer having a film thickness of 2 nm or less/cathode

w) anode/insulating layer having a film thickness of 2 nm or less/light-emitting layer/electron transport layer/cathode

x) anode/light-emitting layer/electron transport layer/insulating layer having a film thickness of 2 nm or less/cathode

y) anode/insulating layer having a film thickness of 2 nm or less/light-emitting layer/electron transport layer/insulating layer having a film thickness of 2 nm or less/cathode

z) anode/insulating layer having a film thickness of 2 nm or less/hole transport layer/light-emitting layer/electron transport layer/cathode

aa) anode/hole transport layer/light-emitting layer/electron transport layer/insulating layer having a film thickness of 2 nm or less/cathode

ab) anode/insulating layer having a film thickness of 2 nm or less/hole transport layer/light-emitting layer/electron transport layer/insulating layer having a film thickness of 2 nm or less/cathode

Furthermore, in each of the structures, an interlayer may be provided between the light-emitting layer and the anode in adjacent to the light-emitting layer. In this case, the interlayer may serve as a hole injection layer and/or hole transport layer.

When an interlayer is applied to the aforementioned structures of a) to ab), the interlayer is preferably provided between an anode and a light-emitting layer and formed of a material which has an intermediate ionization potential between the anode, hole injection layer, or a hole transport layer and a polymer compound constituting the light-emitting layer.

Examples of the material for the interlayer include

a polyvinylcarbazole or a derivative thereof; and

a polymer having an aromatic amine in a side chain or the main chain, such as a polyarylene derivative, arylamine derivative, or triphenyl-diamine derivative.

The method of forming a film of an interlayer is not limited; however, when a polymer material is used, a method of forming a film from a solution may be mentioned.

A solvent to be used for film preparation from the solution is preferably able to dissolve or disperse homogeneously a material to be used for the interlayer. Examples of the solvent include

chlorine base solvents such as chloroform, methane chloride, 1,2-dichloroethane, 1,1,2-trichloroethane, chlorobenzene and o-dichlorobenzene;

ether base solvents such as tetrahydrofuran and dioxane; aromatic hydrocarbon base solvents such as toluene and xylene;

aliphatic hydrocarbon base solvents such as cyclohexane; methylcyclohexane, n-pentane, n-hexane, n-heptane, n-octane, n-nonane and n-decane;

ketone base solvents such as acetone, methylethyl ketone and cyclohexanone;

ester solvents such as ethyl acetate, butyl acetate, and ethyl-cellosolve acetate;

polyhydric alcohols such as ethylene glycol, ethylene glycol monobutyl ether, ethylene glycol monoethyl ether, ethylene glycol monomethyl ether, dimethoxyethane, propylene glycol, diethoxymethane, triethylene glycol monoethyl ether, glycerin, and 1,2-hexane diol, and derivatives of these;

alcohol base solvents such as methanol, ethanol, propanol, isopropanol and cyclohexanol;

sulfoxide base solvents such as dimethylsulfoxide; and

amide base solvents such as N-methyl-2-pyrrolidone and N,N-dimethylformamide.

These organic solvent may be used singly or in a combination of theses.

Examples of the method of forming a film from a solution include coating methods such as spin-coating method, casting method, microgravure coating method, gravure-coating method, bar-coating method, roll-coating method, wire-bar coating method, dip-coating method, spray-coating method, screen printing method, flexographic printing method, offset printing method, and inkjet printing method.

The film thickness of an interlayer differs in optimal value depending upon the material to be used and may be selected so as to have appropriate driving voltage value and light emission efficiency value. The film thickness is, for example, 1 nm to 1 μm, preferably 2 nm to 500 nm, and further preferably, 5 nm to 200 nm.

When the interlayer is provided in adjacent to a light-emitting layer, in particular, when both layers are formed by a coating method, the materials for the two layers are sometimes mixed with each other and negatively affect the characteristics of a device. When the interlayer is provided by a coating method and thereafter the light-emitting layer is formed by a coating method, as a method of reducing contamination of the materials for the two layers, mention may be made of a method in which the interlayer is formed by a coating method and thereafter, the interlayer is heated to render it insoluble to the organic solvent to be used for forming the light-emitting layer, and then the light-emitting layer is formed. The heating is generally performed at a temperature of about 150° C. to 300° C. and generally for about 1 minute to 1 hour. In this case, components which fail to be insoluble in the solvent can be removed by rinsing the interlayer with the solvent to be used for forming the light-emitting layer after heating and before forming the light-emitting layer. When insolubilization treatment is sufficiently performed by heating, rinse with the solvent is not required. To sufficiently perform insolubilization treatment by heating, a polymer compound containing at least one polymerizable group in a molecule is preferably used in the interlayer. In addition, the number of polymerizable groups is preferably 5% relative to the number of repeat units in a molecule.

As a substrate on which a polymer light-emitting device according to the present invention is formed, any substrate may be used as long as it cannot be influenced when an electrode is formed and then an organic material layer is formed. Examples of the substrate include substrates formed of glass, plastic, polymer film and silicon. When an opaque substrate is used, the opposite electrode is preferably transparent or semitransparent.

Generally, in a polymer light-emitting device according to the present invention, at least one of the anode or cathode is transparent or semitransparent. The anode is preferably transparent or semitransparent.

As the material for the anode, use may be made of, for example, a conductive metal oxide film and semitransparent metal thin film. Specific examples thereof include a film (NESA) formed of electrically conductive glass made of, for example, indium oxide, zinc oxide, tin oxide; and composites these such as indium tin oxide (ITO), indium/zinc/oxide, gold, platinum, silver and copper; and ITO, indium/zinc/oxide and tin oxide are preferable. Examples of the forming method include a vacuum deposition method, sputtering method, ion plating method and plating method. Furthermore, as the anode, use may be made of an organic electric conductive film such as polyaniline or a derivative thereof or polythiophene or a derivative thereof.

The film thickness of an anode may be appropriately set in consideration of light permeability and electric conductivity, and is for example, 10 nm to 10 μm, preferably, 20 nm to 1 μm, and further preferably, 50 nm to 500 nm.

To facilitate injection of charge, a layer having an average thickness of 2 nm and formed of a phthalocyanine derivative, electric conductive polymer or carbon or formed of a metal oxide, metal fluoride or an organic insulating material, may be provided on the anode.

As a material for the cathode to be used in a polymer light-emitting device according to the present invention, one having a small work function is preferable. Examples of the material to be used include

metals such as lithium, sodium, potassium, rubidium, cesium, beryllium, magnesium, calcium, strontium, barium, aluminum, scandium, vanadium, zinc, yttrium, indium, cerium, samarium, europium, terbium, and ytterbium;

alloys formed of at least two of them;

alloys formed of at least one of them and one selected from the group consisting of gold, silver, platinum, copper, manganese, titanium, cobalt, nickel, tungsten and tin;

graphite; and a graphite intercalation compound.

Examples of the alloy include

Magnesium-silver alloy, magnesium-indium alloy, magnesium-aluminum alloy, indium-silver alloy, lithium-aluminum alloy, lithium-magnesium alloy, lithium-indium alloy and calcium-aluminum alloy. The cathode may have a stacked structure consisting of two or more layers.

The film thickness of a cathode may be appropriately set in consideration of electric conductivity and durability, and is for example, 10 nm to 10 μm, preferably 20 nm to 1 μm and further preferable 50 nm to 500 nm.

Examples of the method of forming a cathode include a vacuum deposition method, sputtering method, and laminate method in which a metal thin film is formed by thermocompression bonding. Furthermore, a layer formed of an electric conductive polymer or a layer formed of e.g., a metal oxide, metal fluoride, or organic insulating material and having an average film thickness of 2 nm or less may be provided between the cathode and an organic layer. Alternatively, after the cathode is formed, a protecting layer for protecting the polymer light-emitting device may be applied. To use the polymer light-emitting device stably for a long time, the device may be externally protected preferably with a protecting layer and/or a protecting cover.

As the protecting layer, use may be made of e.g., a polymer compound, metal oxide, metal fluoride and metal borate. Furthermore, as the protecting cover, use may be made of e.g., metal plate, glass plate and plastic plate on the surface of which treatment of lowing water permeability is applied. A method of adhering the cover tight with the substrate of a device with a thermoplastic resin or a photosetting resin, thereby sealing them, is preferably used. It is easy to prevent the device from being damaged by keeping a space by use of a spacer. Oxidation of the cathode can be prevented by filling the space with an inert gas such as nitrogen and argon, and further, by placing a drying agent such as barium oxide, it becomes easier to control a damage to the device by water which was absorbed during the production process or a minute amount of water which infiltrates through a cured resin. It is preferred to take one or more of the above measures.

A polymer light-emitting device according to the present invention may be used as a planar light source or a backlight of a segment type display device, a dot matrix display device and a liquid crystal display device.

To obtain planar light emission by use of a polymer light-emitting device according to the present invention, a planar anode and a planar cathode are placed so as to overlap with each other. To obtain patterned light emission, there are

a method in which a mask having a patterned window is provided on the surface of the planar light-emitting device;

a method in which an organic material layer used in non light-emitting portion is formed extremely thick substantially not to emit light from the portion; and

a method in which either one of or both of the anode and cathode are formed so as to have a pattern.

A pattern is formed in accordance with any one of the methods, and several electrodes are arranged so as to independently turn ON/Off. In this way, it is possible to obtain a segment type display device capable of displaying numerical values, characters, and simple symbols. Furthermore, to obtain a dot-matrix device, both an anode and a cathode may be formed in stripe form and arranged so as to cross perpendicularly with each other. Sector color display and multicolor display can be attained by a method of separately applying a plurality of types of polymer phosphors different in emission color, or by a method of using a color filter or a fluorescent conversion filter. A dot matrix device can be driven passively and may be driven actively in combination with, for example, TFT. These display devices can be used as display devices of a computer, television, portable handheld unit, mobile phone, car navigation and a view finder of a video camera, etc.

Furthermore, the planar light-emitting device is a thin-film spontaneous light-emitting device and suitably used as a planar light source for a backlight of a liquid crystal display device or a planar illumination light source. Furthermore, if a flexible substrate is used, the planar light-emitting device can be used also as a curved surface light source or display device.

### EXAMPLES

Following is the detailed description of the present invention by Examples but the present invention is not limited by these.

NMR measurements were performed under the following conditions.

Apparatus: Avance 600 (commercial name) Nuclear Magnetic Resonance Apparatus, made by Bruker Inc.

Measurement solvent: deuterated tetrahydrofuran

Sample concentration: about 1 wt %

Measurement temperature: 30° C.

A polystyrene-reduced number average molecular weight (Mn) and weight average molecular weight (Mw) were obtained by SEC using the following SEC condition 1.

### <SEC Condition 1>

Apparatus: PL-GPC210 system (commercial name) (RI detection) made by Polymer Laboratories Ltd.

Column: PLgel 10 μm MIXED-B (commercial name) made by Polymer Laboratories Ltd. 3 columns

Mobile phase: o-dichlorobenzene

Thermogravimetry was performed using THERMOFLEX TAS200 TG8101D (commercial name) made by Rigaku Co. Ltd. under atmospheric stream at a rate of 80 cc/minute, and a rate of weight reduction was measured after raising temperature at a rate of 10° C./minute from 20° C. to 400° C.

### Comparative Example 1

### Synthesis of Polymer Compound 1

After dissolving 9.875 g of 5,9-dibromo-7,7-dioctyl-7H-benzo[c]fluorene (compound A) and 6.958 g of 2,2′-bipyridyl in 1188 ml of anhydrous tetrahydrofuran, the solution was heated to 60° C. under a nitrogen atmosphere, mixed with 12.253 g of bis(1,5-cyclooctadiene)Ni(0){Ni(COD)₂} and reacted for 3 hours. After the reaction, the reaction solution was cooled to room temperature, instilled to a mixed solution of 59 ml of 25% ammonia water/1188 ml of methanol/118 ml of ion exchanged water and stirred for 30 minutes, and then deposited precipitates were filtered and dried for 2 hours under reduced pressure. Next, 2 batch operations were performed under the same conditions as described above except the scale was expanded to 1.09 fold, and precipitates were obtained in each operation. The precipitates obtained from the 3 batches were combined and was dissolved in 1575 ml of toluene. After dissolving, 6.30 g of radiolight was added to the solution, stirred for 30 minutes and insoluble materials were filtered off. A filtrate thus obtained was passed through an alumina column for purification. Next, 3098 ml of 5.2% aqueous hydrochloric acid was added and after stirring the mixture for 3 hours, the aqueous layer was removed. Subsequently, 3098 ml of 4% ammonia water was added, stirred for 2 hours and the aqueous layer was removed. Further, about 3098 ml of ion exchanged water was added to the organic layer, stirred for 1 hour and then the aqueous layer was removed. Then, the organic layer was added to 4935 ml of methanol, stirred for 1 hour, and deposited precipitates were filtered and dried under reduced pressure. The polymer compound thus obtained (hereinafter, designated as polymer compound 1) is a polymer compound consists of the following (repeating unit A) only, and the yield was 15.460 g. Also, the polystyrene-reduced number average molecular weight and weight average molecular weight by the SEC condition 1 were Mn=72000 and Mw=495000, respectively. The Formula weight of the repeating unit of the polymer, FW₁ was 438.7 and the average chain number was 164.

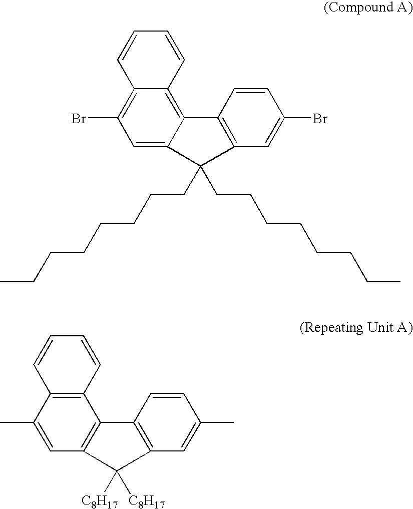

### Attribution of Diad Peaks of Polymer Compound 1

¹H detection ¹H-¹³C, 2 dimensional correlation spectra (HMQC spectra) measurement was performed for polymer compound 1, and chemical shifts of proton indicated by H_{A1}, H_{B1} and H_{C1} in the Formula (a) representing a diad were 7.67 ppm, 7.39 ppm and 7.80 ppm, respectively, and chemical shifts of carbon 13 indicated by C_{A1}, C_{B1} and C_{C1} in the Formula (a) were 128.1 ppm, 125.4 ppm and 123.9 ppm, respectively, and a proton-carbon 13 correlation peak was observed against pairs of proton and carbon indicated by H_{A1} and C_{A1}, H_{B1} and C_{B1}, and H_{C1} and C_{C1}. While chemical shifts of proton indicated by H_{A2}, H_{B2} and H_{C2} in the Formula (b) representing a diad were 8.23 ppm, 7.55 ppm and 7.78 ppm, respectively, and chemical shifts of carbon 13 indicated by C_{A2}, C_{B2} and C_{C2} in the Formula (b) were 127.8 ppm, 125.4 ppm and 122.5 ppm, respectively, and a proton-carbon 13 correlation peak was observed against pairs of proton and carbon indicated by H_{A2} and C_{A2}, H_{B2} and C_{B2}, and H_{C2} and C_{C2}.

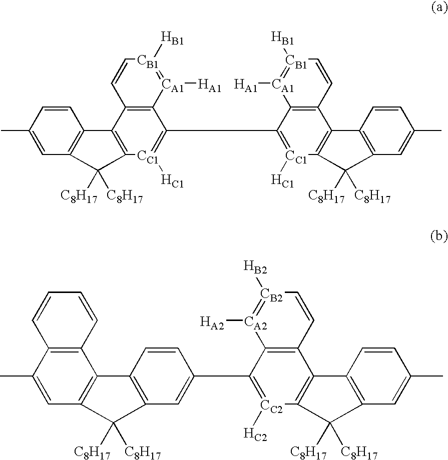

Quantity ratios of H_{A1} and H_{A2}, H_{B1} and H_{B2}, and H_{C1} and H_{C2} were obtained by integrating the intensity of a proton-carbon 13 correlation peak in an HMQC spectra, and the ratio of diad (a) and diad (b) was calculated by taking the numbers of H_{A1}, H_{A2}, H_{B1}, H_{B2}, H_{C1} and H_{C2} in one diad into an account. The results are shown in Table 1.

TABLE 1

| | Location of | | | | | |
|---|---|---|---|---|---|---|
| | correlation | Integrated | Quantity ratio of proton | | | Ratio |
| Diad | peak | intensity | Formula | Value | Average | of diad |
| (a) | H_{A1} and C_{A1} | 539.6 . . . | A1/(A1 + | 0.40 | 0.39 | 0.24 |
| | | (A1) | A2) | | | |
| | H_{B1} and C_{B1} | 1315.1 . . . | B1/(B1 + | 0.39 | | |
| | | (B1) | B2) | | | |
| | H_{C1} and C_{C1} | 2015.4 . . . | C1/(C1 + | 0.38 | | |
| | | (C1) | C2) | | | |
| (b) | H_{A2} and C_{A2} | 822.9 . . . | A2/(A1 + | 0.60 | 0.61 | 0.76 |
| | | (A2) | A2) | | | |
| | H_{B2} and C_{B2} | 2086.5 . . . | B2/(B1 + | 0.61 | | |
| | | (B2) | B2) | | | |
| | H_{C2} and C_{C2} | 3233.8 . . . | C2/(C1 + | 0.62 | | |
| | | (C2) | C2) | | | |

In ¹H detection ¹H-¹³C, 2 dimensional correlation spectra (HMQC spectra) of polymer compound 1, chemical shifts of proton indicated by H_{D2}, and chemical shifts of carbon 13 indicated by C_{D2} in the Formula (c) representing a diad were 7.79 ppm and 125.2 ppm, respectively and a proton-carbon 13 correlation peak was observed against pairs of proton and carbon indicated by H_{D2} and C_{D2}. While, chemical shifts of proton indicated by H_{D3}, and chemical shifts of carbon 13 indicated by C_{D3} in the Formula (d) representing a diad were 8.00 ppm and 121.2 ppm, respectively and a proton-carbon 13 correlation peak was observed against a pair of proton and carbon indicated by H_{D3} and C_{D3}.

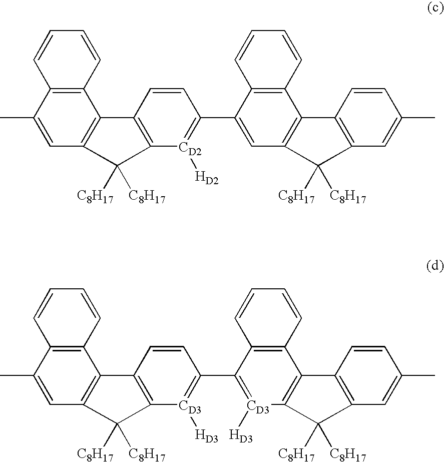

Quantity ratio of H_{D2} and H_{D3}, was obtained by integrating the intensity of a proton-carbon 13 correlation peak, and the ratio of diad (c) and diad (d) was calculated by taking the numbers of H_{D2} and H_{D3} in one diad into an account. The results are shown in Table 2.

TABLE 2

| | Location of | | Quantity ratio of | | |
|---|---|---|---|---|---|
| | correlation | Integrated | proton | | Ratio |
| Diad | peak | intensity | Formula | Value | of diad |
| (c) | H_{D2} and C_{D2} | 2896.8 . . . (D2) | D2/(D2 + D3) | 0.61 | 0.75 |
| (d) | H_{D3} and C_{D3} | 1883.2 . . . (D3) | D3/(D2 + D3) | 0.39 | 0.25 |

Since diad (b) and diad (c) are the same, it was found that the ratio of the 3 types of diads composing polymer compound 1, that are diad (a), diad (b) (or diad (c)) and diad (d), was 24:76:25=19:61:20. The head-tail link in polymer compound 1 is a link formed between the 2 repeating units in diad (b) (or diad (c)), and from the above facts, in polymer compound 1, it was found that the ratio of the number of links formed between the head and tail to the total number of links formed between each other (repeating unit A) is 61%.

### Example 1

### Synthesis of Polymer Compound 2

Under an argon atmosphere, 200 mg (0.31 mmol) of 2-(9-Bromo-7,7-dioctyl-7H-benzo[c]fluoren-5-yl)-4,4,5,5-tetramethyl-[1,3,2]dioxaborolane (compound B), 3.5 mg (0.015 mmol) of palladium acetate and 8.7 mg (0.031 mmol) of tricyclohexylphosphine were added to a 25 ml 2-neck flask connected with a Dimroth condenser, and then the air in the vessel was replaced with argon gas. To the mixture, 12.4 ml of toluene, 5.9 mg (0.023 mmol) of 4-t-butyliodobenzene and 120 μl of n-octylbenzene (internal standard substance) were added and stirred at 110° C. for 10 minutes. To this pale yellow solution, 1.4 ml of 20 wt % hydroxytetraethyl ammonium aqueous solution was added to start the reaction and stirred at 110° C. for 17 hours to continue the reaction. After confirming the loss of compound B by a high speed liquid chromatography, 10 ml of H₂O was added to the reaction mixture, stirred well and an organic layer was separated from an aqueous layer. After concentrating, 9 ml of chloroform was added to the organic layer and this solution was instilled to 72 ml of ethanol to precipitate polymer. The precipitates were recovered by filtration and dried under reduced pressure to obtain 91.8 mg of yellow powder. This powder was dissolved in 6.5 ml of toluene and the solution was passed through a silica gel and alumina column. After concentrating the solution eluted with 13 ml of toluene to about 2 ml, it was instilled into 25 ml of methanol to precipitate. The precipitates were collected by filtration and dried to obtain 51.2 mg (yield 38%) of a polymer composed of (repeating unit A) described above only (hereinafter, designated as polymer compound 2). Also, the polystyrene-reduced number average molecular weight and weight average molecular weight by the SEC condition 1 were Mn=9000 and Mw=17000, respectively. The Formula weight of the repeating unit of the polymer, FW₁ was 438.7 and the average chain number was 21.

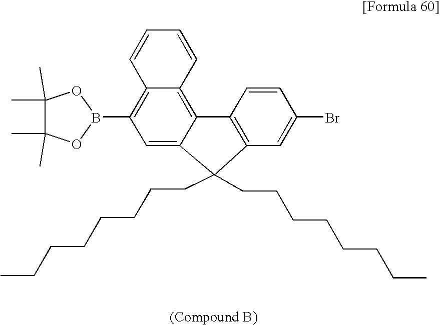

### Attribution of Diad Peaks of Polymer Compound 2

¹H detection ¹H-¹³C, 2 dimensional correlation spectra (HMQC spectra) measurement was performed for polymer compound 2 in the similar manner as for polymer compound 1, and the integrated intensity was obtained by integrating the same range as that of polymer compound 1. Further the ratios of diad (a) to diad (b), and diad (c) and diad (d) were obtained by a similar calculation to that for polymer compound 1. The results are shown in Table 3.

TABLE 3

| | Location of | | | | | Ratio |
|---|---|---|---|---|---|---|
| | correlation | Integrated | Quantity ratio of proton | | | of |
| Diad | peak | intensity | Formula | Value | Average | diad |
| (a) | H_{A1} and C_{A1} | 320.7 . . . | A1/(A1 + | 0.08 | 0.08 | 0.04 |
| | | (A1) | A2) | | | |
| | H_{B1} and C_{B1} | 574.7 . . . | B1/(B1 + | 0.09 | | |
| | | (B1) | B2) | | | |
| | H_{C1} and C_{C1} | 445.3 . . . | C1/(C1 + | 0.06 | | |
| | | (C1) | C2) | | | |
| (b) | H_{A2} and C_{A2} | 3771.4 . . . | A2/(A1 + | 0.92 | 0.92 | 0.96 |
| | | (A2) | A2) | | | |
| | H_{B2} and C_{B2} | 5476.5 . . . | B2/(B1 + | 0.91 | | |
| | | (B2) | B2) | | | |
| | H_{C2} and C_{C2} | 6604.7 . . . | C2/(C1 + | 0.94 | | |
| | | (C2) | C2) | | | |
| (c) | H_{D2} and C_{D2} | 7280.2 . . . | D2/(D2 + | 1.00 | — | 1.00 |
| | | (D2) | D3) | | | |
| (d) | H_{D3} and C_{D3} | 33.4 . . . | D3/(D2 + | 0.00 | — | 0.00 |
| | | (D3) | D3) | | | |

Based on the above results, the ratio of diad (a), diad (b) (or diad (c)) and diad (d) was obtained by a similar calculation to that for polymer compound 1, and found to be 4:96:0. The head-tail link in polymer compound 2 is a link formed between the 2 repeating units in diad (b) (or diad (c)), and from the above facts, it was found that the ratio of the number of links formed between the head and tail to the total number of links formed between each other (repeating unit A) is 96%.

### Comparative Example 2

### Synthesis of Polymer Compound 3

A polymer consisting of only (repeating unit A) described above was obtained from compound A by a similar method to the synthetic method of polymer compound (hereinafter, designated as polymer compound 3. The polystyrene-reduced number average molecular weight and weight average molecular weight by the SEC condition 1 were Mn=17000 and Mw=78000, respectively. The Formula weight of the repeating unit of the polymer, FW₁ was 438.7 and the average chain number was 39.

### Synthesis of Polymer Compound 4

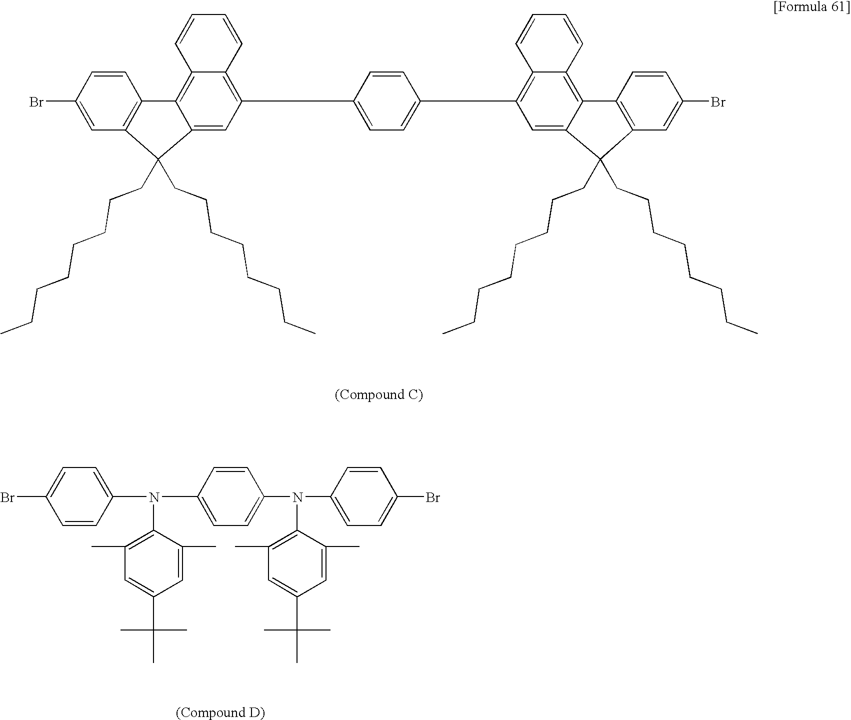

Compound C described above (5.511 g), compound D described above (3.115 g) and 2,2′-bipyridyl (3.865 g) were dissolved in 1320 ml of anhydrous tetrahydrofuran and then heated to 60° C. under a nitrogen atmosphere. Bis(1,5-cyclooctadiene)Ni(0) {Ni(COD)₂} (6.807 g) was added to this solution, stirred and reacted for 3 hours. After the reaction, the mixture was cooled to room temperature, instilled into a mixed solution of 33 ml of 25% aqueous ammonia/1320 ml of methanol/1320 ml of ion exchanged water and stirred for 1 hour. Then deposited precipitates were collected by filtration, dried under reduced pressure and dissolved in 275 ml of toluene. After dissolving, 11 g of radiolight was added to the solution, stirred for 30 minutes and insoluble materials were filtered off. A filtrate thus obtained was passed through an alumina column for purification. The purified solution thus obtained was mixed with 541 ml of 4% aqueous ammonia, stirred for 2 hours and then the aqueous layer was removed. Subsequently, about 541 ml of ion exchanged water was added to the organic layer, stirred for 1 hour and then the aqueous layer was removed. After that, 862 ml methanol was added to the organic layer, stirred for 0.5 hour, and deposited precipitates were collected by filtration and dried under reduced pressure. The yield of the polymer thus obtained (hereinafter, designated as polymer compound 4) was 5.48 g. The polystyrene-reduced number average molecular weight and weight average molecular weight were Mn=20000 and Mw=170000, respectively.

### Production of Light-Emitting Device Made of Polymer Compound 3

### (Preparation of Solution)

Polymer compound 3 and polymer compound 4 were dissolved in toluene at a ratio of 50 wt % and 50 wt %, respectively, to prepare a toluene solution of 2.0 wt % of polymer concentration.

### (Production of EL Device)

On a glass substrate plate on which a 150 nm thick ITO film had been formed by the sputtering method, a 70 nm thick film was formed by spin-coating using a solution which was prepared by filtering a suspension of poly(3,4-ethylenedioxythiophene)/polystyrenesulfonic acid (BaytronP AI4083, Bayer) through a 0.2 μm membrane filter, and dried at 200° C. on a hot plate for 10 minutes. Subsequently, using the toluene solution obtained as described above, a film was formed by the spin-coating method at 2000 rpm. The thickness of thus formed film was about 78 nm. This was further dried under reduced pressure at 80° C. for 1 hour. Then, vacuum depositions were carried out for lithium fluoride to about 4 nm thick, calcium as a cathode to about 5 nm thick and then aluminum to about 80 nm thick to produce an EL device. Vacuum-deposition was started after a vacuum of 1×10⁻⁴ Pa or below was attained.

### (Performance of EL Device)

An EL emission having a peak at 465 nm was obtained from this device by applying a voltage to the device thus obtained. The C. I. E. color coordinate of the EL emission at an applied voltage of 8.0 V was x=0.157, y=0.220. Intensity of the EL emission was almost proportional to an electric current density. Also, this device starts emitting light from 3.1 V and the maximum emission efficiency was 1.47 cd/A.

### (Lifespan Measurement)

The EL device obtained as described above was driven by a constant current of 150 mA/cm², and time dependent change in luminance was measured. The initial luminance of this device was 2150 cd/m² and the halflife was 11.3 hours. By assuming an acceleration coefficient in luminance-lifespan relation is a square and converting to the initial luminance of 400 cd/m², the halflife was 327 hours. Further, the voltage required for driving the device was 8.64 V at the early phase and 9.47 V after the luminance dropped in half, and the voltage change during driving the device was 0.83 V. Still further, the rate of voltage increase calculated from this converted halflife was 2.54 mV/hour.

### Spectra After Driving

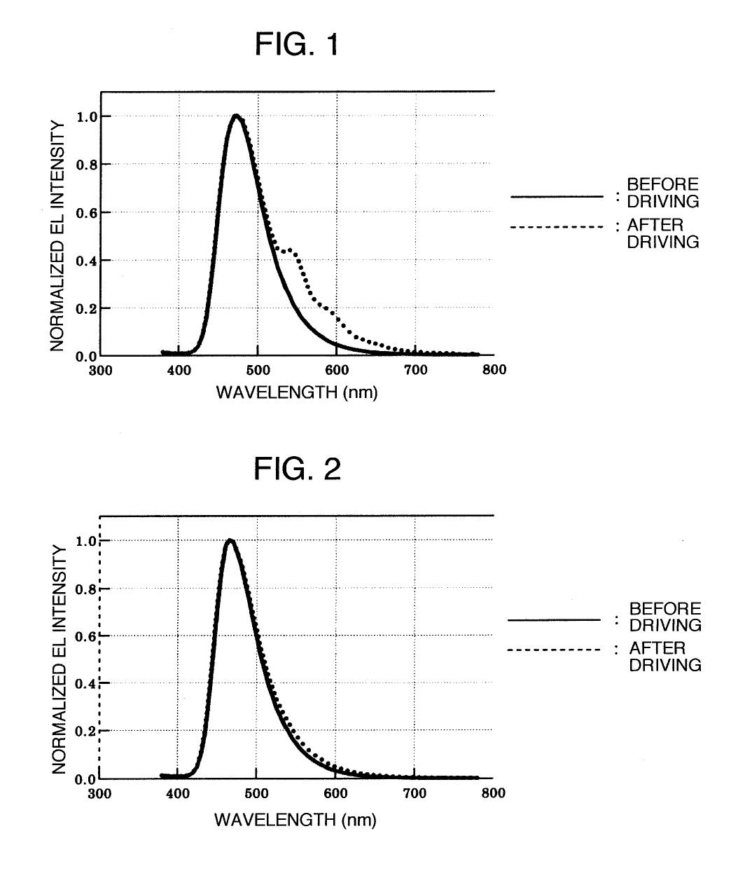

In another test different from the lifespan measurement as described above, the EL device as described above was driven at a constant current of 150 mA/cm² for 78 hours. The luminance at the end of the drive was 10.0% of the initial luminance. For the device thus obtained after the drive, an EL spectra was measured by applying a voltage of 8.0 V, and the peak wavelength was 465 nm and the C. I. E. color coordinate of the EL emission was x=0.195, y=0.270. By comparing this EL spectra with a EL spectra before the driving, an emission having shoulder peaks at 550 nm and 590 nm were newly observed as shown in FIG. 1.

### Example 2

### Synthesis of Polymer Compound 5

A polymer (hereinafter, designated as polymer compound 5) consisting of only the (repeating unit A) described above was obtained from compound B by a similar method to the synthetic method for polymer compound 2 except 4-t-butyliodobenzene was not used. The polystyrene-reduced number average molecular weight and weight average molecular weight by the SEC condition 1 were Mn=15000 and Mw=31000, respectively. The Formula weight of the repeating unit of the polymer, FW₁ was 438.7 and the average chain number was 34.

### Production of Light-Emitting Device Made of Polymer Compound 5

### (Preparation of Solution)

Polymer compound 5 and polymer compound 4 were dissolved in toluene at a ratio of 50 wt % and 50 wt %, respectively, to prepare a toluene solution of 2.0 wt % of polymer concentration.

### (Production of EL Device)

On a glass substrate plate on which a 150 nm thick ITO film had been formed by the sputtering method, a 70 nm thick film was formed by spin-coating using a solution which was prepared by filtering a suspension of poly(3,4-ethylenedioxythiophene)/polystyrenesulfonic acid (BaytronP AI4083, Bayer) through a 0.2 μm membrane filter, and dried at 200° C. on a hot plate for 10 minutes. Subsequently, using the toluene solution obtained as described above, a film was formed by the spin-coating method at 1500 rpm. The thickness of thus formed film was about 74 nm. This was further dried under reduced pressure at 80° C. for 1 hour. Then, vacuum depositions were carried out for lithium fluoride to about 4 nm thick, calcium as a cathode to about 5 nm thick and then aluminum to about 80 nm thick to produce an EL device. Vacuum-deposition was started after a vacuum of 1×10⁻⁴ Pa or below was attained.

### (Performance of EL Device)

An EL emission having a peak at 465 nm was obtained from this device by applying a voltage to the device thus obtained. The C. I. E. color coordinate of the EL emission at an applied voltage of 8.0 V was x=0.154, y=0.209. Intensity of the EL emission was almost proportional to an electric current density. Also, this device starts emitting light from 3.0 V and the maximum emission efficiency was 1.51 cd/A.

### (Lifespan Measurement)

The EL device obtained as described above was driven by a constant current of 150 mA/cm², and time dependent change in luminance was measured. The initial luminance of this device was 2090 cd/m² and the halflife was 37.4 hours. By assuming an acceleration coefficient in luminance-lifespan relation is a square and converting to the initial luminance of 400 cd/m², the halflife was 1021 hours. Further, the voltage required for driving the device was 7.81 V at the early phase and 8.16 V after the luminance dropped in half, and the voltage change during driving the device was 0.35 V. Still further, the rate of voltage increase calculated from this converted halflife was 0.34 mV/hour.

(Spectra after Driving)

In another test different from the lifespan measurement as described above, the EL device as described above was driven at a constant current of 150 mA/cm² for 81 hours. The luminance at the end of the drive was 34.4% of the initial luminance. For the device thus obtained after the drive an EL spectra was measured by applying a voltage of 8.0 V, and the peak wavelength was 465 nm and the C. I. E. color coordinate of the EL emission was x=0.160, y=0.215. By comparing this EL spectra with a EL spectra before the driving, almost no change was observed before and after the driving in the spectra as shown in FIG. 2.

As shown above, it is seen that the polymer light-emitting device using polymer compound 5 has a longer luminance halflife and less change in spectra due to driving compared to the device using polymer compound 3 of Comparative Example 2, and thus color change before and after the drive is suppressed, and the rate of voltage increase during driving is small. Therefore, the polymer compound of the invention of the present application has superior properties as a material to be used in a polymer light-emitting device.

### Comparative Example 3

### Synthesis of Polymer Compound 6

A polymer (hereinafter, designated as polymer compound 6) consisting of only the (repeating unit A) described above was obtained from compound A by a similar method to the synthetic method for polymer compound 1. The polystyrene-reduced number average molecular weight and weight average molecular weight by the SEC condition 1 were Mn=55000 and Mw=119000, respectively. The Formula weight of the repeating unit of the polymer, FW₁ was 438.7 and the average chain number was 125.

### Synthesis of Polymer Compound 7

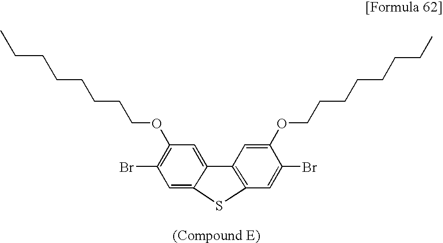

195.37 g of compound E, 239.44 g of compound D and 32.89 g of 2,2′-bipyridyl were dissolved in 46.26 kg of anhydrous tetrahydrofuran and then heated to 60° C. under a nitrogen atmosphere. To this solution 410.15 g of Bis(1,5-cyclooctadiene)Ni(0) {Ni(COD)₂} was added and reacted for 5 hours. After the reaction, the mixture was cooled to room temperature, instilled into a mixed solution of 8.52 kg of 25% aqueous ammonia/16.88 kg of methanol/31.98 kg of ion exchanged water and stirred for 2 hours. Then, deposited precipitates were collected by filtration, dried under reduced pressure. After drying, the precipitates were dissolved in 16.22 kg of toluene and then, 830 g of radiolight was added to the solution, and insoluble materials were filtered off. A filtrate thus obtained was passed through an alumina column for purification. The purified solution thus obtained was mixed with a mixture of 13.52 kg of ion exchanged water/2.04 kg of 25% aqueous ammonia, stirred for 0.5 hour, and then the aqueous layer was removed. Further, 13.52 kg of ion exchanged water was added to the organic layer, stirred for 0.5 hour and then the aqueous layer was removed. After subjecting a part of the organic layer thus obtained to concentration under reduced pressure, the organic layer was added to 34.18 kg of methanol, stirred for 1 hour and deposited precipitates were collected by filtration and dried under reduced pressure. The yield of the polymer thus obtained was 234.54 g. The polystyrene-reduced number average molecular weight and weight average molecular weight were Mn=12000 and Mw=77000, respectively.

0.5% toluene solution of this polymer was prepared and filtered through a 0.45μ filter. The solution obtained after the filtration was fractionated by a repeating SEC under the following conditions.

Column: TSK gel GMH_{HR}-H(GPC column, 21.5 mm I.D.×30 cm, made by TOSOH)

Column temperature: 60° C.

Mobile phase: toluene

Flow rate: 6 ml/min

Amount of sample injected: 2 ml

Fraction collecting time: 11.0-11.5 min

The solution of the fraction thus obtained was concentrated by an evaporator, and a polymer (hereinafter, designated as polymer compound 7) was obtained by re-precipitation from methanol. Its polystyrene-reduced Mn=6800 and Mw=8900.

### Production of Light-Emitting Device Made of Polymer Compound 6

### (Preparation of Solution)

Polymer compound 6 and polymer compound 7, obtained as above, were dissolved in toluene at a ratio of 80 wt % and 20 wt %, respectively, to prepare a toluene solution of 2.0 wt % of polymer concentration.

### (Production of EL Device)

On a glass substrate plate on which a 150 nm thick ITO film had been formed by the sputtering method, a 70 nm thick film was formed by spin-coating using a solution which was prepared by filtering a suspension of poly(3,4-ethylenedioxythiophene)/polystyrenesulfonic acid (BaytronP AI4083, Bayer) through a 0.2 μm membrane filter, and dried at 200° C. on a hot plate for 10 minutes. Subsequently, using the toluene solution obtained as described above, a film was formed by the spin-coating method at 1500 rpm. The thickness of thus formed film was about 83 nm. This was further dried under reduced pressure at 80° C. for 1 hour. Then, vacuum depositions were carried out for lithium fluoride to about 4 nm thick, calcium as a cathode to about 5 nm thick and then aluminum to about 80 nm thick to produce an EL device. Vacuum-deposition was started after a vacuum of 1×10⁻⁴ Pa or below was attained.

### (Performance of EL Device)

An EL emission having a peak at 470 nm was obtained from this device by applying a voltage to the device thus obtained. The C. I. E. color coordinate of the EL emission at an applied voltage of 8.0 V was x=0.157, y=0.212. Intensity of the EL emission was almost proportional to an electric current density. Also, this device starts emitting light from 3.0 V and the maximum emission efficiency was 1.52 cd/A.

### (Lifespan Measurement)

The EL device obtained as described above was driven by a constant current of 150 mA/cm², and time dependent change in luminance was measured. The initial luminance of this device was 1863 cd/m² and the halflife was 6.32 hours. By assuming an acceleration coefficient in luminance-lifespan relation is a square and converting to the initial luminance of 400 cd/m², the halflife was 137 hours. Further, the voltage required for driving the device was 8.99 V at the early phase and 9.74 V after the luminance dropped in half, and the voltage change during driving the device was 0.75 V. Still further, the rate of voltage increase calculated from this converted halflife was 5.47 mV/hour.

Spectra after Driving

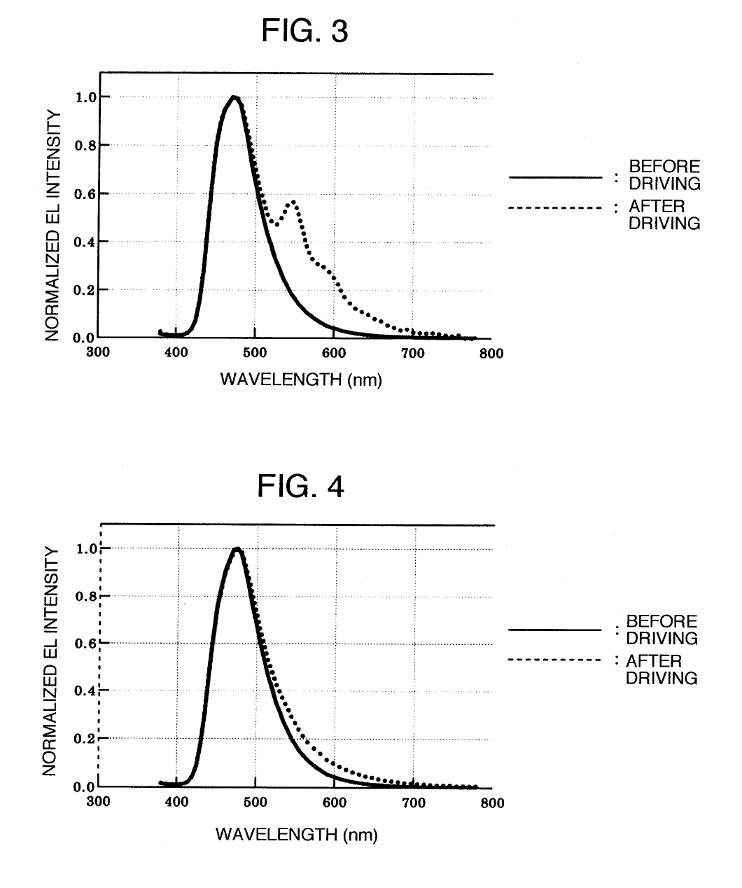

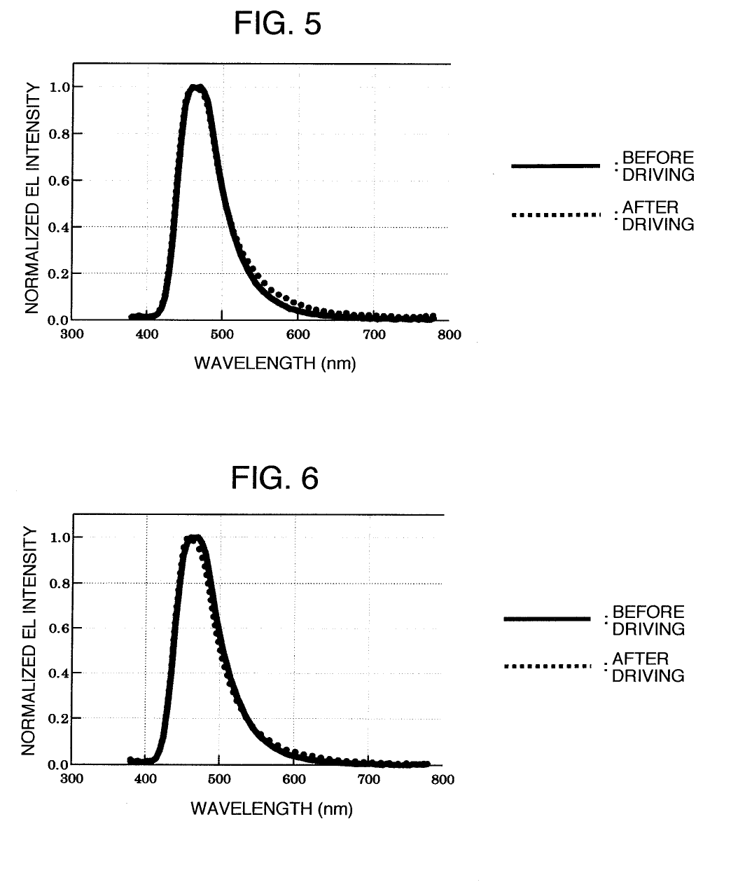

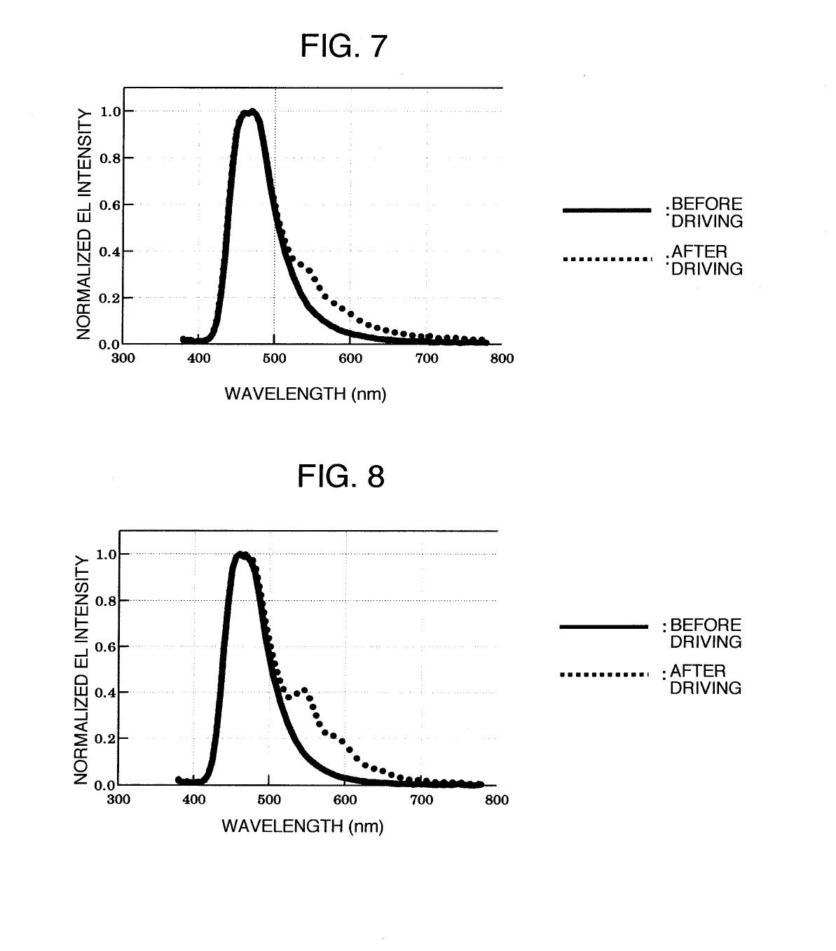

In another test different from the lifespan measurement as described above, the EL device as described above was driven at a constant current of 150 mA/cm² for 81 hours. The luminance at the end of the drive was 10.7% of the initial luminance. For the device thus obtained after the drive, an EL spectra was measured by applying a voltage of 8.0 V, and the peak wavelength was 470 nm and the C. I. E. color coordinate of the EL emission was x=0.230, y=0.310. By comparing this EL spectra with a EL spectra before the driving, an emission having shoulder peaks at 550 nm and 590 nm was newly observed as shown in FIG. 3.

### Example 3

### Production of Light-Emitting Device Made of Polymer Compound 5

### (Preparation of Solution)

Polymer compound 5 and polymer compound 7, obtained as above, were dissolved in toluene at a ratio of 80 wt % and 20 wt %, respectively, to prepare a toluene solution of 2.0 wt % of polymer concentration.

### (Production of EL Device)

On a glass substrate plate on which a 150 nm thick ITO film had been formed by the sputtering method, a 70 nm thick film was formed by spin-coating using a solution which was prepared by filtering a suspension of poly(3,4-ethylenedioxythiophene)/polystyrenesulfonic acid (BaytronP AI4083, Bayer) through a 0.2 μm membrane filter, and dried at 200° C. on a hot plate for 10 minutes. Subsequently, using the toluene solution obtained as described above, a film was formed by the spin-coating method at 600 rpm. The thickness of thus formed film was about 89 nm. This was further dried under reduced pressure at 80° C. for 1 hour. Then, vacuum depositions were carried out for lithium fluoride to about 4 nm thick, calcium as a cathode to about 5 nm thick and then aluminum to about 80 nm thick to produce an EL device. Vacuum-deposition was started after a vacuum of 1×10⁻⁴ Pa or below was attained.

### (Performance of EL Device)

An EL emission having a peak at 475 nm was obtained from this device by applying a voltage to the device thus obtained. The C. I. E. color coordinate of the EL emission at an applied voltage of 8.0 V was x=0.159, y=0.224. Intensity of the EL emission was almost proportional to an electric current density. Also, this device starts emitting light from 2.9 V and the maximum emission efficiency was 1.59 cd/A.

### (Lifespan Measurement)

The EL device obtained as described above was driven by a constant current of 150 mA/cm², and time dependent change in luminance was measured. The initial luminance of this device was 2130 cd/m² and the halflife was 22.9 hours. By assuming an acceleration coefficient in luminance-lifespan relation is a square and converting to the initial luminance of 400 cd/m², the halflife was 648 hours. Further, the voltage required for driving the device was 8.64 V at the early phase and 9.47 V after the luminance dropped in half, and the voltage change during driving the device was 1.03 V. Still further, the rate of voltage increase calculated from this converted halflife was 1.59 mV/hour.

(Spectra after Driving)

In another test different from the lifespan measurement as described above, the EL device as described above was driven at a constant current of 150 mA/cm² for 81 hours. The luminance at the end of the drive was 22.7% of the initial luminance. For the device thus obtained after the drive, an EL spectra was measured by applying a voltage of 8.0 V, and the peak wavelength was 475 nm and the C. I. E. color coordinate of the EL emission was x=0.184, y=0.254. By comparing this EL spectra with a EL spectra before the driving, as shown in FIG. 4 there was almost no change in the shape of the spectra although a slight increase of a long wavelength component was observed in a region over 500 nm.

As shown above, it is seen that the polymer light-emitting device using polymer compound 5 has a longer luminance halflife and less change in spectra due to driving compared to the device using polymer compound 6 of Example 3, and thus color change before and after the drive is suppressed, and the rate of voltage increase during driving is small. Therefore, the polymer compound of the invention of the present application has superior properties as a material to be used in a polymer light-emitting device.

### Comparative Example 4

### Thermogravimetry of Polymer Compound 3

Thermogravimetry of polymer compound 3 described above was performed, and it was found that the rate of weight decrease was 10.4% after raising the temperature from 20° C. to 400° C. at 10° C. per minute.

### Example 4

### Thermogravimetry of Polymer Compound 5

Thermogravimetry of polymer compound 5 described above was performed, and it was found that the rate of weight decrease was 4.2% after raising the temperature from 20° C. to 400° C. at 10° C. per minute. Polymer compound 5 of the invention of the present application has a superior heat resistant property compared to polymer compound 3 of Example 4.

### Comparative Example 5

### Synthesis of Polymer Compound 8

To a 4 necked flask, 1.04 g (6.7 mmol) of 2,2′-bipyridyl and 1.19 g (3.55 mmol) of 1,4-dibromo-2-hexyloxybenzene were added, and the air inside of the flask was replaced with argon gas, and 128 ml of anhydrous tetrahydrofuran was added. After raising the temperature to 40° C., 1.67 g (6.06 mmol) of bis(1,5-cyclooctadiene)Ni(0) {Ni(COD)₂} was added to this solution and stirred at 40° C. for 1 hours to carry out the reaction.

After the reaction, the reaction mixture was cooled to room temperature, instilled into a mixed solution of 12 ml of 25% aqueous ammonia/110 ml of methanol/110 ml of water and stirred for 1.5 hour. Then deposited precipitates were collected by filtration, dried under reduced pressure. Next, 95 ml of toluene and 6.30 g of radiolight were added and stirred for 40 minutes, and insoluble materials were filtered off. A filtrate thus obtained was passed through an alumina column for purification. After concentrating to about 60 ml, the purified filtrate was instilled to 300 ml of methanol. The deposited precipitates were collected by filtration and dried under reduced pressure. The polymer thus obtained (hereinafter, designated as polymer compound 8) was a polymer compound consisting of only (repeating unit B) and the yield was 0.39 g. The polystyrene-reduced number average molecular weight and weight average molecular weight by the SEC condition 1 were Mn=16000 and Mw=39000, respectively. The Formula weight of the repeating unit of the polymer, FW₁ was 176.27 and the average chain number was 91.

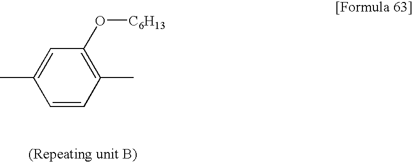

### Determination of Ratio of Head-Tail Link in Polymer Compound 8

¹H detection ¹H-¹³C 2 dimensional correlation spectra (HMQC spectra) measurement was performed for polymer compound 8, and it was found that a chemical shift of proton indicated as H_{E1} in the Formula (e) representing a triad was observed at 7.30 ppm and a chemical shift of ¹³C indicated as C_{E1} was observed at 122.3 ppm. In the Formula (f) representing a triad, a chemical shift of proton indicated as H_{E2} was observed at 7.37 ppm and a chemical shift of ¹³C indicated as C_{E2} was observed at 119.6 ppm. In the Formula (g) representing a triad, a chemical shift of proton indicated as H_{E3} was observed at 7.25 ppm and a chemical shift of ¹³C indicated as C_{E3} was observed at 121.3 ppm. In the Formula (h) representing a triad, a chemical shift of proton indicated as H_{E4} was observed at 7.31 ppm and a chemical shift of ¹³C indicated as C_{E4} was observed at 118.7 ppm.

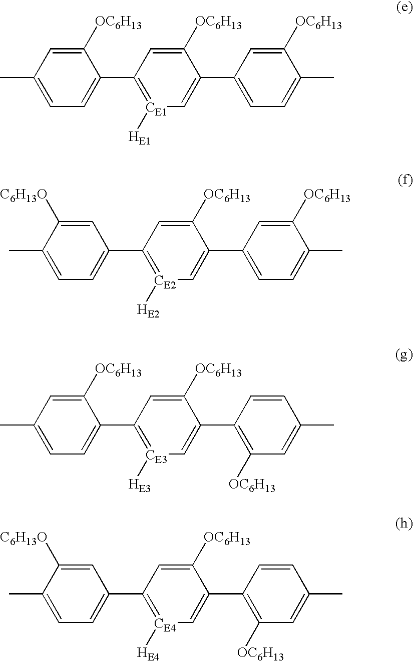

An integrated value of a proton-¹³C correlation peak intensity in an HMQC spectra is proportional to the number of H_{E1}, H_{E2}, H_{E3} and H_{E4} described above. The integrated values of the proton-¹³C correlation peak intensity are shown in Table 4.

TABLE 4

| | Correlation | |
|---|---|---|
| Triad | peak | Integrated intensity |
| (e) | H_{E1} and C_{E1} | 2293.6 . . . (I1) |
| (f) | H_{E2} and C_{E2} | 762.7 . . . (I2) |
| (g) | H_{E3} and C_{E3} | 568.7 . . . (I3) |
| (h) | H_{E4} and C_{E4} | 167.6 . . . (I4) |

A head-head link, head-tail link and tail-tail link in polymer compound 8 were represented by the Formula (1).

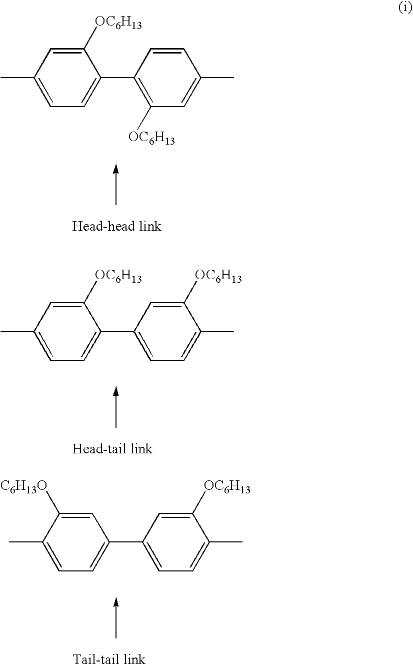

Here, by considering the numbers of the head-head link, head-tail link and tail-tail link, and the numbers of proton H_{E1}, H_{E2}, H_{E3} and H_{E4}, the relative number of the head-head link, head-tail link and tail-tail link is calculated using the integrated values (I1), (I2), (I3) and (I4) shown in Table 4 as follows.

Head-head link=(I3+I4)/2

Head-tail link=I1+I2

Tail-tail link=(I2+I4)/2

Using the above Formulas, the ratio of the head-head link, head-tail link and tail-tail link included in polymer compound 8 was calculated, and the results are shown in Table 5.

TABLE 5

| | | Relative | Ratio of |
|---|---|---|---|
| Link | Formula | number | link (%) |
| Head-head link | (I3 + I4)/2 | 368.1 | 9% |
| Head-tail link | I1 + I2 | 3056.3 | 79% |
| Tail-tail link | (I2 + I4)/2 | 465.1 | 12% |

The above results show that the number ratio of the head-head link, head-tail link and tail-tail link was 9:79:12. The results suggest that in polymer compound 8, the ratio of the number of the links formed between head and tail to the total number of links formed each other between the repeating units B was 79%.

### Example 5

### Synthesis of Compound F

Under an inert gas atmosphere, 2.0 g (6.0 mmol) of 1,4-dibromo-2-hexyloxybenzene was dissolved in 60 ml of dehydrated methyl-t-butyl ether in a 200 ml 4 necked flask and the solution was cooled to −70° C. Next, a hexane solution of 1.6 mol/L of n-butyllithium was instilled for 6 minutes at −70° C. and stirred for 2 hours at −70° C. Then, 1.5 ml of 2-isopropoxy-4,4,5,5-tetramethyl-1,3,2-dioxaborolane was instilled for 1 minute at −70° C., and then the temperature was raised to room temperature in 1 hour and 15 minutes while stirring, and stirring was continued for 10 hours. Next, 30 ml of water was added at 0° C., and after the temperature was raised to room temperature, stirring was continued for 30 minutes and ethyl acetate was added with stirring, and then the organic layer and the aqueous layer were separated. The organic layer was concentrated and stood at −5° C. overnight to obtain 2.3 g of solid. 1.1 g of the solid thus obtained was dissolved in 2 ml of methanol at 40° C. and cooled to room temperature to deposit crystals. The crystals thus obtained was filtered and dried to obtain compound F (0.5 g, LC area percentage 99.6%).

GC-MS: [M^{+]=382}.

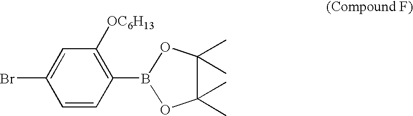

### Synthesis of Polymer Compound 9

Under an argon atmosphere, 300.2 mg (1.06 mmol) of compound F, 11.9 mg (0.053 mmol) of palladium acetate, and 22.9 mg (0.11 mmol) of tricyclohexylphosphine were added to a 100 ml 2-neck flask connected with a Dimroth condenser, and then the air in the vessel was replaced with argon gas. To the mixture, 42.6 ml of toluene was added and stirred and the temperature was raised to 110° C. Next, 5.7 ml of 20 wt % hydroxytetraethyl ammonium aqueous solution was added at 110° C., and the reaction was carried out at 110° C. for 18.5 hours while stirring. After cooling the reaction mixture to room temperature, 400 ml of ethanol was added, and a deposited solid was collected by filtration and dried. The solid thus obtained was dissolved in chloroform, passed through a column packed with silica gel and alumina, and the solution thus obtained was concentrated to dryness to obtain a solid. The solid was dissolved in 3 ml of chloroform and the solution was instilled to 50 ml of ethanol to deposit a solid, which was collected by filtration and dried to obtain 78.4 mg of a polymer (hereinafter, designated as polymer compound 9) composed of the aforementioned (repeating unit B) only. The polystyrene-reduced number average molecular weight and weight average molecular weight by the SEC condition 1 were Mn=3300 and Mw=5200, respectively. The Formula weight of the repeating unit of the polymer, FW₁ was 176.27 and the average chain number was 19.

### Determination of Ratio of Head-Tail Link in Polymer Compound 9

¹H detection ¹H-¹³C 2 dimensional correlation spectra (HMQC spectra) measurement was performed for polymer compound 9, in a similar manner to that for polymer compound 8, and the integrated intensity was obtained by integrating in the same range as in polymer compound 8. The results are shown in Table 6.

TABLE 6

| Triad | Correlation peak | Integrated intensity |
|---|---|---|
| (e) | H_{E1} and C_{E1} | 2374.5 . . . (I1′) |
| (f) | H_{E2} and C_{E2} | −19.5 . . . (I2′) |
| (g) | H_{E3} and C_{E3} | 98.7 . . . (I3′) |
| (h) | H_{E4} and C_{E4} | 14.5 . . . (I4′) |

Based on the results of the integration and by a similar manner to that for polymer compound 8, the ratio of the head-head link, head-tail link and tail-tail link included in polymer compound 9 was calculated, and the results are shown in Table 7.

TABLE 7

| | | Relative | Ratio of |
|---|---|---|---|
| Link | Formula | number | link (%) |
| Head-head link | (I3′ + I4′)/2 | 56.6 | 2% |
| Head-tail link | I1′ + I2′ | 2355.0 | 98% |
| Tail-tail link | (I2′ + I4′)/2 | −2.5 | 0% |

The above results show that the number ratio of the head-head link, head-tail link and tail-tail link included in polymer compound 9 was 2:98:0. The results suggest that in polymer compound 9, the ratio of the number of the links formed between head and tail to the total number of links formed each other between the repeating unit B was 98%.

### Example 6

### Synthesis of Polymer Compound 10

Under an argon atmosphere, 1400.0 mg (2.17 mmol) of aforementioned compound B, 72.1 mg (0.12 mmol) of aforementioned compound A, 83.4 mg (0.12 mmol) of following compound G were added to a 200 ml 3-neck flask connected with a Dimroth condenser, and then the air in the vessel was replaced with argon gas. To the mixture, 17 ml of toluene was added and stirred and the temperature was raised to 45° C. Next, 3.3 mg of [tris(dibenzylideneacetone)]dipalladium, 10.1 mg of tris(o-methoxyphenyl)phosphine and 4 ml of toluene were added, stirred for 10 minutes, 11 ml of 30 wt % of cesium carbonate was added, and the temperature was raised to 115° C. The reaction mixture was stirred for 40 minutes, cooled to room temperature, and then the aqueous layer was separated from the organic layer. The organic layer was instilled to 300 ml of methanol and a deposited solid was collected by filtration and dried. The solid thus obtained was dissolved in 72 ml of toluene, passed through a column packed with silica gel and alumina, and the solution thus obtained was instilled to 720 ml methanol and the deposited solid was filtered and dried to obtain 864.9 mg of a polymer (hereinafter, designated as polymer compound 10) composed of the aforementioned (repeating unit A) only. The polystyrene-reduced number average molecular weight and weight average molecular weight by the SEC condition 1 were Mn=180000 and Mw=439000, respectively. The Formula weight of the repeating unit of the polymer, FW₁ was 438.7 and the average chain number was 410.

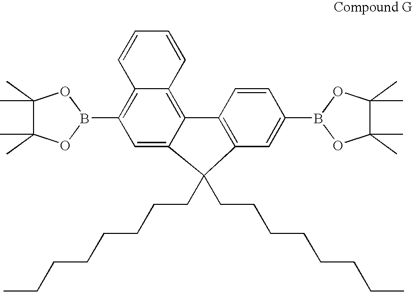

### Attribution of Diad Peaks of Polymer Compound 10

¹H detection ¹H-¹³C, 2 dimensional correlation spectra (HMQC spectra) measurement was performed for polymer compound 10, and chemical shifts of proton indicated by H_{B1} and H_{C1} in the Formula (a) representing a diad were 7.39 ppm, 7.81 ppm, respectively, and chemical shifts of carbon 13 indicated by C_{B1} and C_{C1} in the Formula (a) were 125.4 ppm and 123.8 ppm, respectively, and a proton-carbon 13 correlation peak was observed against pairs of proton and carbon indicated by H_{B1} and C_{B1}, and H_{C1} and C_{C1}. While chemical shifts of proton indicated by H_{B2} and H_{C2} in the Formula (b) representing a diad were 7.54 ppm and 7.79 ppm, respectively, and chemical shifts of carbon 13 indicated by C_{B2} and C_{C2} in the Formula (b) were 125.2 ppm and 122.5 ppm, respectively, and a proton-carbon 13 correlation peak was observed against pairs of proton and carbon indicated by H_{B2} and C_{B2}, and H_{C2} and C_{C2}.

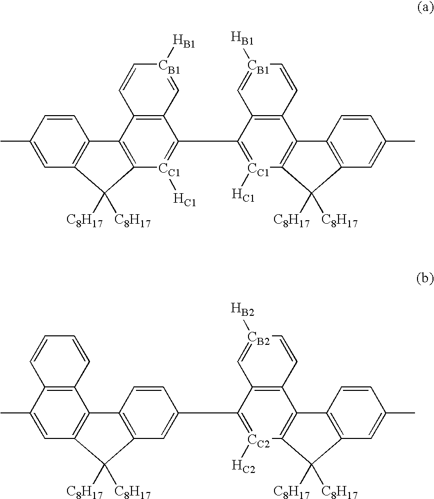

Quantity ratios of H_{B1} and H_{B2}, and H_{C1} and H_{C2} were obtained by integrating the intensity of a proton-carbon 13 correlation peak in an HMQC spectra, and the ratio of diad (a) and diad (b) was calculated by taking the numbers of H_{B1}, H_{B2}, H_{C1} and H_{C2} in one diad into an account. The results are shown in Table 8.

TABLE 8

| Correlation | | | | | Ratio |
|---|---|---|---|---|---|
| peak | Intergrated | Quantity ratio of proton | | | of |
| location | intensity | Formula | Value | Average | diad |
| H_{B1} and C_{B1} | 276.0 . . . (B1) | B1/(B1 + B2) | 0.11 | 0.13 | 0.07 |
| H_{C1} and C_{C1} | 606.7 . . . (C1) | C1/(C1 + C2) | 0.14 | | |
| H_{B2} and C_{B2} | 2129.4 . . . (B2) | B2/(B1 + B2) | 0.89 | 0.87 | 0.93 |
| H_{C2} and C_{C2} | 3641.6 . . . (C2) | C2/(C1 + C2) | 0.86 | | |

In ¹H detection ¹H-¹³C, 2 dimensional correlation spectra (HMQC spectra) of polymer compound 10, chemical shifts of proton indicated by H_{D2} and H_{E2} in the Formula (c) representing a diad were 7.79 ppm, 7.76 ppm, respectively, and chemical shifts of carbon 13 indicated by C_{D2} and C_{E2} in the Formula (a) were 125.2 ppm and 129.7 ppm, respectively, and a proton-carbon 13 correlation peak was observed against pairs of proton and carbon indicated by H_{D2} and C_{D2} and H_{E2} and C_{E2}. While chemical shifts of proton indicated by H_{D3} and H_{E3} in the Formula (d) representing a diad were 8.00 ppm and 7.96 ppm, respectively, and chemical shifts of carbon 13 indicated by C_{D3} and C_{E3} in the Formula (d) were 121.2 ppm and 126.6 ppm, respectively, and a proton-carbon 13 correlation peak was observed against pairs of proton and carbon indicated by H_{D3} and C_{D3}, and H_{E3} and C_{E3}.

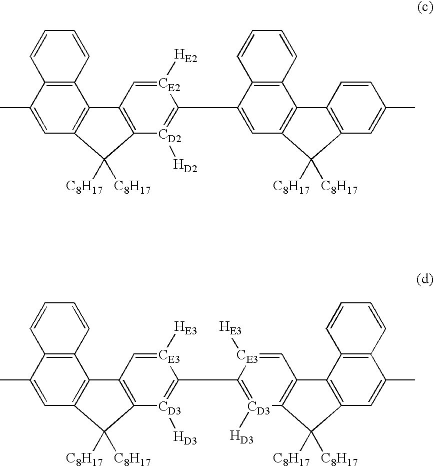

Quantity ratios of H_{D2} and H_{D3}, and H_{E2} and H_{E3} were obtained by integrating the intensity of a proton-carbon 13 correlation peak in an HMQC spectra, and the ratio of diad (d) and diad (e) was calculated by taking the numbers of H_{D2}, H_{D3}, H_{E2} and H_{E3} in one diad into an account. The results are shown in Table 9.

TABLE 9

| Correction | | | | | Ratio |
|---|---|---|---|---|---|
| peak | Integrated | Quantity ratio of proton | | | of |
| location | intensity | Formula | Value | Average | diad |
| H_{D2} and C_{D2} | 3030.5 . . . (D2) | D2/(D2 + D3) | 0.90 | 0.89 | 0.94 |
| H_{E2} and C_{E2} | 2281.6 . . . (E2) | E2/(E2 + E3) | 0.87 | | |
| H_{D3} and C_{D3} | 320.4 . . . (D3) | D3/(D2 + D3) | 0.10 | 0.11 | 0.06 |
| H_{E3} and C_{E3} | 329.2 . . . (E3) | E3/(E2 + E3) | 0.13 | | |

Since diad (b) and diad (c) are the same, it was shown that the ratio of 3 types of diads composing polymer compound 10, that is diad (a), diad (b) (or diad (c)) and diad (d) was 7:93:6. The results suggest that in polymer compound 10, the ratio of the number of the links formed between head and tail to the total number of links formed each other between the repeating units A was 88%.

### Example 7

### Synthesis of Polymer Compound 11

627 mg of a polymer (hereinafter, designated as polymer compound 11) consisting of only the aforementioned repeating unit A was obtained by a similar procedure to <synthesis of polymer compound 10> in Example 6 by using 1076 mg (1.67 mmol) of compound B only, instead of using 1400.0 mg (2.17 mmol) of compound B, 72.1 mg (0.12 mmol) of compound A and 83.4 mg (0.12 mmol) of compound G. The polystyrene-reduced number average molecular weight and weight average molecular weight by the SEC condition 1 were Mn=109000 and Mw=384000, respectively. The Formula weight of the repeating unit of the polymer, FW₁ was 438.7 and the average chain number was 248.

### Attribution of Diad Peaks in Polymer Compound 11

¹H detection ¹H-¹³C, 2 dimensional correlation spectra (HMQC spectra) measurement was performed for polymer compound 11 in the similar manner as for polymer compound 10, and the integrated intensity was obtained by integrating the same range as that of polymer compound 10. Further the ratios of diad (a) to diad (b), and diad (c) and diad (d) were obtained by a similar calculation to that for polymer compound 10. The results are shown in Table 10.

TABLE 10

| Correlation | | | | | Ratio |
|---|---|---|---|---|---|
| peak | Integrated | Quantity ratio of proton | | | of |
| location | intensity | Formula | Value | Average | diad |
| H_{B1} and C_{B1} | 120.2 . . . (B1) | B1/(B1 + B2) | 0.04 | 0.04 | 0.02 |
| H_{C1} and C_{C1} | 171.9 . . . (C1) | C1/(C1 + C2) | 0.03 | | |
| H_{D2} and C_{D2} | 4336.8 . . . (D2) | D2/(D1 + D2) | 0.99 | 0.99 | 0.99 |
| H_{E2} and C_{E2} | 3153.5 . . . (E2) | E2/(E1 + E2) | 0.98 | | |
| H_{B2} and C_{B2} | 2955.9 . . . (B2) | B2/(B1 + B2) | 0.96 | 0.96 | 0.98 |
| H_{C2} and C_{C2} | 4939.2 . . . (C2) | C2/(C1 + C2) | 0.97 | | |
| H_{D3} and C_{D3} | 22.8 . . . (D3) | D3/(D2 + D3) | 0.01 | 0.01 | 0.01 |
| H_{E3} and C_{E3} | 48.5 . . . (E3) | B3/(B2 + B3) | 0.02 | | |

Based on the above results, the ratio of diad (a), diad (b) (or diad (c)) and diad (d) was obtained by a similar calculation to that for polymer compound 10, and found to be 2:98:1. From the above facts, it was found that the ratio of the number of links formed between the head and tail to the total number of links formed between each other (repeating unit A) is 98%.

### Comparative Example 6

### Synthesis of Polymer Compound 12

1030 mg of a polymer (hereinafter, designated as polymer compound 12) consisting of only the aforementioned repeating unit A was obtained by a similar procedure to <synthesis of polymer compound 10> in Example 6 by using 1400.0 mg (2.17 mmol) of compound B, 192.3 mg (0.32 mmol) of compound A and 222.5 mg (0.32 mmol) of compound G instead of using 1400.0 mg (2.17 mmol) of compound B, 72.1 mg (0.12 mmol) of compound A and 83.4 mg (0.12 mmol) of compound G. The polystyrene-reduced number average molecular weight and weight average molecular weight by the SEC condition 1 were Mn=151000 and Mw=388000, respectively. The Formula weight of the repeating unit of the polymer, FW₁ was 438.7 and the average chain number was 344.

### Attribution of Diad Peaks in Polymer Compound 12

¹H detection ¹H-¹³C, 2 dimensional correlation spectra (HMQC spectra) measurement was performed for polymer compound 12, and chemical shifts of proton indicated by H_{B1} and H_{C1} in the Formula (a) representing a diad were 7.39 ppm, 7.81 ppm, respectively, and chemical shifts of carbon 13 indicated by C_{B1} and C_{C1} in the Formula (a) were 125.4 ppm and 123.8 ppm, respectively, and a proton-carbon 13 correlation peak was observed against pairs of proton and carbon indicated by H_{B1} and C_{B1}, and H_{C1} and C_{C1}. While chemical shifts of proton indicated by H_{B2} and H_{C2} in the Formula (b) representing a diad were 7.54 ppm and 7.79 ppm, respectively, and chemical shifts of carbon 13 indicated by C_{B2} and C_{C2} in the Formula (b) were 125.2 ppm and 122.5 ppm, respectively, and a proton-carbon 13 correlation peak was observed against pairs of proton and carbon indicated by H₈₂ and C_{B2}, and H_{C2} and C_{C2}.

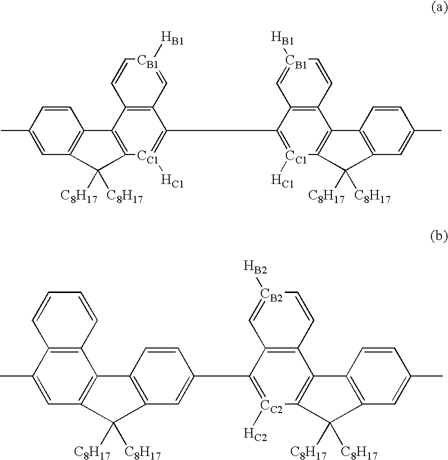

Quantity ratios of H_{B1} and H_{B2}, and H_{C1} and H_{C2} were obtained by integrating the intensity of a proton-carbon 13 correlation peak in an HMQC spectra, and the ratio of diad (a) and diad (b) was calculated by taking the numbers of H_{B1}, H_{B2}, H_{C1} and H_{C2} in one diad into an account. The results are shown in Table 11.

TABLE 11

| Correlation | | | | | Ratio |
|---|---|---|---|---|---|
| peak | Integrated | Quantity ratio of proton | | | of |
| location | intensity | Formula | Value | Average | diad |
| H_{B1} and C_{B1} | 779.8 . . . (B1) | B1/(B1 + B2) | 0.22 | 0.22 | 0.12 |
| H_{C1} and C_{C1} | 1227.1 . . . (C1) | C1/(C1 + C2) | 0.22 | | |
| H_{B2} and C_{B2} | 2763.5 . . . (B2) | B2/(B1 + B2) | 0.78 | 0.78 | 0.88 |
| H_{C2} and C_{C2} | 4284.6 . . . (C2) | C2/(C1 + C2) | 0.78 | | |

In ¹H detection ¹H-¹³C, 2 dimensional correlation spectra (HMQC spectra) of polymer compound 12, chemical shifts of proton indicated by H_{D2} and H_{E2} in the Formula (c) representing a diad were 7.79 ppm, 7.76 ppm, respectively, and chemical shifts of carbon 13 indicated by C_{D2} and C_{E2} in the Formula (c) were 125.2 ppm and 129.7 ppm, respectively, and a proton-carbon 13 correlation peak was observed against pairs of proton and carbon indicated by H_{D2} and C_{D2}, and H_{E2} and C_{E2}. While chemical shifts of proton indicated by H_{D3} and H_{E3} in the Formula (d) representing a diad were 8.00 ppm and 7.96 ppm, respectively, and chemical shifts of carbon 13 indicated by C_{D3} and C_{E3} in the Formula (d) were 121.2 ppm and 126.6 ppm, respectively, and a proton-carbon 13 correlation peak was observed against pairs of proton and carbon indicated by H_{D3} and C_{D3} and H_{E3} and C_{E3}.

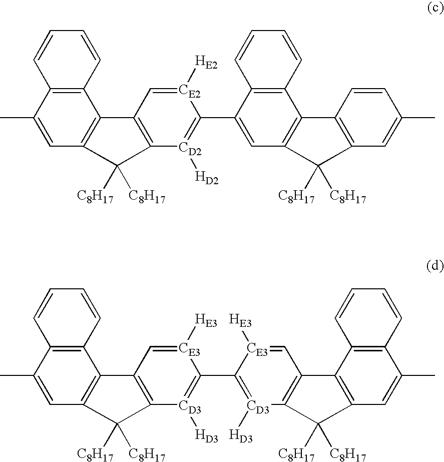

Quantity ratios of H_{D2} and H_{D3}, and H_{E2} and H_{E3} were obtained by integrating the intensity of a proton-carbon 13 correlation peak in an HMQC spectra, and the ratio of diad (c) and diad (d) was calculated by taking the numbers of H_{D2}, H_{D3}, H_{E2} and H_{E3} in one diad into an account. The results are shown in Table 12.

TABLE 12

| Correlation | | | | | Ratio |
|---|---|---|---|---|---|
| peak | Integrated | Quantity ratio of proton | | | of |
| location | intensity | Formula | Value | Average | diad |
| H_{D2} and C_{D2} | 3457.7 . . . (D2) | D2/(D2 + D3) | 0.78 | 0.77 | 0.87 |
| H_{E2} and C_{E2} | 2675.0 . . . (E2) | E2/(E2 + E3) | 0.76 | | |
| H_{D3} and C_{D3} | 958.01 . . . (D3) | D3/(D2 + D3) | 0.22 | 0.23 | 0.13 |
| H_{E3} and C_{E3} | 854.92 . . . (E3) | E3/(E2 + E3) | 0.24 | | |

Since diad (b) and diad (c) are the same, it was found that the ratio of the 3 types of diads composing polymer compound 12, that are diad (a), diad (b) (or diad (c)) and diad (d), was 12:88:13=11:78:11. From the above results, it was found that the ratio of the number of links formed between the head and tail to the total number of links formed between each other (repeating unit A) is 78%.

### Comparative Example 7

### Synthesis of Polymer Compound 13

A polymer (hereinafter, designated as polymer compound 13) consisting of only the aforementioned repeating unit A was obtained by a similar procedure to <synthesis of polymer compound 10> in Example 6 by using compound A and compound G at a molar ratio of 50:50 instead of using 1400.0 mg (2.17 mmol) of compound B, 72.1 mg (0.12 mmol) of compound A and 83.4 mg (0.12 mmol) of compound G. The polystyrene-reduced number average molecular weight and weight average molecular weight by the SEC condition 1 were Mn=155000 and Mw=372000, respectively. The Formula weight of the repeating unit of the polymer, FW₁ was 438.7 and the average chain number was 353.

### Attribution of Diad Peaks of Polymer Compound 13

¹H detection ¹H-¹³C, 2 dimensional correlation spectra (HMQC spectra) measurement was performed for polymer compound 13 in a similar manner as for polymer compound 10, and the integrated intensity was obtained by integrating the same range as that of polymer compound 10. Further the ratios of diad (a) to diad (b), and diad (c) and diad (d) were obtained by a similar calculation to that for polymer compound 13. The results are shown in Table 13.

TABLE 13

| Correlation | | | | | Ratio |
|---|---|---|---|---|---|
| peak | Integrated | Quantity ratio of proton | | | of |
| location | intensity | Formula | Value | Average | diad |
| H_{B1} and C_{B1} | 1396.1 . . . (B1) | B1/(B1 + B2) | 0.45 | 0.46 | 0.30 |
| H_{C1} and C_{C1} | 2414.5 . . . (C1) | C1/(C1 + C2) | 0.47 | | |
| H_{D2} and C_{D2} | 2086.2 . . . (D2) | D2/(D1 + D2) | 0.56 | 0.54 | 0.70 |
| H_{E2} and C_{E2} | 1658.7 . . . (E2) | E2/(E1 + E2) | 0.52 | | |
| H_{B2} and C_{B2} | 1713.7 . . . (B2) | B2/(B1 + B2) | 0.55 | 0.54 | 0.70 |
| H_{C2} and C_{C2} | 2703.5 . . . (C2) | C2/(C1 + C2) | 0.53 | | |
| H_{D3} and C_{D3} | 1665.2 . . . (D2) | D3/(D2 + D3) | 0.44 | 0.46 | 0.30 |
| H_{E3} and C_{E3} | 1524.7 . . . (E3) | E3/(E2 + E3) | 0.48 | | |

Based on the above results, the ratio of diad (a), diad (b) (or diad (c)) and diad (d) was obtained by a similar calculation to that for polymer compound 10, and found to be 23:54:23. From the above facts, it was found that the ratio of the number of links formed between the head and tail to the total number of links formed between each other (repeating unit A) is 54%.

### Example 8

### Production of Light-Emitting Device Made of Polymer Compound 10

### (Preparation of Solution)

Polymer compound 10 obtained in Example 6 was dissolved in xylene at a ratio of 1.3 wt %.

### (Production of EL Device)

On a glass substrate plate on which a 150 nm thick ITO film had been formed by the sputtering method, a 70 nm thick film was formed by spin-coating using a solution which was prepared by filtering a suspension of poly(3,4-ethylenedioxythiophene)/polystyrenesulfonic acid (BaytronP AI4083, Bayer) through a 0.2 μm membrane filter, and dried at 200° C. on a hot plate for 10 minutes. Subsequently, using the xylene solution of polymer compound 10 obtained as described above, a film was formed by the spin-coating method at 2700 rpm. The thickness of thus formed film was about 119 nm. This was further dried at 90° C. for 1 hour under a nitrogen atmosphere where an oxygen concentration and water concentration was 10 ppm or less. Then, vacuum depositions were carried out for lithium fluoride to about 4 nm thick, calcium as a cathode to about 5 nm thick and then aluminum to about 80 nm thick to produce an EL device. Vacuum-deposition was started after a vacuum of 1×10⁻⁴ Pa or below was attained.

### (Performance of EL Device)

An EL emission having a peak at 470 nm was obtained from this device by applying a voltage to the device thus obtained. The color of EL emission at 100 cd/m² hour demonstrated by the C. I. E. color coordinate was x=0.16, y=0.18. Intensity of the EL emission was almost proportional to an electric current density. Also, the voltage at the time of reaching 1 cd/m² was 4.6 V and the maximum emission efficiency was 0.15 cd/A.

(Change of Spectra Before and after Driving the Device)

The EL device obtained as described above was driven at a constant current of 50 MA/cm², and the EL spectra was measured 1.5 hours later, and small shoulder peaks were observed at 550 nm and 590 nm. Each luminance intensity was normalized by the peak intensity at 470 nm to obtain the increase rate of luminance intensity at 550 nm and 590 nm. It was found that the luminance intensity at 550 nm and 590 nm were slightly increased by 3.5% and 2.6%, respectively.

### Example 9

### Production of Light-Emitting Device Made of Polymer Compound 11

### (Preparation of Solution)

Polymer compound 11 obtained in Example 7 was dissolved in xylene at a ratio of 1.3 wt %.

### (Production of EL Device)

On a glass substrate plate on which a 150 nm thick ITO film had been formed by the sputtering method, a 70 nm thick film was formed by spin-coating using a solution which was prepared by filtering a suspension of poly(3,4-ethylenedioxythiophene)/polystyrenesulfonic acid (BaytronP AI4083, Bayer) through a 0.2 μm membrane filter, and dried at 200° C. on a hot plate for 10 minutes. Subsequently, using the xylene solution of polymer compound 11 obtained as described above, a film was formed by the spin-coating method at 2000 rpm. The thickness of thus formed film was about 116 nm. This was further dried at 90° C. for 1 hour under a nitrogen atmosphere where an oxygen concentration and water concentration was 10 ppm or less. Then, vacuum depositions were carried out for lithium fluoride to about 4 nm thick, calcium as a cathode to about 5 nm thick and then aluminum to about 80 nm thick to produce an EL device. Vacuum-deposition was started after a vacuum of 1×10⁻⁴ Pa or below was attained.

### (Performance of EL Device)

An EL emission having a peak at 470 nm was obtained from this device by applying a voltage to the device thus obtained. The color of EL emission at 100 cd/m² hour demonstrated by the C. I. E. color coordinate was x=0.16, y=0.18. Intensity of the EL emission was almost proportional to an electric current density. Also, the voltage at the time of reaching 1 cd/m² was 3.8 V and the maximum emission efficiency was 0.22 cd/A.

(Change of Spectra Before and after Driving the Device)

The EL device obtained as described above was driven at a constant current of 50 mA/cm², and the EL spectra was measured 1.5 hours later, and shoulder peaks observed at 550 nm and 590 nm in Example 8 were hardly seen. Luminance intensity was normalized by the peak intensity at 470 nm to obtain the increase rate of luminance intensity at 550 nm and 590 nm. It was found that the luminance intensity at 550 nm and 590 nm were increased by 0.1% and 1.2%, respectively.

### Comparative Example 8

### Production of Light-Emitting Device Made of Polymer Compound 12

### (Preparation of Solution)

Polymer compound 12 obtained in Comparative Example 6 was dissolved in xylene at a ratio of 1.3 wt %.

### (Production of EL Device)

On a glass substrate plate on which a 150 nm thick ITO film had been formed by the sputtering method, a 70 nm thick film was formed by spin-coating using a solution which was prepared by filtering a suspension of poly(3,4-ethylenedioxythiophene)/polystyrenesulfonic acid (BaytronP AI4083, Bayer) through a 0.2 μm membrane filter, and dried at 200° C. on a hot plate for 10 minutes. Subsequently, using the xylene solution of polymer compound 12 obtained as described above, a film was formed by the spin-coating method at 3200 rpm. The thickness of thus formed film was about 119 nm. This was further dried at 90° C. for 1 hour under a nitrogen atmosphere where an oxygen concentration and water concentration was 10 ppm or less. Then, vacuum depositions were carried out for lithium fluoride to about 4 nm thick, calcium as a cathode to about 5 nm thick and then aluminum to about 80 nm thick to produce an EL device. Vacuum-deposition was started after a vacuum of 1×10⁻⁴ Pa or below was attained.

### (Performance of EL Device)

An EL emission having a peak at 470 nm was obtained from this device by applying a voltage to the device thus obtained. The color of EL emission at 100 cd/m² hour demonstrated by the C. I. E. color coordinate was x=0.16, y=0.19. Intensity of the EL emission was almost proportional to an electric current density. Also, the voltage at the time of reaching 1 cd/m² was 5.4 V and the maximum emission efficiency was 0.15 cd/A.

(Change of Spectra Before and after Driving the Device)

The EL device obtained as described above was driven at a constant current of 50 mA/cm², and the EL spectra was measured 1.5 hours later, and large shoulder peaks were observed at 550 nm and 590 nm. Each luminance intensity was normalized by the peak intensity at 470 nm to obtain the increase rate of luminance intensity at 550 nm and 590 nm. It was found that the luminance intensity at 550 nm and 590 nm were slightly increased by 14% and 8.9%, respectively.

### Comparative Example 9

### Production of Light-Emitting Device Made of Polymer Compound 13

### (Preparation of Solution)

Polymer compound 13 obtained in Comparative Example 7 was dissolved in xylene at a ratio of 1.3 wt %.

### (Production of EL Device)

On a glass substrate plate on which a 150 nm thick ITO film had been formed by the sputtering method, a 70 nm thick film was formed by spin-coating using a solution which was prepared by filtering a suspension of poly(3,4-ethylenedioxythiophene)/polystyrenesulfonic acid (BaytronP AI4083, Bayer) through a 0.2 μm membrane filter, and dried at 200° C. on a hot plate for 10 minutes. Subsequently, using the xylene solution of polymer compound 13 obtained as described above, a film was formed by the spin-coating method at 3200 rpm. The thickness of thus formed film was about 117 nm. This was further dried at 90° C. for 1 hour under a nitrogen atmosphere where an oxygen concentration and water concentration was 10 ppm or less. Then, vacuum depositions were carried out for lithium fluoride to about 4 nm thick, calcium as a cathode to about 5 nm thick and then aluminum to about 80 nm thick to produce an EL device. Vacuum-deposition was started after a vacuum of 1×10⁻⁴ Pa or below was attained.

### (Performance of EL Device)

An EL emission having a peak at 460 nm was obtained from this device by applying a voltage to the device thus obtained. The color of EL emission at 100 cd/m² hour demonstrated by the C. I. E. color coordinate was x=0.15, y=0.17. Intensity of the EL emission was almost proportional to an electric current density. Also, the voltage at the time of reaching 1 cd/m² was 3.6 V and the maximum emission efficiency was 0.32 cd/A.

(Change of Spectra Before and after Driving the Device)

The EL device obtained as described above was driven at a constant current of 50 mA/cm², and the EL spectra was measured 1.5 hours later, and large shoulder peaks were observed at 550 nm and 590 nm. Each luminance intensity was normalized by the peak intensity at 460 nm to obtain the increase rate of luminance intensity at 550 nm and 590 nm. It was found that the luminance intensity at 550 nm and 590 nm were slightly increased by 22% and 13%, respectively.

The results of Examples 8-9 and Comparative Examples 8-9 are shown in Table 14. As seen in table 14, the polymer compounds of the invention of the present application have superior properties as materials to be used in a polymer light emission device because they demonstrated only a small EL spectra change and superior chemical stability.

TABLE 14

| | | Ratio (%) | | |
|---|---|---|---|---|
| | | of links | Increase | Increase |
| | | formed | rate (%) | rate (%) |
| | | between | of 550 nm | of 590 nm |
| | | head and | emission | emission |
| | Polymer compound | tail | intensity | intensity |
| Example 8 | Polymer compound 10 | 88 | 3.5 | 2.6 |
| Example 9 | Polymer compound 11 | 98 | 0.1 | 1.2 |
| Comparative | Polymer compound 12 | 75 | 14 | 8.9 |
| Example 8 | | | | |
| Comparative | Polymer compound 13 | 54 | 22 | 13 |
| Example 9 | | | | |

### Comparative Example 10

### Synthesis of Polymer Compound 14

A polymer (hereinafter, designated as polymer compound 14) consisting of the following (repeating unit A) and the following (repeating unit C) was obtained by a similar procedure to <synthesis of polymer compound 10> in Example 6 by using 2.464 g (4.12 mmol) of compound A, 3.117 g (4.50 mmol) of compound G and 0.322 g (0.45 mmol) of compound D instead of using 1400.0 mg (2.17 mmol) of compound B, 72.1 mg (0.12 mmol) of compound A and 83.4 mg (0.12 mmol) of compound G. The polystyrene-reduced number average molecular weight and weight average molecular weight by the SEC condition 1 were Mn=62000 and Mw=175000, respectively.

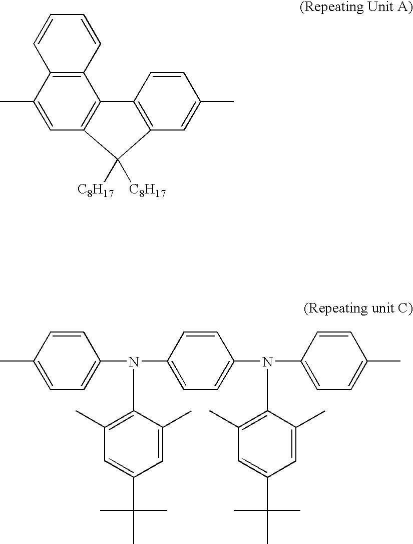

### Attribution of the Diad Peaks of Polymer Compound 14

In ¹H detection ¹H-¹³C, 2 dimensional correlation spectra (HMQC spectra) measurement of polymer compound 14, chemical shifts of proton indicated by H_{C1} in the Formula (a) representing a diad was 7.76 ppm and chemical shifts of carbon 13 indicated by C_{C1} in the Formula (a) representing a diad was 123.8 ppm and a proton-carbon 13 correlation peak was observed against a pair of proton and carbon indicated by H_{C1} and C_{C1}. While, chemical shifts of proton and carbon indicated by H_{C2} in the Formula (b) representing a diad was 7.73 ppm and chemical shifts of carbon 13 indicated by C_{C2} in the Formula (b) representing a diad was 122.4 ppm, and a proton-carbon 13 correlation peak was observed against a pair of proton and carbon indicated by H_{C2} and C_{C2}. Further, chemical shifts of proton indicated by H_{C4} in the Formula (e) representing a diad was 7.56 ppm and chemical shifts of carbon 13 indicated by C_{C4} in the Formula (e) representing a diad was 122.4 ppm, and a proton-carbon 13 correlation peak was observed against a pair of proton and carbon indicated by H_{C4} and C_{C4}.

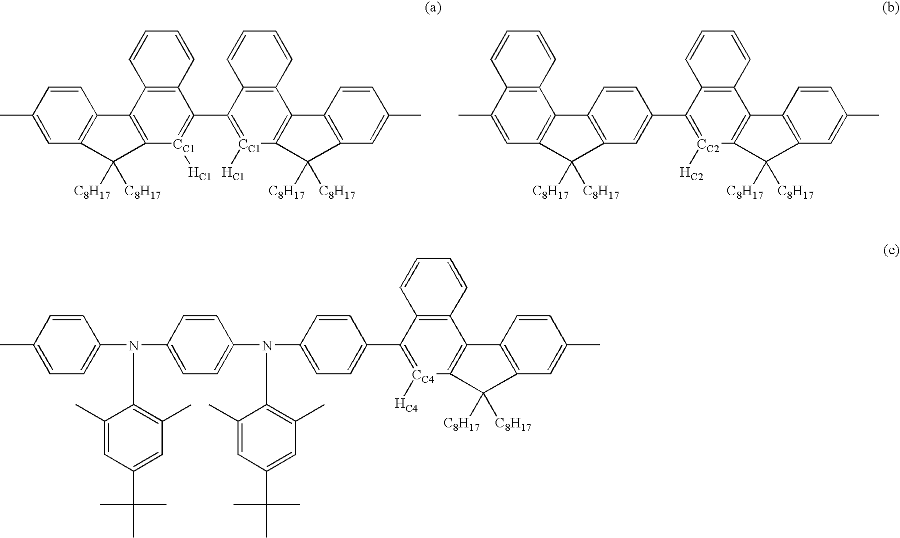

Quantity ratios of H_{C1}, H_{C2} and H_{C4} were obtained by integrating the intensity of a proton-carbon 13 correlation peak in an HMQC spectra, and the ratio of diad (a), diad (b) and diad (e) was calculated by taking the numbers of H_{C1}, H_{C2}, and H_{C4} in one diad into an account. The results are shown in Table 15.

TABLE 15

| Correlation | | | | Ratio |
|---|---|---|---|---|
| peak | Integrated | Quantity ratio of proton | | of |
| location | intensity | Formula | Value | diad |
| H_{C1} and C_{C1} | 3133.0 . . . (C1) | C1/ | 0.47 | 0.30 |
| | | (C1 + C2 + C4) . . . (c1) | | |
| H_{C2} and C_{C2} | 3200.3 . . . (C2) | C2/ | 0.48 | 0.62 |
| | | (C1 + C2 + C4) . . . (c2) | | |
| H_{C4} and C_{C4} | 389.8 . . . (C4) | C4/ | 0.06 | 0.08 |
| | | (C1 + C2 + C4) . . . (c4) | | |

In ¹H detection ¹H-¹³C, 2 dimensional correlation spectra (HMQC spectra) of polymer compound 14, chemical shifts of proton indicated by H_{D2}, and chemical shifts of carbon 13 indicated by C_{D2} in the Formula (c) representing a diad were 7.73 ppm and 125.2 ppm, respectively and a proton-carbon 13 correlation peak was observed against a pair of proton and carbon indicated by H_{D2} and C_{D2}. While, chemical shifts of proton indicated by H_{D3}, and chemical shifts of carbon 13 indicated by C_{D3} in the Formula (d) representing a diad were 7.96 ppm and 121.1 ppm, respectively and a proton-carbon 13 correlation peak was observed against a pair of proton and carbon indicated by H_{D3} and C_{D3}. Further, a chemical shift of proton indicated by H_{D5} and a chemical shift of carbon 13 indicated by C_{D5} in the Formula (f) representing a diad were 7.71 ppm and 120.3 ppm, respectively, and a proton-carbon 13 correlation peak was observed against a pair of proton and carbon indicated by H_{D5} and C_{D5}.

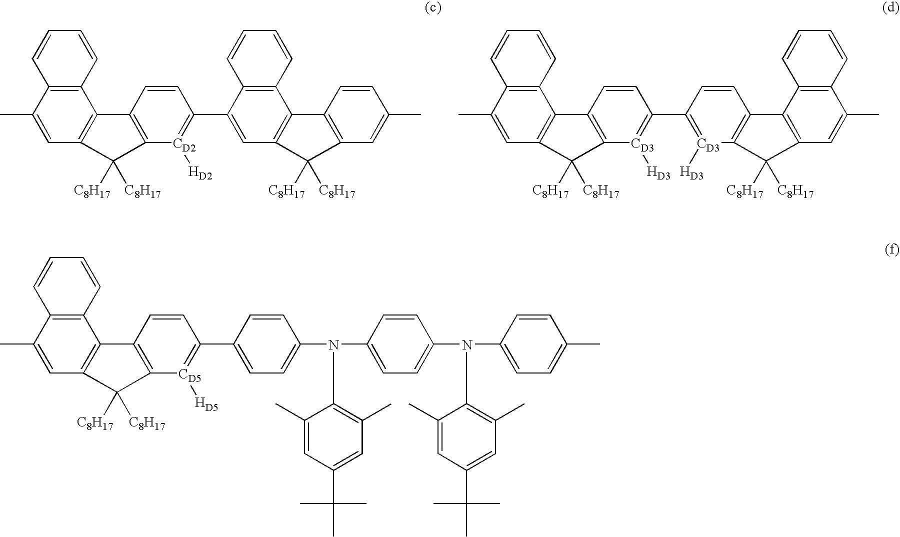

A quantity ratio of H_{D2} and H_{D3}, and H_{D5}, was obtained by integrating the intensity of a proton-carbon 13 correlation peak in an HMQC spectra, and the ratio of diad (c), diad (d) and diad (f) was calculated by taking the numbers of H_{D2}, H_{D3} and H_{D5} in one diad into an account. The results are shown in Table 16.

TABLE 16

| Correlation | | | | Ratio |
|---|---|---|---|---|
| peak | Integrated | Quantity ratio of proton | | of |
| location | intensity | Formula | Value | diad |
| H_{D2} and C_{D2} | 3446.8 . . . (D2) | D2/ | 0.53 | 0.66 |
| | | (D2 + D3 + D5) . . . (d2) | | |
| H_{D3} and C_{D3} | 2552.7 . . . (D3) | D3/ | 0.39 | 0.24 |
| | | (D2 + D3 + D5) . . . (d3) | | |
| H_{D5} and C_{D5} | 522.6 . . . (D5) | D5/ | 0.08 | 0.10 |
| | | (D2 + D3 + D5) . . . (d5) | | |

Since diad (b) and diad (c) are the same, it was found that the ratio of the 3 types of diads composing polymer compound 14, that are diad (a), diad (b) (or diad (c)) and diad (d), was 32:66:24. From the above facts, it was found that in polymer compound 14 the ratio of the number of links formed between the head and tail to the total number of links formed between each other (repeating unit A) is 54%.

### Calculation of Average Chain Number of (Repeating Unit A) in Polymer Compound 14

An average chain number (N_{A}) of (repeating unit A) in polymer compound 14 can be obtained from the following Formula (A2-1) by modifying the aforementioned Formula (A2).

Average Chain number(N_{A})=N1′/N2′ (A2-1)

wherein N1′ is a ratio of the number of (repeating unit A) to the total number of diads included in a unit quantity of polymer compound 14, and N2′ is a ratio of a number of blocks made of the (repeating unit A) to the total number of diads included in a unit quantity of polymer compound 14. Here, the blocks made of the (repeating unit A) is represented by the following Formula (BR-3).

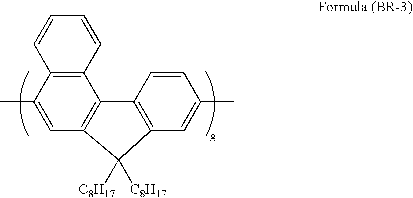

wherein g represents an integer of 1 or larger. This block is juxtaposed with repeating units other than the one represented by (repeating unit A) or a terminal group.

That is, in polymer compound 14, using the aforementioned number of diads,

N1′=([diad(a)]+[diad(b)]+[diad(e)]+[diad(c)]+[diad(d)]+[diad(f)])

N2′=([diad(e)]+[diad(f)])

Here, in the above 2 Formulas, [diad (a)], [diad (b)], [diad (e)], [diad (c)], [diad (d)] and [diad (f)] represent the ratio of number of each diad (a), diad (b), diad (e), diad (c), diad (d) and diad (f) to the total number of diads included in polymer compound 14. Also, using the marks described in Table 15 and Table 16, c1, c2, c4, d2, d3 and d5, can be substituted as follows:

$$\begin{matrix}c 1 = [ diad ( a ) ] / ( [ diad ( a ) ] + [ diad ( b ) ] + [ diad ( e ) ] ) \\ = C [ diad ( b ) ]\end{matrix}$$

$$\begin{matrix}c 2 = [ diad ( b ) ] / ( [ diad ( a ) ] + [ diad ( b ) ] + [ diad ( e ) ] ) \\ = C [ diad ( b ) ]\end{matrix}$$

$$\begin{matrix}c 4 = [ diad ( e ) ] / ( [ diad ( a ) ] + [ diad ( b ) ] + [ diad ( e ) ] ) \\ = C [ diad ( e ) ]\end{matrix}$$

(here, in the above 3 Formulas, C=1/([diad (a)]+[diad (b)]+[diad (e)])

$$\begin{matrix}d 2 = [ diad ( c ) ] / ( [ diad ( c ) ] + [ diad ( d ) ] + [ diad ( f ) ] ) \\ = D [ diad ( c ) ]\end{matrix}$$

$$\begin{matrix}d 3 = [ diad ( d ) ] / ( [ diad ( c ) ] + [ diad ( d ) ] + [ diad ( f ) ] ) \\ = D [ diad ( d ) ]\end{matrix}$$

$$\begin{matrix}d 5 = [ diad ( f ) ] / ( [ diad ( c ) ] + [ diad ( d ) ] + [ diad ( f ) ] ) \\ = D [ diad ( f ) ]\end{matrix}$$

(here, in the above 3 Formulas, D=1/([diad (c)]+[diad (d)]+[diad (f)])
By substituting the aforementioned Formula (A2-1), the Formula (A2-1) is expressed using c1, c2, c4, d2, d3, d5, and C and D as follows:

$$\begin{matrix}{N}_{A} = N {1}^{′} / N {2}^{′} \\ = ( c 1 / C + c 2 / C + c 4 / C + d 2 / D + d 3 / D + \\ d 5 / D ) / ( c 4 / C + d 5 / D ) \\ = \{ c 1 + c 2 + c 4 + ( d 2 + d 3 + d 5 ) \cdot C / D \} / \\ ( c 4 + d 5 \cdot C / D )\end{matrix} \qquad Formula ( A2 \text{-} 2 )$$

On the other hand, it is obvious from the diad (b) structure and diad (c) structure that

[diad(b)]=[diad(c)].

Using c2 and d2, and C and D, this Formula can be converted as follows:

c2/C=d2/D

This Formula is further converted to

C/D=c2/d2 (A2-3)

From the Formulas (A2-2) and (A2-3), the following Formula is obtained:

N_{A}={d2(d1+d2+d4)+c2(d2+d3+d5)}/(d2·c4+c2·d5) Formula (A2-4)

The average chain number of polymer compound 14 calculated using Formula (A2-4) and values from Table 15 and 16 was 15.

### Example 10

### Synthesis of Polymer Compound 15

A polymer (hereinafter, designated as polymer compound 15) consisting of the aforementioned (repeating unit A) and the aforementioned (repeating unit C) was obtained by a similar procedure to <synthesis of polymer compound 10> in Example 6 by using 1000 mg (1.55 mmol) of compound B, 30.1 mg (0.04 mmol) of compound D and 34.0 mg (0.04 mmol) of the following compound H, instead of using 1400.0 mg (2.17 mmol) of compound B, 72.1 mg (0.12 mmol) of compound A and 83.4 mg (0.12 mmol) of compound G. The polystyrene-reduced number average molecular weight and weight average molecular weight by the SEC condition 1 were Mn=81000 and Mw=187000, respectively.

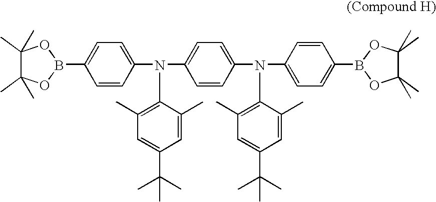

### Attribution of Diad Peaks in Polymer Compound 15

HMQC spectra measurement was performed for polymer compound 15 in the similar manner as for polymer compound 14, and the integrated intensity was obtained by integrating the same range as that of polymer compound 14. Further the ratios of diad (a), diad (b) and diad (e), and diad (c), diad (d) and diad (f) were obtained by a similar calculation to that for polymer compound 14. The results are shown in Table 17.

TABLE 17

| Correlation | | | | |
|---|---|---|---|---|
| peak | Integrated | Quantity ratio of proton | | Ratio |
| location | intensity | Formula | Value | of diad |
| H_{C1} and C_{C1} | 106.6 . . . (C1) | C1/(C1 + C2 + C4) | 0.02 | 0.01 |
| H_{C2} and C_{C2} | 5848.1 . . . (C2) | C2/(C1 + C2 + C4) | 0.92 | 0.93 |
| H_{C4} and C_{C4} | 384.8 . . . (C4) | C4/(C1 + C2 + C4) | 0.06 | 0.06 |
| H_{D2} and C_{D2} | 5887.4 . . . (D2) | D2/(D2 + D3 + D5) | 0.91 | 0.92 |
| H_{D3} and C_{D3} | 80.4 . . . (D3) | D3/(D2 + D3 + D5) | 0.01 | 0.01 |
| H_{D5} and C_{D5} | 483.6 . . . (D5) | D5/(D2 + D3 + D5) | 0.07 | 0.08 |

Based on the above results, the ratio of diad (a), diad (b) (or diad (c)) and diad (d) was obtained by a similar calculation to that for polymer compound 14, and found to be 1:98:1. From the above facts, in polymer compound 15 it was found that the ratio of the number of links formed between the head and tail to the total number of links formed between each other (repeating unit A) is 98%.

### Calculation of Average Chain Number of (Repeating Unit A) in Polymer Compound 15

An average chain number of (repeating unit A) in polymer compound 15 was 15 when calculated by using the Formula (A2-4) and the values in Table 17 in a similar manner as in the average chain number of (repeating unit A) in polymer compound 14.

### Example 11

### Synthesis of Polymer Compound 16

A polymer (hereinafter, designated as polymer compound 16) consisting of the aforementioned (repeating unit A) and the aforementioned (repeating unit C) was obtained by a similar procedure to <synthesis of polymer compound 10> in Example 6 by using 700.0 mg (1.08 mmol) of compound B, 171.7 mg (0.23 mmol) of compound D and 193.5 mg (0.23 mmol) of the following compound H, instead of using 1400.0 mg (2.17 mmol) of compound B, 72.1 mg (0.12 mmol) of compound A and 83.4 mg (0.12 mmol) of compound G. The polystyrene-reduced number average molecular weight and weight average molecular weight by the SEC condition 1 were Mn=45000 and Mw=990000, respectively.

### Attribution of Diad Peaks of Polymer Compound 16

HMQC spectra measurement was carried out for polymer compound 16, in a similar manner to that for polymer compound 14, and the integrated intensity was obtained by integrating in the same range as in polymer compound 14. Further the ratios of diad (a), diad (b) and diad (e), and diad (c), diad (d) and diad (f) were obtained by a similar calculation to that for polymer compound 14. The results are shown in Table 18.

TABLE 18

| Correlation | | | | |
|---|---|---|---|---|
| peak | Integrated | Quantity ratio of proton | | Ratio |
| location | intensity | Formula | Value | of diad |
| H_{C1} and C_{C1} | 0.0 . . . (C1) | C1/(C1 + C2 + C4) | 0.00 | 0.00 |
| H_{C2} and C_{C2} | 4243.1 . . . (C2) | C2/(C1 + C2 + C4) | 0.74 | 0.74 |
| H_{C4} and C_{C4} | 1481.9 . . . (C4) | C4/(C1 + C2 + C4) | 0.26 | 0.26 |
| H_{D2} and C_{D2} | 5407.3 . . . (D2) | D2/(D2 + D3 + D5) | 0.75 | 0.75 |
| H_{D3} and C_{D3} | 0.0 . . . (D3) | D3/(D2 + D3 + D5) | 0.00 | 0.00 |
| H_{D5} and C_{D5} | 1757.5 . . . (D5) | D5/(D2 + D3 + D5) | 0.25 | 0.25 |

Based on the above results, the ratio of diad (a), diad (b) (or diad (c)) and diad (d) was obtained by a similar calculation to that for polymer compound 14, and found to be 0:100:0. From the above facts, in polymer compound 16 it was found that the ratio of the number of links formed between the head and tail to the total number of links formed between each other (repeating unit A) is 100%.

### Calculation of Average Chain Number of (Repeating Unit A) in Polymer Compound 16

An average chain number of (repeating unit A) in polymer compound 16 was 4 when calculated by using the Formula (A2-4) and the values in Table 18 in a similar manner as in the average chain number of (repeating unit A) in polymer compound 14.

### Comparative Example 11

### Synthesis of Polymer Compound 17

A polymer (hereinafter, designated as polymer compound 17) consisting of the aforementioned (repeating unit A), the aforementioned (repeating unit C) and the following (repeating unit D) was obtained by a similar procedure to <synthesis of polymer compound 10> in Example 6 by using 500.0 mg (0.84 mmol) of compound A, 578.6 mg (0.84 mmol) of compound G, 16.2 mg (0.02 mmol) of compound D, 18.3 mg (0.02 mmol) of the following compound H, 10.4 mg (0.02 mmol) of the following compound 1 and 12.5 mg (0.02 mmol) of the following compound J, instead of using 1400.0 mg (2.17 mmol) of compound B, 72.1 mg (0.12 mmol) of compound A and 83.4 mg (0.12 mmol) of compound G. The polystyrene-reduced number average molecular weight and weight average molecular weight by the SEC condition 1 were Mn=77000 and Mw=420000, respectively.

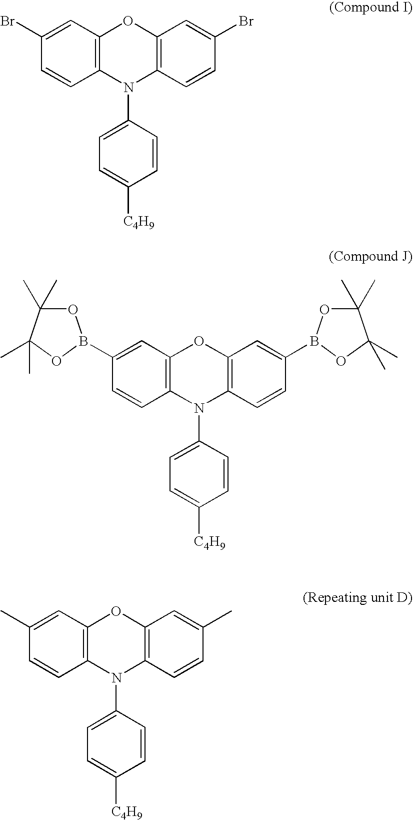

### Attribution of Diad Peaks in Polymer Compound 17

In HMQC spectra of polymer compound 17, chemical shifts of proton indicated by H_{C1} in the Formula (a) representing a diad was 7.81 ppm and chemical shifts of carbon 13 indicated by C_{C1} in the Formula (a) representing a diad were 123.9 ppm, and a proton-carbon 13 correlation peak was observed against a pair of proton and carbon indicated by H_{C1} and C_{C1}. While, chemical shifts of proton indicated by H_{C2} in the Formula (b) was 7.77 ppm and chemical shifts of carbon 13 indicated by C_{C2} in the Formula (b) representing a diad were 122.5 ppm and a proton-carbon 13 correlation peak was observed against a pair of proton and carbon indicated by H_{C2} and C_{C2}. Further chemical shifts of proton indicated by H_{C4} in the Formula (e) representing a diad and by H_{C6} in the Formula (g) representing a diad were both 7.60 ppm, and chemical shifts of carbon 13 indicated by C_{C4} in the Formula (e) and C_{C6} in the Formula (g) were both 122.3 ppm, and a proton-carbon 13 correlation peak was observed against pairs of proton and carbon indicated by H_{C4} and C_{C4}, and H_{C6} and C_{C6}.

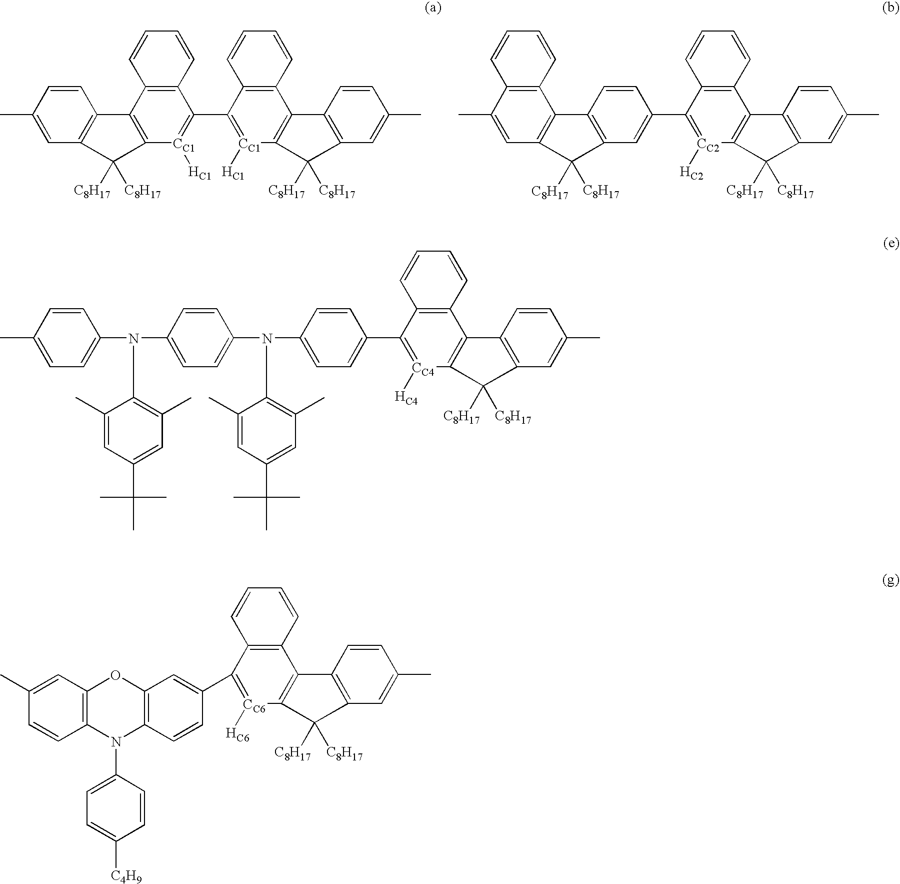

Quantity ratio of the sum of H_{C1}, H_{C2}, and H_{C4} and H_{C6} were obtained by integrating the intensity of a proton-carbon 13 correlation peak, and the ratio of diad (a), diad (b) and a sum of diad (e) and diad (g) (hereinafter represented by diad (e)+(g)) was calculated by taking the numbers of H_{C1}, H_{C2}, H_{C4} and H_{C6} in one diad into an account. The results are shown in Table 19.

TABLE 19

| Correlation | | | | |
|---|---|---|---|---|
| peak | Integrated | Quantity ratio of proton | | Ratio |
| location | intensity | Formula | Value | of diad |
| H_{C1} and C_{C1} | 2953.1 . . . (C1) | C1/ | 0.47 | 0.30 |
| | | (C1 + C2 + | | |
| | | C4_6) . . . (c1) | | |
| H_{C2} and C_{C2} | 3005.8 . . . (C2) | C2/ | 0.48 | 0.62 |
| | | (C1 + C2 + | | |
| | | C4_6) . . . (c2) | | |
| H_{C4} and C_{C4} | 366.9 . . . (C4_6) | C4_6/ | 0.06 | 0.08 |
| H_{C6} and C_{C6} | | (C1 + C2 + | | |
| | | C4_6) . . . (c4_6) | | |

In HMQC spectra of polymer compound 17, chemical shifts of proton indicated by H_{D2}, and chemical shifts of carbon 13 indicated by C_{D2} in the Formula (c) representing a diad were 7.79 ppm and 125.3 ppm, respectively and a proton-carbon 13 correlation peak was observed against a pair of proton and carbon indicated by H_{D2} and C_{D2}. While, chemical shifts of proton indicated by H_{D3}, and chemical shifts of carbon 13 indicated by C_{D3} in the Formula (d) representing a diad were 7.99 ppm and 121.2 ppm, respectively and a proton-carbon 13 correlation peak was observed against a pair of proton and carbon indicated by H_{D3} and C_{D3}. Further, chemical shifts of proton indicated by H_{D5} in the Formula (f) representing a diad and by H_{D7} in the Formula (h) representing a diad were both 7.78 ppm, and chemical shifts of carbon 13 indicated by C_{D5} in the Formula (f) and C_{D7} in the Formula (h) were both 120.4 ppm, and a proton-carbon 13 correlation peak was observed against pairs of proton and carbon indicated by H_{D5} and C_{D5}, and H_{D7} and C_{D7}.

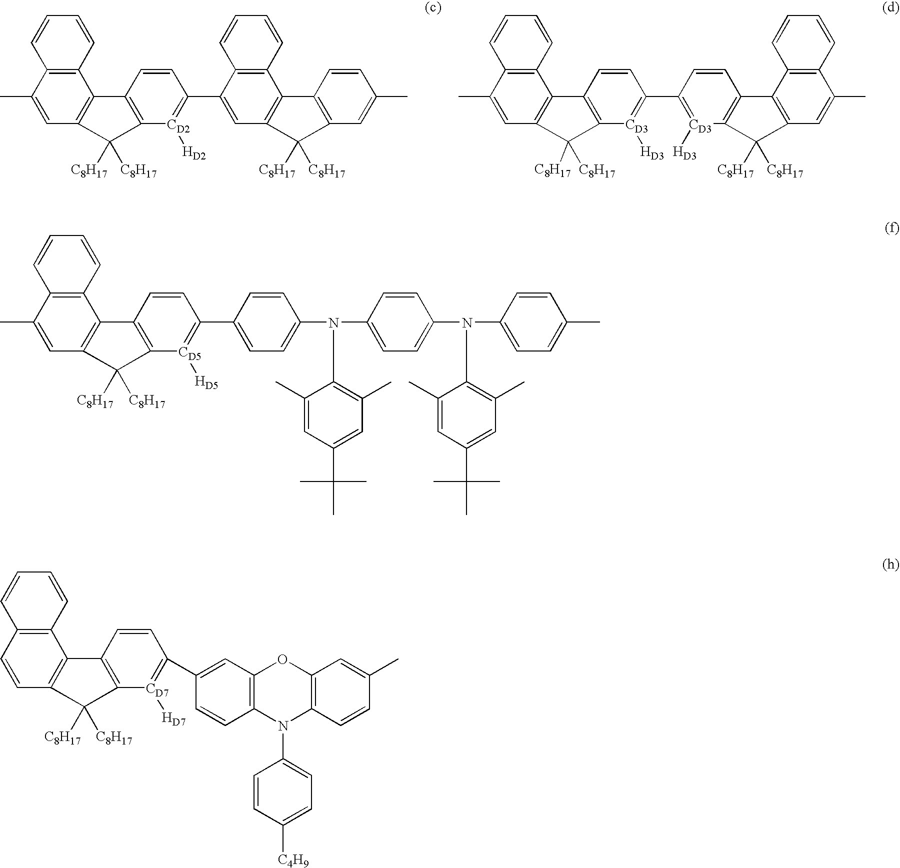

Quantity ratio of the sum of H_{D2}, H_{D3}, and H_{D5} and H_{D7} were obtained by integrating the intensity of a proton-carbon 13 correlation peak, and the ratio of diad (c), diad (d) and a sum of diad (f) and diad (h) (hereinafter represented by diad (f)+(h)) was calculated by taking the numbers of H_{D2}, H_{D3}, H_{D5} and H_{D7} in one diad into an account. The results are shown in Table 20.

TABLE 20

| Correlation | | | | |
|---|---|---|---|---|
| peak | Integrated | Quantity ratio of proton | | Ratio |
| location | intensity | Formula | Value | of diad |
| H_{D2} and C_{D2} | 3302.8 . . . (D2) | D2/ | 0.55 | 0.69 |
| | | (D2 + D3 + | | |
| | | D5_7) . . . (d2) | | |
| H_{D3} and C_{D3} | 2309.9 . . . (D3) | D3/ | 0.39 | 0.24 |
| | | (D2 + D3 + | | |
| | | D5_7) . . . (d3) | | |
| H_{D5} and C_{D5} | 340.0 . . . (D5_7) | C5_7/ | 0.06 | 0.07 |
| H_{D7} and C_{D7} | | (D2 + D3 + | | |
| | | D5_7)) . . . (d5_7) | | |

Since diad (b) and diad (c) are the same, it was shown that the ratio of 3 types of diads composing polymer compound 17, that is diad (a), diad (b) (or diad (c)) and diad (d) was 34:69:24. The results suggest that in polymer compound 17, the ratio of the number of the links formed between head and tail to the total number of links formed each other between the repeating unit A was 54%.

### Calculation of Average Chain Number of (Repeating Unit A) in Polymer Compound 17

The average chain number (N_{B}) of (repeating unit A) in polymer compound 17 can be obtained from the following Formula (A2-5) by modifying the aforementioned Formula (A2).

Average chain number(N_{B})=N1″/N2″ (A2-5)

wherein N1″ is a ratio of the number of (repeating unit A) to the total number of diads included in a unit quantity of polymer compound 17, and N2″ is a ratio of a number of blocks made of the (repeating unit A) to the total number of diads included in a unit quantity of polymer compound 17. Here, the blocks made of the (repeating unit A) is represented by the aforementioned Formula (BR-3).

That is, in polymer compound 17, using the aforementioned number of diads NB is represented by the following Formula:

$${N}_{B} = ( [ diad ( a ) ] + [ diad ( b ) ] + [ diad ( e ) + ( g ) ] + [ diad ( c ) ] + [ diad ( d ) ] + [ diad ( f ) + ( h ) ] ) / ( [ diad ( e ) + ( g ) ] + [ diad ( f ) + ( h ) ] ) \qquad ( A2 \text{-} 6 )$$

wherein in the above 2 Formulas [diad (a)], [diad (b)], [diad (e)+(g)], [diad (c)], [diad (d)] and [diad (f)+(h)] are ratios of numbers of each diad (a), diad (b), diad (e)+(g), diad (c), diad (d) and diad (f)+(h) to the total number of diads included in polymer compound 17. Also, using marks in Table 19 and 20, c1, c2, c4_{—}6, d2, d3, d5_{—}7, following conversions can be made:

$$\begin{matrix}c 1 = [ diad ( a ) ] / ( [ diad ( a ) ] + [ diad ( b ) ] + [ diad ( e ) + ( g ) ] ) \\ = {C}^{′} [ diad ( a ) ]\end{matrix}$$

$$\begin{matrix}c 2 = [ diad ( b ) ] / ( [ diad ( a ) ] + [ diad ( b ) ] + [ diad ( e ) + ( g ) ] ) \\ = {C}^{′} [ diad ( b ) ]\end{matrix}$$

$$\begin{matrix}c 4 \_ 6 = [ diad ( e ) + ( g ) ] / ( [ diad ( a ) ] + [ diad ( b ) ] + [ diad ( e ) + ( g ) ] ) \\ = {C}^{′} [ diad ( e ) + ( g ) ]\end{matrix}$$

(here, in the above 3 Formulas, C′=1/([diad (a)]+[diad (b)]+[diad (e)+(g)]))

$$\begin{matrix}d 2 = [ diad ( c ) ] / ( [ diad ( c ) ] + [ diad ( d ) ] + [ diad ( f ) + ( h ) ] ) \\ = {D}^{′} [ diad ( c ) ]\end{matrix}$$

$$\begin{matrix}d 3 = [ diad ( d ) ] / ( [ diad ( c ) ] + [ diad ( d ) ] + [ diad ( f ) + ( h ) ] ) \\ = {D}^{′} [ diad ( d ) ]\end{matrix}$$

$$\begin{matrix}d 5 \_ 7 = [ diad ( f ) + ( h ) ] / ( [ diad ( c ) ] + [ diad ( d ) ] + [ diad ( f ) + ( h ) ] ) \\ = {D}^{′} [ diad ( f ) + ( h ) ]\end{matrix}$$

(here, in the above 3 Formulas, D′=1/([diad (c)]+[diad (d)]+[diad (f)+(h)])).
By substituting the aforementioned Formula (A2-6), the Formula (A2-6) is expressed using c1, c2, c4_{—}6, d2, d3, d5_{—}7, and C and D as follows:

$$\begin{matrix}{N}_{B} = ( c 1 / {C}^{′} + c 2 / {C}^{′} + c 4 \_ 6 / {C}^{′} + d 2 / {D}^{′} + \\ d 5 \_ 7 / {D}^{′} ) / ( c 4 \_ 6 / {C}^{′} + d 5 \_ 7 / {D}^{′} ) \\ = \{ c 1 + c 2 + c 4 \_ 6 + ( d 2 + d 3 + d 5 \_ 7 ) … \cdot \\ {C}^{′} / {D}^{′} \} / ( c 4 \_ 6 + d 5 \_ 7 \cdot {C}^{′} / {D}^{′} ) .\end{matrix} \qquad Formula ( A2 \text{-} 7 )$$

On the other hand, it is obvious from the diad (b) structure and diad (c) structure that

[diad(b)]=[diad(c)].

Using c2 and d2, and C′ and D′, this Formula can be converted as follows:

c2/C′=d2/D′

This Formula is further converted to

C′/D′=c2/d2 Formula (A2-8)

From the Formulas (A2-7) and (A2-8), the following Formula is obtained:

N_{B}={d2(d1+d2+d4_{—}6)+c2(d2+d3+d5_{—}7)}/(d2·c4_{—}6+c2·d5_{—}7) Formula (A2-9)

The average chain number calculated using Formula (A2-9) and values from Table 19 and 20 was 17.

### Example 12

### Synthesis of Polymer Compound 18

A polymer (hereinafter, designated as polymer compound 18) consisting of the aforementioned (repeating unit A), the aforementioned (repeating unit C) and the aforementioned (repeating unit D) was obtained by a similar procedure to <synthesis of polymer compound 10> in Example 6 by using 1050.0 mg (1.63 mmol) of compound B, 15.8 mg (0.02 mmol) of compound D, 17.8 mg (0.02 mmol) of compound H, 10.1 mg (0.02 mmol) of compound 1 and 12.1 mg (0.02 mmol) of compound J, instead of using 1400.0 mg (2.17 mmol) of compound B, 72.1 mg (0.12 mmol) of compound A and 83.4 mg (0.12 mmol) of compound G. The polystyrene-reduced number average molecular weight and weight average molecular weight by the SEC condition 1 were Mn=65000 and Mw=457000, respectively.

### Attribution of Diad Peaks of Polymer Compound 18

HMQC spectra measurement was carried out for polymer compound 18, in a similar manner to that for polymer compound 17, and the integrated intensity was obtained by integrating in the same range as in polymer compound 17. Further the ratios of diad (a), diad (b) and diad (e)+(g), and diad (c), diad (d) and diad (f)+(h) were obtained by a similar calculation to that for polymer compound 17. The results are shown in Table 21.

TABLE 21

| Correlation | | | | Ratio |
|---|---|---|---|---|
| peak | Integrated | Quantity ratio of proton | | of |
| location | intensity | Formula | Value | diad |
| H_{C1} and C_{C1} | 149.5 . . . (C1) | C1/(C1 + C2 + C4_6) | 0.03 | 0.02 |
| H_{C2} and C_{C2} | 4004.6 . . . (C2) | C2/(C1 + C2 + C4_6) | 0.89 | 0.91 |
| H_{C4} and C_{C4} | 343.0 . . . (C4_6) | C4_6/(C1 + C2 + | 0.08 | 0.08 |
| H_{C6} and C_{C6} | | C4_6) | | |
| H_{D2} and C_{D2} | 4051.8 . . . (D2) | D2/(D2 + D3 + | 0.92 | 0.92 |
| | | D5_7) | | |
| H_{D3} and C_{D3} | 0.0 . . . (D3) | D3/(D2 + D3 + | 0.00 | 0.00 |
| | | D5_7) | | |
| H_{D5} and C_{D5} | 374.6 . . . (D5_7) | D5_7/(D2 + D3 + | 0.08 | 0.08 |
| H_{D7} and C_{D7} | | D5_7) | | |

Based on the above results, the ratio of diad (a), diad (b) (or diad (c)) and diad (d) was obtained by a similar calculation to that for polymer compound 17, and found to be 2:98:0. From the above facts, in polymer compound 18 it was found that the ratio of the number of links formed between the head and tail to the total number of links formed between each other (repeating unit A) is 98%.

### Calculation of Average Chain Number of (Repeating Unit A) in Polymer Compound 18

An average chain number of (repeating unit A) in polymer compound 18 was 12 when calculated by using the Formula (A2-9) and the values in Table 22 in a similar manner as in the average chain number of (repeating unit A) in polymer compound 17.

### Comparative Example 12

### Production of Light-Emitting Device Made of Polymer Compound 17

### (Preparation of Solution)

Polymer compound 17 obtained in Comparative Example 11 was dissolved in xylene at a rate of polymer concentration of 1.0 wt %.

### (Production of EL Device)

On a glass substrate plate on which a 150 nm thick ITO film had been formed by the sputtering method, a 70 nm thick film was formed by spin-coating using a solution which was prepared by filtering a suspension of poly(3,4-ethylenedioxythiophene)/polystyrenesulfonic acid (BaytronP AI4083, Bayer) through a 0.2 μm membrane filter, and dried at 200° C. on a hot plate for 10 minutes. Subsequently, using the xylene solution of polymer compound 17 obtained as described above, a film was formed by the spin-coating method at 2500 rpm. The thickness of thus formed film was about 101 nm. This was further dried at 90° C. for 1 hour under a nitrogen atmosphere where an oxygen concentration and water concentration was 10 ppm or less. Then, vacuum depositions were carried out for lithium fluoride to about 4 nm thick, calcium as a cathode to about 5 nm thick and then aluminum to about 80 nm thick to produce an EL device. Vacuum-deposition was started after a vacuum of 1×10⁻⁴ Pa or below was attained.

### (Performance of EL Device)

An EL emission having a peak at 470 nm was obtained from this device by applying a voltage to the device thus obtained. The color of EL emission at 100 cd/m² hour demonstrated by the C. I. E. color coordinate was x=0.15, y=0.25. Intensity of the EL emission was almost proportional to an electric current density. Also, the voltage at the time of reaching 1 cd/m² was 5.4 V and the maximum emission efficiency was 2.74 cd/A.

(Change of Spectra Before and after Driving the Device)

The EL device obtained as described above was driven at a constant current of 50 mA/cm², and the EL spectra was measured 5 hours later, and shoulder peaks were observed at 550 nm and 590 nm. Each luminance intensity was normalized by the peak intensity at 470 nm to obtain the increase rate of luminance intensity at 550 nm and 590 nm. It was found that the luminance intensity at 550 nm and 590 nm were increased by 8.6% and 5.3%, respectively.

### Example 13

### Production of Light-Emitting Device Made of Polymer Compound 18

### (Preparation of Solution)

Polymer compound 18 obtained in Example 12 was dissolved in xylene at a rate of a polymer concentration of 1.0 wt %.

### (Production of EL Device)

On a glass substrate plate on which a 150 nm thick ITO film had been formed by the sputtering method, a 70 nm thick film was formed by spin-coating using a solution which was prepared by filtering a suspension of poly(3,4-ethylenedioxythiophene)/polystyrenesulfonic acid (BaytronP AI4083, Bayer) through a 0.2 μm membrane filter, and dried at 200° C. on a hot plate for 10 minutes. Subsequently, using the xylene solution of polymer compound 18 obtained as described above, a film was formed by the spin-coating method at 2500 rpm. The thickness of thus formed film was about 111 nm. This was further dried at 90° C. for 1 hour under a nitrogen atmosphere where an oxygen concentration and water concentration was 10 ppm or less. Then, vacuum depositions were carried out for lithium fluoride to about 4 nm thick, calcium as a cathode to about 5 nm thick and then aluminum to about 80 nm thick to produce an EL device. Vacuum-deposition was started after a vacuum of 1×10⁻⁴ Pa or below was attained.

### (Performance of EL Device)

An EL emission having a peak at 470 nm was obtained from this device by applying a voltage to the device thus obtained. The color of EL emission at 100 cd/m² hour demonstrated by the C. I. E. color coordinate was x=0.15, y=0.28. Intensity of the EL emission was almost proportional to an electric current density. Also, the voltage at the time of reaching 1 cd/m² was 5.8 V and the maximum emission efficiency was 2.74 cd/A.

(Change of Spectra Before and after Driving the Device)

The EL device obtained as described above was driven at a constant current of 50 mA/cm², and the EL spectra was measured 5 hours later, and almost no shoulder peak was observed at 550 nm and 590 nm. Each luminance intensity was normalized by the peak intensity at 475 nm to obtain the increase rate of luminance intensity at 550 nm and 590 nm. It was found that the luminance intensity at 550 nm and 590 nm were increased by 0.1% and 0.7%, respectively.

As the above results indicate, the polymer compound of the invention of the present application have less change in EL spectra after driving and is superior in chemical stability compared to Comparative Example 12.

### Reference Example 1

### Stability Test for Substituted Group

102.1 mg (0.76 mmol) of n-butylbenzene, 115.9 mg (0.77 mmol) of n-butyloxybenzene, 124.8 mg (0.76 mmol) of n-butyloxymethylbenzene and 162.6 mg (0.77 mmol) of benzyl benzoate were placed in a 200 ml 4 necked flask, and the air inside of the flask was replaced with argon gas. Next, 42 ml of tetrahydrofuran, 15 ml of a 1.0 N tetrahydrofuran solution of lithium aluminium hydride (15 mmol) and 102.1 mg of n-octylbenzene as an internal standard substance were added. After raising the temperature to 70° C., the mixture was stirred for 10 hours, and then mixed with 15 ml of the 1.0 N tetrahydrofuran solution of lithium aluminium hydride (15 mmol) and stirred at 70° C. for 8 hours. Residual rate of each compound (ratio of input amount and amount not decomposed) was measured by the high speed liquid chromatography and the results shown in Table 22 were obtained.

TABLE 22

| Compound | Residual rate |
|---|---|
| n-butylbenzene | 99% |
| n-butyloxybenzene | 99% |
| n-butyloxymethylbenzene | 68& |
| benzyl benzoate | 0% |

From the above results, it became clear that an alkoxymethyl group and an acyloxymethyl group are readily decomposed under reducing environment, and therefore not suitable as a substituent for polyarylene of the present invention.

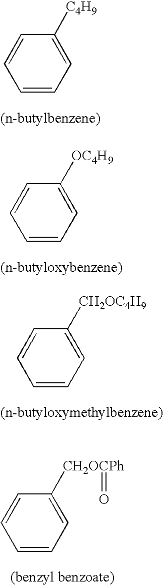

### INDUSTRIAL APPLICABILITY

The polymer compound (polyarylene) of the present invention is superior in a stability such as heat stability and chemical stability, is useful as a light-emitting material and charge transport material, and can be used for laser dyes, organic solar cell material, organic semiconductor for organic transistors, electroconductive thin film material such as conductive thin film, organic semiconductor thin film and the like, and polymer electrolyte material such as polymer electrolyte membrane of metal ion and proton conductive membrane and the like.

1. A polymer compound characterized by comprising a chain comprising only repeating units represented by following Formula (1), wherein an average number of repeating units forming the chain is 3 or greater, and a ratio of bonds formed between a head and a tail to all bonds formed between the repeating units is 85% or greater, 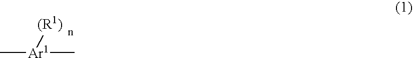
wherein Ar¹ is a divalent aromatic group and the aromatic ring is an aromatic hydrocarbon ring; R¹ represents a substituent on Ar¹, and they each independently represent a hydrocarbon group, a hydrocarbon oxy group, a hydrocarbon thio group, a trialkylsilyl group, a halogen atom, a nitro group, a cyano group, a hydroxyl group, a mercapto group, an acyl group, a formyl group, a carboxyl group, a hydrocarbon oxycarbonyl group, an amino group, an aminocarbonyl group, an imidoyl group, an azo group, an acyloxy group, a phosphonic acid group or a sulfonic acid group; n represents an integer from 0 to 30 and when n is an integer of 2 or greater, a plurality of R¹ may be the same or different from each other; when the carbon atoms of the repeating unit represented by Formula (1) are assigned numbers as a divalent group according to the IUPAC organic chemistry nomenclature, of two carbon atoms with free atomic valences, a carbon atom with a smaller number is a head, and a carbon atom with a larger number is a tail; and no repeating unit represented by Formula (1) has a two-fold axis of symmetry that intersects a straight line connecting the head and tail at right angles at the midpoint of the line.

2. The polymer compound according to claim 1, wherein the Ar¹ is an atomic group remaining when two hydrogen atoms bonded to carbon atoms of an aromatic ring are removed from a condensed ring containing one or more aromatic rings.

3. The polymer compound according to claim 1, comprising a chain comprising only repeating units represented by the Formula (1), wherein an average number of repeating units forming the chain is 5 or greater.

4. The polymer compound according to claim 1, comprising only one type of repeating units represented by the Formula (1).

5. The polymer compound according to claim 1, comprising one kind of repeating units represented by the Formula (1) and one or more kinds of repeating units represented by following Formula (5), (6), (7) or (8), 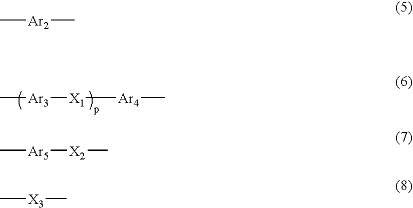
wherein each of Ar₂, Ar₃, Ar₄, and Ar₅ is independently an arylene group, a divalent heterocyclic group, or a divalent group having a metal complex structure; each of X₁, X₂, and X₃ independently represents —CRₐ═CR_{b}—, —C≡C—, —N(R_{c})—, —O—, —S—, —SO—, —SO₂—, or —(SiR_{d}Rₑ)_{q}—; each of Rₐ and R_{b} is, independently, a hydrogen atom, a monovalent hydrocarbon group, a monovalent heterocyclic group, carboxyl group, a hydrocarbon oxycarbonyl group, or a cyano group; each of R_{c}, R_{d}, and Rₑ is, independently, a hydrogen atom, a monovalent hydrocarbon group, a monovalent heterocyclic group; p is 1 or 2; q is an integer from 1 to 12; and when there are a plurality of each of Rₐ, R_{b}, R_{c}, R_{d}, and Rₑ, they can be the same or different from each other.

6. The polymer compound according to claim 5, comprising one kind of repeating units represented by the Formula (1) and one or more and 10 or less kinds of repeating units represented by the Formula (5) or (6).

7. The polymer compound according to claim 1, wherein the ratio of bonds formed between the head and tail to all bonds formed between these repeating units represented by the Formula (1) is 90% or greater.

8. The polymer compound according to claim 1, wherein the ratio of bonds formed between the head and tail to all bonds formed between these repeating units represented by the Formula (1) is 95% or greater.

9. A method for producing the polymer compound according to claim 1, characterized in that the compound is produced by polycondensation with a compound represented by following Formula (A) as one of raw materials, 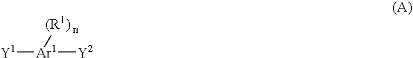
wherein Ar¹, R¹, and n have the same meanings as Ar¹, R¹, and n in Formula (1);
Y¹ each independently represents a halogen atom, a sulfonate group represented by Formula (B), or a methoxy group; and Y² is a borate ester group, a boric acid group, a group represented by Formula (C), a group represented by Formula (D), or a group represented by Formula (E), 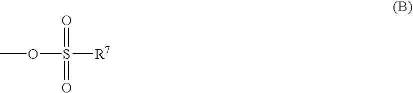
wherein R⁷ represents a hydrocarbon group that can be substituted,
—MgX_{A} (C)
wherein X_{A} represents a halogen atom selected from the group consisting of a chlorine atom, a bromine atom, and an iodine atom,
—ZnX_{A} (D)
wherein X_{A} represents a halogen atom selected from the group consisting a chlorine atom, a bromine atom, and an iodine atom,
—Sn(R⁸)₃ (E)
wherein R⁸ represents a hydrocarbon group that can be substituted, and a plurality of R⁸ may be the same or different from each other.

10. A polymer composition comprising at least one kind of material selected from the group consisting of a hole transport material, electron transport material and light-emitting material, and the polymer compound according to claim 1.

11. A solution characterized by comprising the polymer compound according to claim 1.

12. A solution characterized by comprising the polymer composition according to claim 10.

13. The solution according to claim 11, comprising 2 or more kinds of organic solvents.

14. The solution according to claim 11, having a viscosity of 1-20 mPa·s at 25° C.

15. A light-emitting film comprising the polymer compound according to claim 1, or a polymer composition comprising at least one kind of material selected from the group consisting of a hole transport material, electron transport material and light-emitting material, and the polymer compound according to claim 1.

16. The light-emitting film according to claim 15, wherein a quantum yield of fluorescence is 50% or greater.

17. An electroconductive film comprising the polymer compound according to claim 1, or a polymer composition comprising at least one kind of material selected from the group consisting of a hole transport material, electron transport material and light-emitting material, and the polymer compound according to claim 1.

18. An organic semiconductor film comprising the polymer compound according to claim 1, or a polymer composition comprising at least one kind of material selected from the group consisting of a hole transport material, electron transport material and light-emitting material, and the polymer compound according to claim 1.

19. An organic transistor characterized by comprising the organic semiconductor film according to claim 18.

20. A method for producing the film according to claim 15, characterized in that an inkjet method is used.

21. A polymer light-emitting device characterized by having an organic layer between electrodes consisting of an anode and a cathode, wherein the organic layer comprises the polymer compound according to claim 1 or a polymer composition comprising at least one kind of material selected from the group consisting of a hole transport material, electron transport material and light-emitting material, and the polymer compound according to claim 1.

22. The polymer light-emitting device according to claim 21, wherein the organic layer is a light-emitting layer.

23. The polymer light-emitting device according to claim 22, wherein the light-emitting layer further comprises a hole transport material, an electron transport material or a light-emitting material.

24. A polymer light-emitting device having a light-emitting layer and a charge transport layer between electrodes consisting of an anode and a cathode, wherein the charge transport layer comprises the polymer compound according to claim 1 or a polymer composition comprising at least one kind of material selected from the group consisting of a hole transport material, electron transport material and light-emitting material, and the polymer compound according to claim 1.

25. A polymer light-emitting device having a light-emitting layer and a charge transport layer between electrodes consisting of an anode and a cathode and having a charge injection layer between the charge transport layer and the electrodes, wherein the charge injection layer comprises the polymer compound according to claim 1 or a polymer composition comprising at least one kind of material selected from the group consisting of a hole transport material, electron transport material and light-emitting material, and the polymer compound according to claim 1.

26. A planar light source characterized by using the polymer light-emitting device according to claim 21.

27. A segment display device characterized by using the polymer light-emitting device according to claim 21.

28. A dot matrix display device characterized by using the polymer light-emitting device according to claim 21.

29. A liquid crystal display device, characterized in that the polymer light-emitting device according to claim 21 is used as a backlight.
